(19) United States
(12) Patent Application Publication
(10) Pub. No.: US 2013/0062682 A1
(43) Pub. Date: Mar. 14, 2013

(54) SEMICONDUCTOR MEMORY AND MANUFACTURING METHOD THEREOF

(71) Applicants: Masato ENDO, Yokohama-shi (JP); Yoshiko Kato, Yokohama-shi (JP)

(72) Inventors: Masato ENDO, Yokohama-shi (JP); Yoshiko Kato, Yokohama-shi (JP)

(21) Appl. No.: 13/428,430

(22) Filed: Mar. 23, 2012

(30) Foreign Application Priority Data
Sep. 14, 2011 (JP) 2011-200585

(51) Int. Cl. H01L 29/792; H01L 21/76

(52) U.S. Cl. 257/324; 438/404; 257/E29.309; 257/E21.54

(57) ABSTRACT

According to one embodiment, a semiconductor memory includes a memory cell provided in a first active area surrounded with a first isolation insulating film, a first transistor provided in a second active area surrounded with a second isolation insulating film, a shield gate electrode on the second isolation insulating film. The bottom surface of the shield gate electrode is positioned more closely to a semiconductor substrate side as compared with the highest upper surface of the second isolation insulating film.

### CROSS-REFERENCE TO RELATED APPLICATIONS

This application is based upon and claims the benefit of priority from prior Japanese Patent Application No. 2011-200585, filed Sep. 14, 2011, the entire contents of which are incorporated herein by reference.

### FIELD

Embodiments described herein relate generally to a semiconductor memory and a manufacturing method thereof.

### BACKGROUND

A semiconductor memory, for example, a flash memory is mounted on various electronic apparatuses.

The flash memory includes, in a chip, a transistor having a high junction breakdown voltage, a high surface breakdown voltage and a high gate breakdown voltage (called the high breakdown voltage transistor), to generate and transfer a high voltage (e.g., 10 V or higher) as a driving voltage in the chip.

When the high breakdown voltage transistor is driven, an inversion layer is formed under an isolation insulating film which surrounds a high breakdown voltage transistor forming area, and leak occurs between adjacent elements via the inversion layer sometimes.

To prevent the inversion layer from being formed under this isolation insulating film, various technologies have been investigated.

### BRIEF DESCRIPTION OF THE DRAWINGS

FIG. 1 is a schematic diagram for explaining a basic example of a semiconductor memory of an embodiment;

FIG. 2 is a schematic diagram for explaining a constitution of the semiconductor memory of the embodiment;

FIG. 3 is a plan view showing a structure of a semiconductor memory of a first embodiment;

FIG. 4 is a sectional view showing the structure of the semiconductor memory of the first embodiment;

FIG. 5 is a sectional view showing the structure of the semiconductor memory of the first embodiment;

FIG. 6 is a sectional view showing the structure of the semiconductor memory of the first embodiment;

FIG. 7 is a sectional process view showing one process of a manufacturing method of the semiconductor memory of the first embodiment;

FIG. 8 is a sectional process view showing one process of a manufacturing method of the semiconductor memory of the first embodiment;

FIG. 9 is a sectional process view showing one process of a manufacturing method of the semiconductor memory of the first embodiment;

FIG. 10 is a sectional process view showing one process of a manufacturing method of the semiconductor memory of the first embodiment;

FIG. 11 is a sectional process view showing one process of a manufacturing method of the semiconductor memory of the first embodiment;

FIG. 12 is a sectional process view showing one process of a manufacturing method of the semiconductor memory of the first embodiment;

FIG. 13 is a plane process view showing one process of a manufacturing method of the semiconductor memory of the first embodiment;

FIG. 14 is a sectional process view showing one process of a manufacturing method of the semiconductor memory of the first embodiment;

FIG. 15 is a sectional process view showing one process of a manufacturing method of the semiconductor memory of the first embodiment;

FIG. 16 is a sectional process view showing one process of a manufacturing method of the semiconductor memory of the first embodiment;

FIG. 17 is a sectional process view showing one process of a manufacturing method of the semiconductor memory of the first embodiment;

FIG. 18 is a sectional process view showing one process of a manufacturing method of the semiconductor memory of the first embodiment;

FIG. 19 is a sectional process view showing one process of a manufacturing method of the semiconductor memory of the first embodiment;

FIG. 20 is a view showing a structure of a semiconductor memory of a second embodiment;

FIG. 21 is a sectional process view showing one process of a manufacturing method of the semiconductor memory of the second embodiment;

FIG. 22 is a sectional process view showing one process of a manufacturing method of the semiconductor memory of the second embodiment;

FIG. 23 is a sectional process view showing one process of a manufacturing method of the semiconductor memory of the second embodiment;

FIG. 24 is a view showing a structure of a semiconductor memory of a third embodiment;

FIG. 25 is a sectional process view showing one process of a manufacturing method of the semiconductor memory of the third embodiment;

FIG. 26 is a view showing a structure of a semiconductor memory of a fourth embodiment;

FIG. 27 is a sectional process view showing one process of a manufacturing method of the semiconductor memory of the fourth embodiment;

FIG. 28 is a sectional process view showing one process of a manufacturing method of the semiconductor memory of the fourth embodiment;

FIG. 29 is a sectional process view showing one process of a manufacturing method of the semiconductor memory of the fourth embodiment;

FIG. 30 is a view showing a structure of a semiconductor memory of a fifth embodiment;

FIG. 31 is a sectional process view showing one process of a manufacturing method of the semiconductor memory of the fifth embodiment;

FIG. 32 is a view showing a structure of a semiconductor memory of a sixth embodiment;

FIG. 33 is a sectional process view showing one process of a manufacturing method of the semiconductor memory of the sixth embodiment;

FIG. 34 is a sectional view showing a structure of a semiconductor memory of a seventh embodiment;

FIG. 35 is a sectional process view showing one process of a manufacturing method of the semiconductor memory of the seventh embodiment;

FIG. 36 is a sectional process view showing one process of a manufacturing method of the semiconductor memory of the seventh embodiment;

FIG. 37 is a sectional view showing a structure of a semiconductor memory of an eighth embodiment;

FIG. 38 is a sectional view showing a structure of a semiconductor memory of a ninth embodiment;

FIG. 39 is a plan view showing a modification of the semiconductor memory of the embodiment;

FIG. 40 is a sectional view showing a modification of the semiconductor memory of the embodiment;

FIG. 41 is a sectional view showing a modification of the semiconductor memory of the embodiment; and

FIG. 42 is a sectional view showing a modification of the semiconductor memory of the embodiment.

### DETAILED DESCRIPTION

Hereinafter, embodiments will be described in detail with reference to the drawings. In the following description, elements having the same function and constitution are denoted with the same signs, and repeated descriptions will be made if necessary.

In general, according to one embodiment, a memory cell array provided in a semiconductor substrate and including a first active area surrounded with a first isolation insulating film; a first transistor area provided in the semiconductor substrate and including a second active area surrounded with a second isolation insulating film; a memory cell provided in the memory cell array, the memory cell comprising a first gate insulating film provided on the first active area, a charge storage layer provided on the first gate insulating film, a first insulator provided on the charge storage layer, and a control gate electrode provided on the charge storage layer via the first insulator; a first transistor provided in the first transistor area, the first transistor comprising a second gate insulating film having a second film thickness larger than a first film thickness of the first gate insulating film and provided on the second active area, and a first electrode layer provided on the second gate insulating film; and a shield gate electrode provided on the second isolation insulating film. The bottom surface of the shield gate electrode is positioned more closely to the semiconductor substrate side as compared with the highest upper surface of the second isolation insulating film.

### Embodiments

### <A> Basic Configuration

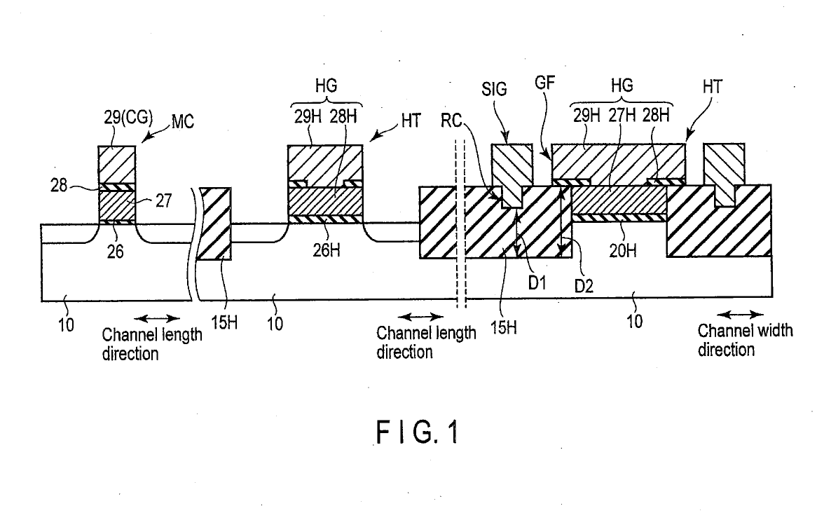

A basic example of a semiconductor memory of the present embodiment will be described with reference to FIG. 1.

FIG. 1 is a sectional view for explaining the basic example of the semiconductor memory of the present embodiment.

FIG. 1 schematically shows a structure of a memory cell, in a channel length direction, included in the semiconductor memory (e.g., a flash memory) of the present embodiment and a structure, in channel length and width directions, of a field-effect transistor as a peripheral element (a control element).

As shown in FIG. 1, a memory cell MC is a field-effect transistor of a stack gate structure including a charge storage layer (a floating gate electrode or an insulating film including electron trap level) 27 and a control gate electrode 29. Between the charge storage layer 27 and the control gate electrode 29, an insulator (an inter-gate insulating film or a block insulating film) 28 is provided. A tunnel insulating film 26 is provided between a semiconductor substrate 10 and the charge storage layer 27.

On the semiconductor substrate 10 which is the same as in the memory cell MC, there is provided a high breakdown voltage transistor HT, for example, a field-effect transistor having a high junction breakdown voltage, a high surface breakdown voltage, a high gate breakdown voltage, and a high threshold voltage. The high breakdown voltage transistor HT has a gate structure similar to the gate structure of the memory cell. A gate electrode HG of the high breakdown voltage transistor HT includes a first layer 27H of the same constitution (the same film thickness or material) as the charge storage layer 27 and a second layer 29H of the same constitution (the same film thickness or material) as the control gate electrode 29. The second layer 29H comes in contact with the first layer 27H via an opening of an insulator 28H in the gate electrode HG, and hence it is electrically connected to the first conductive layer 27H. Generally, the thickness of the gate insulating film 20H is larger than the thickness of the tunnel insulating film.

For example, part (here, the second layer 29H) of the gate electrode HG of the high breakdown voltage transistor HT is drawn onto an isolation insulating film 15H adjacent to an active area of an area where the high breakdown voltage transistor is disposed (called the high breakdown voltage transistor forming area). In the gate electrode HG of the high breakdown voltage transistor, a portion GF drawn onto the isolation insulating film 15H will be called the gate fringe GF.

In the present embodiment, a shield gate electrode SIG is provided on the isolation insulating film 15H which surrounds the high breakdown voltage transistor forming area. The shield gate electrode SIG includes, for example, at least a part of a constituting member of a control gate electrode CG of the memory cell.

The shield gate electrode SIG is provided on the isolation insulating film 15H to suppress the formation of an inversion layer (a channel) in a bottom portion of the isolation insulating film 15H owing to the gate fringe portion GF to which a high voltage is applied, when the high breakdown voltage transistor is driven. When the high breakdown voltage transistor HT is driven, 0 V or a negative bias is applied to the shield gate electrode SIG.

A trench RC is provided in the isolation insulating film 15H. In the semiconductor memory of the present embodiment, at least a part of the shield gate electrode SIG is buried in the trench RC.

When part of the shield gate electrode SIG is buried in the trench, a bottom portion of the shield gate electrode SIG is positioned more closely to a bottom side of the semiconductor substrate 10 (or the isolation insulating film 15H) than the highest portion of the upper surface of the isolation insulating film 15H, in a direction vertical to the surface of the semiconductor substrate. For example, the bottom portion of the shield gate electrode SIG is positioned more closely to the bottom side of the semiconductor substrate 10 than a bottom portion of the gate fringe portion GF of the high breakdown voltage transistor HT.

In consequence, a distance D1 between the bottom portion of the shield gate electrode SIG and the bottom portion of the isolation insulating film 15H is smaller than a distance D2 between the bottom portion of the gate fringe portion GF and the bottom portion of the isolation insulating film 15H.

Consequently, an effect of suppressing the formation of the inversion layer of the bottom portion of the isolation insulating film 15H by the shield gate electrode SIG is strengthened.

In an area where the shield gate electrode is disposed (called a shield gate forming area), at least a part of the upper surface of the isolation insulating film 15H is positioned more closely to the bottom portion side of the semiconductor substrate 10 than the upper surface of the isolation insulating film 15H provided with the gate fringe portion GF.

A step of retreating (etching) the upper surface of the isolation insulating film 15H in the shield gate forming area toward the bottom side of the semiconductor substrate 10 (e.g., a step of forming the trench RC) can be common to a step of forming the memory cell MC and the high breakdown voltage transistor HT as in, for example, a step of forming the opening through the insulator 28H. Therefore, it is possible to form the shield gate electrode SIG having the above-mentioned structure without the increase of manufacturing steps.

Therefore, the semiconductor memory of the present embodiment can decrease, for example, the leak between the elements, and can enhance operation characteristics. Moreover, according to a manufacturing method of the semiconductor memory of the present embodiment, there can be provided a memory having enhanced operation characteristics without the increase of the manufacturing steps.

### <B> Embodiments

### (B1) First Embodiment

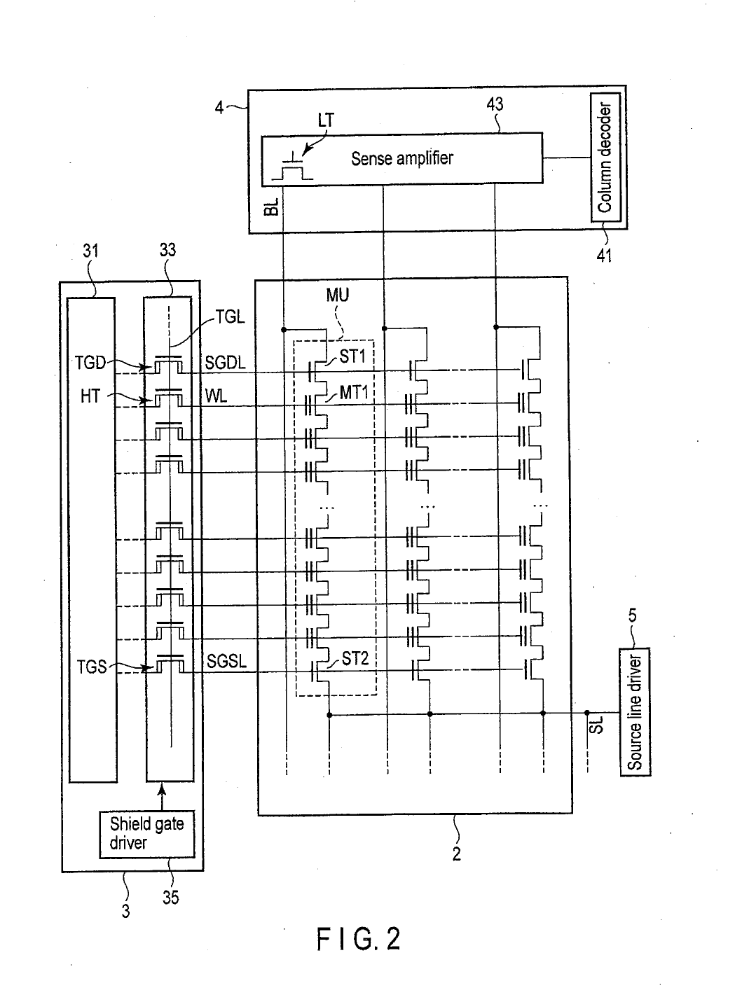

A semiconductor memory of a first embodiment will be described with reference to FIG. 2 to FIG. 19.

(a) Constitution

A circuit constitution of the semiconductor memory of the first embodiment will be described with reference to FIG. 2.

The semiconductor memory of the first embodiment is, for example, a flash memory. FIG. 2 is a schematic diagram showing a constitution in the vicinity of a memory cell array 2 of the flash memory.

As shown in FIG. 2, the flash memory includes the memory cell array 2, a row control circuit 3, a column control circuit 4, and a source line driver 5.

The memory cell array 2 includes memory cells MC which can hold data, respectively. The memory cells MC are field-effect transistors each including a charge storage layer which can hold a charge, and a control gate electrode.

The flash memory of the present embodiment is, for example, an NAND-type flash memory. The memory cell array 2 shown in FIG. 2 includes memory cell units MU arranged in an array. Each of the memory cell units MU is formed of the memory cells MC and two select transistors ST1 and ST2.

There is no special restriction on the number of the memory cells MC in one memory cell unit MU, as long as the number of the cells is two or more. The number of the cells in the memory cell unit MU may be 8, 16, 32, 64, 128, 256 or the like.

In the one memory cell unit MU, current paths of the memory cells MC are connected in series. Hereinafter, the memory cells whose current paths are connected in series will be called an NAND string.

The NAND string is disposed between the select transistor ST1 and the select transistor ST2. One end of the NAND string is connected to one end of the current path of the select transistor ST1, and the other end of the NAND string is connected to one end of the current path of the select transistor ST2.

The control gate electrode of the memory cell MC is connected to a word line WL. The control gate electrodes of the memory cells MC arranged in the same row are connected to the common word line WL.

Gates of the select transistors ST1 and ST2 arranged in the same row are connected in common to selection gate lines SGDL and SGSL, respectively.

The other end (a drain) of the current path of the select transistor ST1 is connected to one bit line BL. The memory cell units MU arranged in the same column are connected to the common bit line BL.

The other end (a source) of the current path of the select transistor ST2 is connected to a source line SL. The memory cell units MU arranged in the same row are connected to the common source line SL.

The row control circuit 3 selects the row of the memory cell array 2 in accordance with an address input from the outside. The row control circuit 3 includes a row decoder 31 and a word line driver 33.

The row decoder 31 decodes a row address signal form the outside, and transfers the decoded signal to the word line driver 33.

The word line driver 33 includes transfer gate transistors TGD and TGS whose gates are connected to a common transfer gate line TGL, and field-effect transistors HT.

To the common transfer gate line TGL, there are connected the two transfer gate transistors TGD and TGS. One end of a current path of the one transfer gate transistor TGD is connected to the selection gate line SGDL on a drain side of the memory cell unit MU. One end of a current path of the other transfer gate transistor TGS is connected to the selection gate line SGSL on a source side of the memory cell unit MU.

To the common transfer gate line TGL, there are connected the same number of the field-effect transistors HT as that of the word lines WL connected to the memory cell unit MU. A gate of the field-effect transistor HT is connected to the transfer gate line TGL. One end of a current path of the field-effect transistor HT is connected to the word line WL. In the word line driver 33, the field-effect transistor HT connected to the word line is formed of a high breakdown voltage transistor, to apply a voltage of about 10 V to 25 V to the word line WL. The high breakdown voltage transistor HT has a high junction breakdown voltage, a high surface breakdown voltage and a high gate breakdown voltage. Consequently, the high breakdown voltage transistor HT having the high breakdown voltages has a driving voltage (or threshold voltage) greater than that of the low breakdown voltage transistor LT. A predetermined voltage such as a program voltage is applied to each of the word lines WL via a channel of the high breakdown voltage transistor.

For example, the voltage applied to the word line is generated by a charge pump circuit.

In the present embodiment, the row control circuit 3 includes a shield gate driver 35. The shield gate driver 35 controls a potential of a shield gate electrode provided adjacent to the high breakdown voltage transistor.

The column control circuit 4 includes a column decoder 41 and a sense amplifier circuit 43.

The column decoder 41 decodes a column address signal from the outside, and transfers the decoded signal to the sense amplifier 43.

The sense amplifier 43 detects and amplifies potential fluctuations of the bit line BL in accordance with data stored in the memory cell which is a reading object, when the data is read. Moreover, the sense amplifier 43 transfers a predetermined potential to the bit line, when the data is written. The sense amplifier circuit 43 includes, for example, field-effect transistors. Each of the field-effect transistors included in the sense amplifier circuit 43 is mainly formed of a low breakdown voltage transistor. The low breakdown voltage transistor LT has a low junction breakdown voltage, a low surface breakdown voltage and a low gate breakdown voltage. A driving voltage of a low breakdown voltage transistor LT having the low breakdown voltages is smaller than that of the high breakdown voltage transistor HT, and is, for example, about 3 V to 7 V.

The source line driver 5 controls a potential level of the source line SL in accordance with an operation of the memory cell array 2.

Operations of the memory cell array 2, the row/column control circuits 3 and 4 and the source line driver 5 are controlled by a state machine (not shown). The state machine manages and controls the operations of the memory cell array 2 and the circuits 3, 4 and 5 on the basis of a request from an external apparatus such as a host device or a memory controller.

In the present embodiment, circuits other than the memory cell array 2 included in the flash memory, for example, the row control circuit 3, the column control circuit 4 and the source line driver 5 will be called peripheral circuits. In a chip (a semiconductor substrate) of the flash memory, an area where the peripheral circuit is formed will be called a peripheral circuit area. Moreover, when the low breakdown voltage transistor and the high breakdown voltage transistor forming the peripheral circuit are not distinguished, the transistors will be called peripheral transistors.

Here, the operation of the flash memory of the present embodiment will be described.

In the NAND-type flash memory, the data is written in one go in the memory cells MC which are writing objects connected to the same word line WL. This data writing unit will be called a page. The reading of the data is also executed in units of pages. The data is erased from the memory cells MC in one go. A data erasing unit will be called a block.

When the data is written, the word line WL corresponding to an address is selected by the row decoder 31 and the word line driver 33 in the row control circuit 3. A program voltage VPGM of, for example, about 20 V (an absolute value) is applied to the selected word line WL. Moreover, an intermediate voltage VPASS smaller than the program voltage VPGM is applied to a word line (called an unselected word line) other than the selected word line. The intermediate voltage VPASS is a voltage to turn on the memory cell MC, and has a size of, for example, about 6 V to 15 V (an absolute value).

The high breakdown voltage transistor HT in the word line driver 33 is driven to apply the program voltage VPGM and the intermediate voltage VPASS to the word line WL. Therefore, a voltage of 20 V or higher is applied to the transfer gate line TGL, and the voltage of 20 V or higher is applied to the gates of the transfer gate transistors TGD and TGS and the high breakdown voltage transistor HT, respectively.

When the high breakdown voltage transistor HT is driven, the shield gate driver 35 applies, for example, a voltage of 0 V to the shield gate electrode. A function of the shield gate electrode will be described later.

The column control circuit 4 applies a selection voltage (e.g., 0 V) to the bit line connected to the memory cell which is the data writing object. On the other hand, the circuit applies a non-selection voltage (>0 V) to the bit line connected to the memory cell which is not the data writing object. A non-selection potential from the bit line BL is transferred to the channel region of the memory cell, and then the select transistor ST1 is turn off.

In accordance with a potential difference between the program voltage VPGM and the channel potential of the memory cell, the threshold voltage of the memory cell which is the writing object shifts into a range of threshold values associated with the data (a threshold value distribution). In consequence, predetermined data is written in the memory cells.

In other hand, the channel region of non selected memory cell is boost up by the voltage applied to the word line and the non-selection potential transferred to the channel region. In consequence, the threshold voltage of the memory cell which is not the data writing object does not shift.

When the data is read, the word line WL corresponding to the address is selected, and a reading voltage VCGR is applied to the selected word line. When the data is read, a non-selection voltage VREAD is applied to the unselected word line. The non-selection voltage VREAD is a voltage to turn on the memory cell MC. In addition, the column control circuit 4 sets the bit line BL to a charged state.

When the threshold voltage (the on-voltage) of the memory cell MC is not higher than the reading voltage VCGR, the memory cell MC connected to the selected word line turns on. When the threshold voltage of the memory cell MC is higher than the reading voltage VCGR, the memory cell connected to the selected word line turns off. In accordance with the on-state or off-state of the memory cell MC corresponding to the reading voltage VCGR, a potential level of the bit line BL fluctuates. The potential fluctuations of the bit line BL are detected/amplified by the sense amplifier 43, whereby the data is identified.

When the data is erased, 0 V is applied to all the word lines WL, and an erasing voltage (e.g., 20 V) is applied to a well region where the memory cell array 2 is formed.

The memory cell array 2 and the peripheral circuit areas 3, 4 and 5 are provided in the common semiconductor substrate (the semiconductor chip). Moreover, constitutional elements in the memory cell array 2 and constitutional elements in the peripheral circuits 3, 4 and 5 are essentially simultaneously formed by using a common manufacturing process.

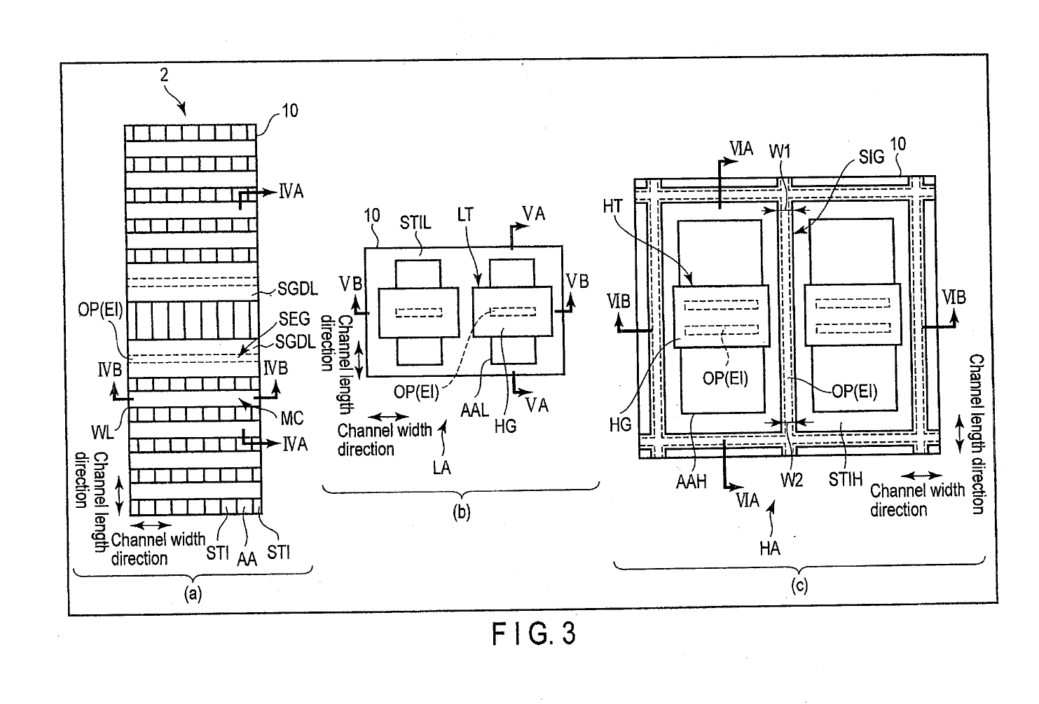

The structure of the flash memory of the present embodiment will be described with reference to FIG. 3 to FIG. 5.

FIG. 3 is a plan view (an upper surface view) for explaining the constitutional elements included in the flash memory of the present embodiment. (a) of FIG. 3 shows a planar structure of the memory cell array 2. (b) of FIG. 3 shows a planar structure of the low breakdown voltage transistor LT in the peripheral circuit area. (c) of FIG. 3 shows a planar structure of the high breakdown voltage transistor HT and the shield gate electrode SIG in the peripheral circuit area.

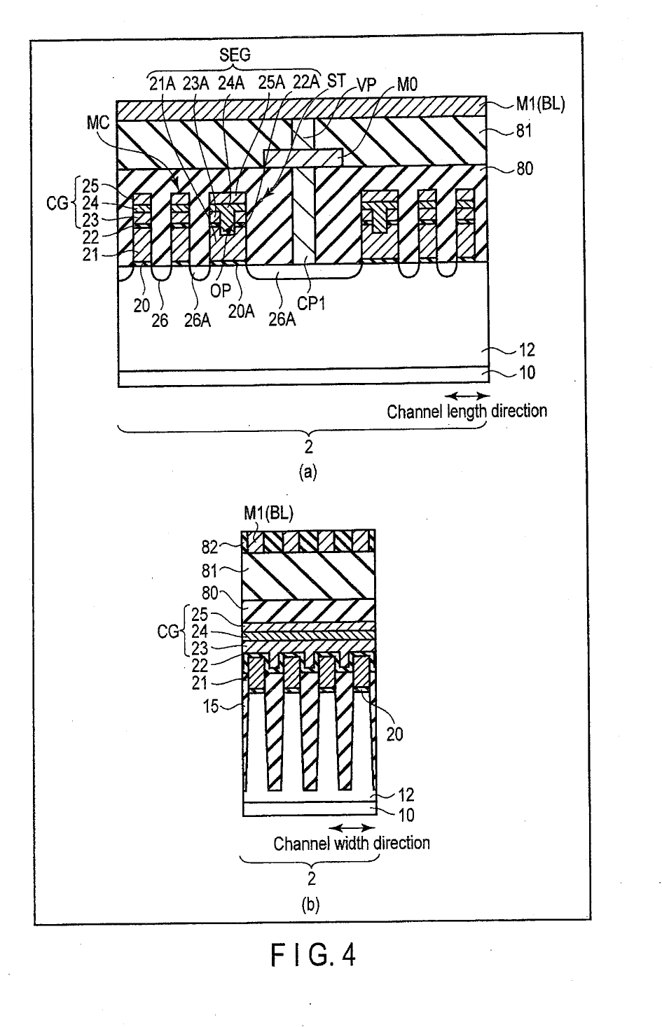

FIG. 4 is a sectional view of the memory cell array 2 and the memory cells MC. (a) of FIG. 4 shows a sectional structure cut along the IVA-IVA line of (a) of FIG. 3. (b) of FIG. 4 shows a sectional structure cut along the IVB-IVB line of (a) of FIG. 3.

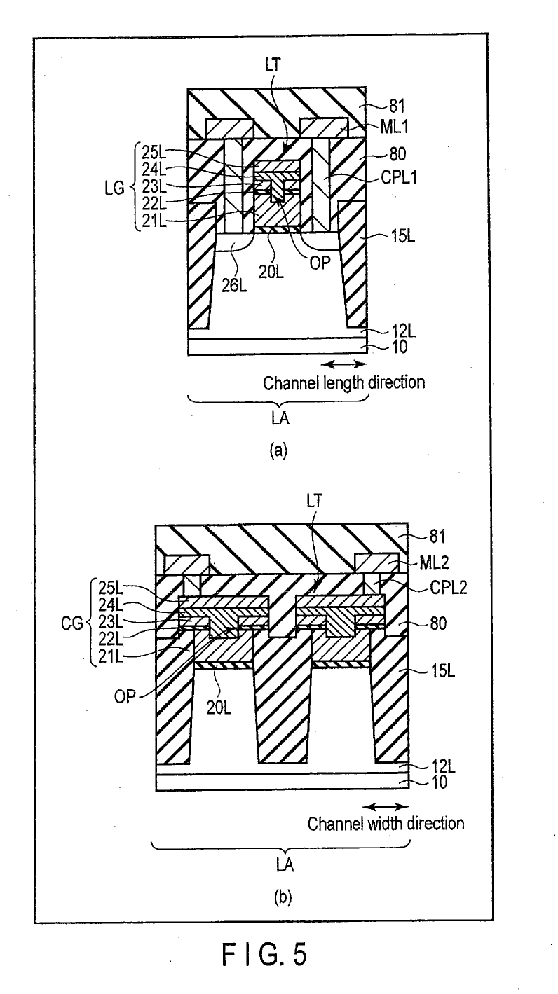

FIG. 5 is a sectional view of the low breakdown voltage transistor LT in the peripheral circuit area. (a) of FIG. 5 shows a sectional structure cut along the VA-VA line of (b) of FIG. 3. (b) of FIG. 5 shows a sectional structure cut along the VB-VB line of (b) of FIG. 3.

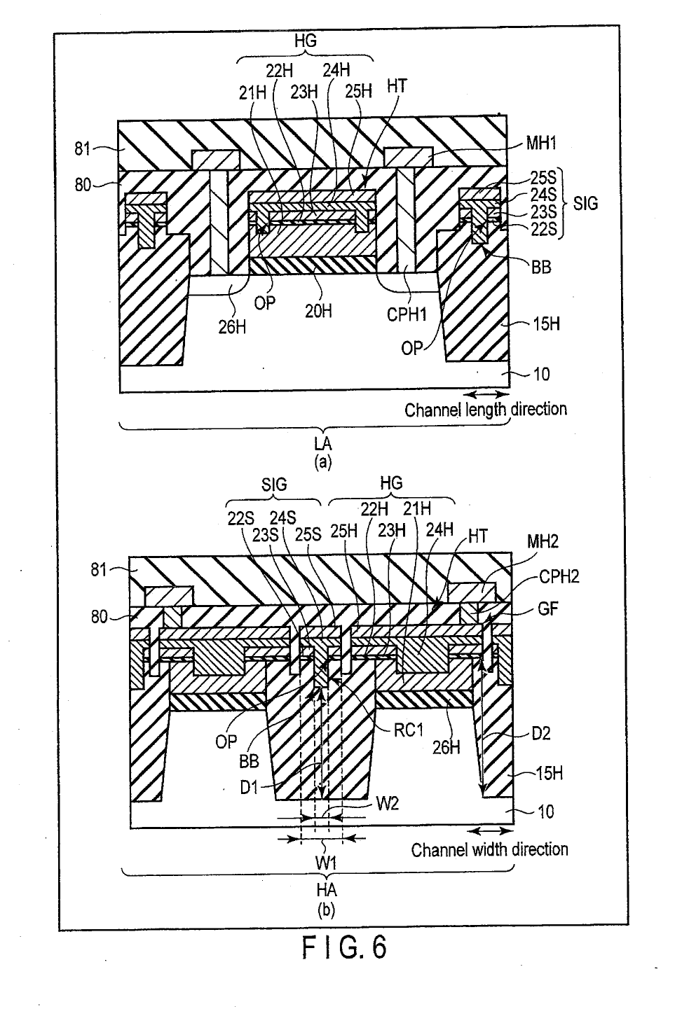

FIG. 6 is a sectional view of the high breakdown voltage transistor HT and the shield gate electrode SIG in the peripheral circuit area. (a) of FIG. 6 shows a sectional structure cut along the VIA-VIA line of (c) of FIG. 3. (b) of FIG. 6 shows a sectional structure cut along the VIS-VIB line of (c) of FIG. 3.

Hereinafter, an area LA where the low breakdown voltage transistor is formed will be called a low breakdown voltage transistor forming area LA, and an area HA where the high breakdown voltage transistor is formed will be called a high breakdown voltage transistor forming area HA. Moreover, an area where the shield gate electrode is formed will be called a shield gate forming area.

Structures of the memory cell array 2, the memory cell MC and a select transistor ST will be described with reference to (a) of FIG. 3, (a) of FIG. 4 and (b) of FIG. 4.

As shown in FIG. 3 and FIG. 4, the memory cell array 2 includes isolation areas STI and active areas AA. In the memory cell array 2, the active areas AA extend in a transistor channel length direction (a column direction or a y-direction). Each of the isolation areas STI is provided between the active areas AA adjacent in a transistor channel width direction (a row direction or an x-direction). The active areas AA extending in the channel length direction and the isolation areas STI extending in the channel length direction form a line-and-space layout in the semiconductor substrate 10.

In a surface layer portion of the semiconductor substrate 10 of the memory cell array 2, a p-type well region 12 is provided. The memory cells MC and the select transistors ST are provided in the active areas AA of the p-type well region 12.

As described above, the memory cells MC are field-effect transistors each including a charge storage layer 21 and the control gate electrode CG.

The charge storage layer 21 is provided on a gate insulating film 20 on the surface of the p-type well region 12. The gate insulating film 20 functions as a tunnel insulating film of the memory cell MC, when the data is written. The gate insulating film 20 is formed of a silicon oxide film, a silicon oxynitride film, or a high-dielectric constant insulating film (a high-k film). The gate insulating film 20 may be a single layer film or a multilayer film of these films.

The charge storage layer 21 is formed of, for example, a polysilicon layer. Hereinafter, the charge storage layer 21 formed of the polysilicon layer will be called the floating gate electrode 21.

In the memory cells MC adjacent in a channel width direction, the floating gate electrodes 21 of the respective memory cells MC are electrically isolated by an isolation insulating film 15 buried in the isolation area STI. In the memory cell array 2, the upper surface of the isolation insulating film 15 retreats more closely to the bottom side of the semiconductor substrate 10 than the upper surface of the floating gate electrode 21, in a direction vertical to the surface of the semiconductor substrate 10. In consequence, the floating gate electrode 21 has a structure where part of the side surface of the upper portion side of the floating gate electrode 21 does not come in contact with the isolation insulating film 15.

An insulator 22 is provided on the floating gate electrode 21. Here, the insulator 22 will be called the inter-gate insulating film 22. The inter-gate insulating film 22 is formed of, for example, a silicon oxide film, a silicon oxynitride film, a high-dielectric constant insulating film, or a laminate structure of these films (e.g., an ONO film). The inter-gate insulating film 22 covers part of the upper surface and side surface of the floating gate electrode.

The control gate electrode CG is stacked on the floating gate electrode 21 via the inter-gate insulating film 22. The control gate electrode CG faces the upper surface of the floating gate electrode 21 and the side surface of the floating gate electrode 21 in the channel width direction. The control gate electrode CG covers the side surface of the floating gate electrode 21 in addition to the upper surface of the floating gate electrode 21, so that a coupling ratio of the control gate electrode CG and the floating gate electrode 21 of the memory cell MC is enhanced. It is to be noted that in the isolation area STI, the control gate electrode CG is provided on the isolation insulating film 15 via the inter-gate insulating film 22.

The control gate electrode CG extends in, for example, the channel width direction, and is shared by the memory cells MC arranged in the channel width direction. The control gate electrode CG functions as the word line WL.

For example, the control gate electrode CG includes conductive layers. In the present embodiment, the control gate electrode CG is formed of a laminate of three conductive layers 23, 24 and 25. Among the three conductive layers 23, 24 and 25 of the control gate electrode CG, the lowermost conductive layer 23 comes in contact with the inter-gate insulating film 22. The lowermost conductive layer 23 is, for example, a polysilicon layer. The second conductive layer 24 is, for example, a polysilicon layer. The uppermost conductive layer 25 is, for example, a silicide layer. It is to be noted that the uppermost conductive layer 25 may be formed of a metal layer, and the second (intermediate) conductive layer 24 may be formed of a silicide layer. Moreover, the whole control gate electrode CG may be formed by the polysilicon layer or the silicide layer.

For example, a side wall insulating film (not shown) is provided on the side surface of the gate electrode of the memory cell MC in a transistor channel length direction.

As to the memory cells MC in the common active area AA, the memory cells MC adjacent to each other in the channel length direction share a source/drain, whereby current paths (channel areas) are connected in series. In consequence, an NAND string including the memory cells formed. For example, a diffusion layer (hereinafter called the source/drain diffusion layer) 26 as the source/drain of the memory cell MC is formed in the p-type well region 12. The diffusion layer 26 is, for example, an n-type impurity semiconductor region. An area between the adjacent source and drain becomes the channel area which becomes a movement area of electrons. However, in the memory cell MC, the source/drain diffusion layer 26 is not formed sometimes.

It is to be noted that the memory cell MC may have a gate structure of an MONOS structure. In this case, the charge storage layer 21 is formed of an insulating film including a trap level for the electrons as in a silicon nitride film.

The select transistors ST1 and ST2 are provided at one end and the other end of the active area AA corresponding to the memory cell unit MU. Gate structures of the two select transistors ST1 and ST2 in the memory cell unit MU are essentially the same. Therefore, FIG. 4 shows the only select transistor ST1 on a drain side of the NAND string, and the select transistor on a source side of the NAND string is omitted. Hereinafter, when the drain-side and source-side select transistors ST1 and ST2 are not distinguished, the transistors will be described as the select transistors ST.

The select transistors ST are formed essentially simultaneously with the memory cells MC.

A gate insulating film 20A of each of the select transistors ST is provided on the surface of the well region 12. The gate insulating film 20A is formed simultaneously with the tunnel insulating film 20 of the memory cell MC. In this case, the gate insulating film 20A is made of the same material as the tunnel insulating film 20, and has the same film thickness as the tunnel insulating film 20.

A gate electrode SEG of the select transistor ST has a stack gate structure including a lower electrode 21A and upper electrode layers 23A, 24A and 25A.

On the gate insulating film 20A, the lower electrode layer 21A of the select transistor ST is provided. The lower electrode layer 21A is formed simultaneously with the floating gate electrode 21. Therefore, the lower electrode layer 21A is made of the same material (here, polysilicon) as the floating gate electrode 21, and has the same film thickness as the floating gate electrode 21.

On the lower electrode layer 21A, an insulator 22A having an opening OP is provided. The insulator 22A is made of the same material as the inter-gate insulating film 22, and has essentially the same film thickness as the inter-gate insulating film 22. Hereinafter, a step of forming the opening OP through the insulator (the inter-gate insulating film) 22A between the stacked electrode layers of the select transistor ST will be called the EI step. Moreover, an area EA provided with the opening OP formed by the EI step will be called the EI area.

For example, by the EI step, the upper surface of the lower electrode layer 21A is etched so as to correspond to a forming position of the opening OP, and the upper surface of the lower electrode layer 21A becomes depressed. In this case, a sectional shape of the lower electrode layer 21A becomes a hollow shape.

The upper electrode layers 23A, 24A and 25A of the select transistor ST are provided on the insulator 22A, and stacked on the lower electrode layer 21A via the insulator 22A. The upper electrode layers 23A, 24A and 25A are electrically connected to the lower electrode layer 21A via the opening OP of the insulator 22A.

The upper electrode layers 23A, 24A and 25A are formed essentially simultaneously with the control gate electrode CG. The upper electrode layers 23A, 24A and 25A are made of the same material as conductive layers 23, 24 and 25 included in the control gate electrode CG, and have essentially the same film thickness as the control gate electrode CG.

An upper electrode layer SG of the select transistor ST extends along a channel width, and is shared by the select transistors ST arranged in the channel width direction. The upper electrode layers 23A, 24A and 25A function as the selection gate lines SGDL and SGSL.

In the well region 12, diffusion layers 26A as the source/drain of the select transistor ST are provided. In the two diffusion layers 26A of the select transistor ST, the one diffusion layer 26A is shared as the source/drain of the memory cell MC at a dead end of the NAND string. In consequence, the select transistor ST is connected in series with a current path of the NAND string, to form the memory cell unit. Moreover, in the two diffusion layers 26A of each of the select transistors ST, the other diffusion layer 26A is connected to a contact plug CP1. Via the contact plug CP1, one end of the memory cell unit MU is connected to the bit line BL, and the other end of the memory cell unit MU is connected to the source line SL.

On the semiconductor substrate 10, interlayer insulating films 80 and 81 are provided to cover the memory cells MC and the select transistors ST. The interlayer insulating films 80 and 81 are, for example, silicon oxide films.

The contact plug CP1 is formed in a contact hole formed in the interlayer insulating film 80. The contact plug CP1 comes in contact with the upper surface of the diffusion layer 26A of the select transistor ST.

For example, a side well insulating film (not shown) is provided on the side surface of the gate electrode SEG of the select transistor ST in the channel length direction of the transistor.

A metal layer M0 is provided on the interlayer insulating film 80 and the contact plug CP1. The metal layer M0 is electrically connected to the contact plug CP1.

When the contact plug CP1 is connected to the drain-side select transistor ST of the memory cell unit MU, a via plug VP is connected to the metal layer M0. The via plug VP is buried in a contact hole of the interlayer insulating film 81. The bit line BL extending in the channel length direction is provided on the interlayer insulating film 81 and the via plug VP. The bit line BL is connected to the drain-side select transistor via the via plug VP, the metal layer (an intermediate interconnect) M0 and the contact plug CP1.

The bit line BL is provided at a position which overlaps with the active area AA in the direction vertical to the substrate surface, above the active area AA.

On the source side of the memory cell unit MU, a source-side select transistor (not shown) is connected to a contact plug (not shown) buried in the interlayer insulating film 80, and the contact plug is connected to a metal layer at the same interconnect level as the intermediate interconnect M0. The metal layer functions as a source line, and extends in the channel width direction.

In the present embodiment, the interconnect level indicates a position (a height) in the direction vertical to the substrate surface on the basis of the surface of the semiconductor substrate 10.

As to two memory cell units arranged in the channel length direction, the memory cell units MU are formed on the active areas AA, respectively, so that two drain-side select transistors ST1 face each other via the contact plug CP1 in the channel length direction. The two drain-side select transistors ST1 share the plugs CP and VP and the metal layers M0 and BL.

Furthermore, as to the source-side select transistors ST2, the two select transistors ST2 facing each other via the contact plug in the channel length direction share a plug and a metal layer. In consequence, the reduction of an occupying area of the memory cell unit in the memory cell array 2 is achieved.

The gate structure of the select transistor ST is different from the gate structure of the memory cell MC in that the upper electrode layers 23A, 24A and 25A extend through the opening OP formed through the insulator 22A to come in contact with the lower electrode layer 21A. In consequence, the upper electrode layer SG is electrically connected to the lower electrode layer 21A in the select transistor ST.

For example, in the example shown in FIG. 4, the upper electrode layers 23A, 24A and 25A include three conductive layers 23A, 24A and 25A. For example, among the three conductive layers in the upper electrode layers 23A, 24A and 25A, an opening is formed in the lowermost conductive layer (a polysilicon layer) 23A by the EI step. The intermediate conductive layer (e.g., the polysilicon layer or the silicide layer) 24A comes in contact with the lower electrode layer 21A via the opening OP in the conductive layer 23A and the insulator 22A. The uppermost conductive layer 25A of the upper electrode layers is, for example, the silicide layer or a metal layer.

For example, a channel length of the select transistor ST is larger than that of the memory cell MC.

A structure of the low breakdown voltage transistor will be described with reference to (b) of FIG. 3 and FIG. 5. As described above, the peripheral circuit includes the low breakdown voltage transistor LT and the high breakdown voltage transistor HT as the peripheral transistors. The low breakdown voltage transistor LT having a low junction breakdown voltage, a low surface breakdown voltage and a low gate breakdown voltage is driven with a driving voltage of, for example, about 1 V to 7 V. The low breakdown voltage transistor LT has a gate structure similar to the select transistor ST.

As shown in (b) of FIG. 3, (a) of FIG. 5 and (b) of FIG. 5, the low breakdown voltage transistor LT is provided in an active area AAL defined by an isolation area STIL in the low breakdown voltage transistor forming area LA. The active area AAL is surrounded with the isolation area STIL.

In the isolation area STIL, an isolation insulating film 15L is buried. In the active area AAL, a well region 12L is provided. The conductivity type of the well region 12L is set to one of a p-type and an n-type depending on whether the low breakdown voltage transistor LT is of an n-channel type or a p-channel type.

A gate insulating film 20L of the low breakdown voltage transistor LT is provided on the surface of the well region 12L. The gate insulating film 20L of the low breakdown voltage transistor LT is formed substantially simultaneously with, for example, the gate insulating films 20 and 20A of the memory cell MC and the select transistor ST. In this case, the gate insulating film 20L of the low breakdown voltage transistor LT is made of the same material as the gate insulating films 20 and 20A of the memory cell MC and the select transistor ST, and has the same film thickness as the gate insulating films 20 and 20A. The film thickness of the gate insulating film 20L of the low breakdown voltage transistor may be larger than or may be smaller than that of the gate insulating films 20 and 20A of the memory cell MC and the select transistor ST. When the film thickness of the gate insulating film 20L of the low breakdown voltage transistor is set to be larger than that of the gate insulating film 20 of the memory cell MC, the gate insulating film 20L of the low breakdown voltage transistor is formed by a step different from a step of forming the gate insulating film 20 of the memory cell MC. Moreover, a material of the gate insulating film 20L of the low breakdown voltage transistor may be different from a material of the gate insulating films 20 and 20A of the memory cell MC and the select transistor ST.

A gate electrode LG of the low breakdown voltage transistor LT is provided on the gate insulating film 20L. The gate electrode LG of the low breakdown voltage transistor LT has a gate structure where a lower electrode layer 21L and upper electrode layers 23L, 24L and 25L are laminated via an insulator 22L having an opening OP in the same manner as in the select transistor ST.

The lower electrode layer 21L of the gate electrode LG of the low breakdown voltage transistor LT is provided on the gate insulating film 20L. On the lower electrode layer 21L of the low breakdown voltage transistor LT, the insulator 22L having the opening OP is provided. The upper electrode layer including the conductive layers 23L, 24L and 25L is stacked on the lower electrode layer 21L via the insulator 22L. Part (here, the intermediate conductive layer 24L) of the upper electrode layers 23L, 24L and 25L extends through the opening OP, and is connected to the lower electrode layer 21L.

Diffusion layers 26L are provided as a source and a drain of the low breakdown voltage transistor LT in the well region 12L, respectively. The conductivity type of the diffusion layer 26L as the source/drain is suitably set depending on whether the low breakdown voltage transistor LT is of the p-channel type or the n-channel type.

The diffusion layer 26L is connected to a contact plug CPL1. The contact plug CPL1 is buried in the contact hole formed in the interlayer insulating film 80. On the contact plug CPL1 and the interlayer insulating film 80, an interconnect (wiring line) ML1 is provided. The interconnect ML1 is positioned at the same interconnect level as the intermediate interconnect M0 in the memory cell array 2. The interconnect ML1 is further connected to an interconnect provided at the interconnect level of the upper layer via a via plug (not shown) to form a predetermined circuit. Moreover, the gate electrode LG of the low breakdown voltage transistor LT is connected to a contact plug CPL2. The contact plug CPL2 is connected to an interconnect ML2.

For example, a gate length and gate width of the low breakdown voltage transistor LT are set to be not smaller than those of the select transistor ST.

A structure of the high breakdown voltage transistor will be described with reference to (c) of FIG. 3 and FIG. 6. The high breakdown voltage transistor HT having a high junction breakdown voltage, a high surface breakdown voltage and a high gate breakdown voltage is driven with a driving voltage of, for example, about 10 V to 25 V. The high breakdown voltage transistor HT has a gate structure similar to the low breakdown voltage transistor LT or the select transistor ST.

As shown in (c) of FIG. 3 and (a) of FIG. 6, and (b) of FIG. 6, the high breakdown voltage transistor HT is provided in an active area AAH defined by an isolation area STIR in the high breakdown voltage transistor forming area HA. The active area AAH is surrounded with the isolation area STIR.

In the isolation area STIR, an isolation insulating film 15H is buried. For example, in the active area AAH where the high breakdown voltage transistor HT is provided, no well region is provided. For example, the active area AAH is an intrinsic area which hardly includes impurities for imparting conductivity. However, in the active area AAH, there may be provided a well region having an impurity concentration lower than that of the well region 12 in the memory cell array 2 or a well region having an impurity concentration lower than that of the well region 12L in the low breakdown voltage transistor forming area LA.

A gate insulating film 20H of the high breakdown voltage transistor HT is provided on the surface of the semiconductor substrate 10. The gate insulating film 20H of the high breakdown voltage transistor HT has a larger film thickness than the gate insulating films 20, 20A and 20L of the memory cell MC, the select transistor ST and the low breakdown voltage transistor LT. In consequence, the high breakdown voltage transistor HT acquires a high insulation resistance as compared with the other transistors MC, ST and LT. The gate insulating film 20H of the high breakdown voltage transistor HT is formed in a step different from, for example, a step of forming the gate insulating films 20, 20A and 20L of the memory cell MC, the select transistor ST and the low breakdown voltage transistor LT. For example, the gate insulating film 20H of the high breakdown voltage transistor HT may be made of a material different from the material of the gate insulating films 20, 20A and 20L of the other transistors MC, ST and LT.

The gate electrode HG is provided on a gate insulating film 21H of the high breakdown voltage transistor HT. The high breakdown voltage transistor HT has a larger gate length and gate width than the select transistor ST and the low breakdown voltage transistor LT, to acquire the high insulation resistance and transfer a high voltage (e.g., 25 V) to the word line WL.

The gate electrode HG of the high breakdown voltage transistor HT has a gate structure where the lower electrode layer 21H and upper electrode layers 23H, 24H and 25H are stacked via an insulator 22H in the same manner as in the select transistor ST and the low breakdown voltage transistor LT.

The lower electrode layer 21H included in the gate electrode HG of the high breakdown voltage transistor HT is provided on the gate insulating film 20H. As shown in (b) of FIG. 6, the side surface of the lower electrode layer 21H in the channel width direction comes in contact with the side surface of the isolation insulating film 15H.

On the lower electrode layer 21H of the high breakdown voltage transistor HT, the insulator 22H having an opening OP is provided. As shown in (a) of FIG. 6, for example, two openings OP are formed through the insulator 22H in the high breakdown voltage transistor HT.

The upper electrode layer of the high breakdown voltage transistor HT is a laminate of the conductive layers 23H, 24H and 25H in the same manner as in the control gate electrode CG. The upper electrode layer of the high breakdown voltage transistor HT includes the three conductive layers 23H, 24H and 25H. Part (here, the intermediate conductive layer 24H) of the upper electrode layers 23H, 24H and 25H extends through the opening OP, and is connected to the lower electrode layer 21H.

As shown in (a) of FIG. 6 and (b) of FIG. 6, the openings are provided in the lowermost conductive layer 23H of the upper electrode layers. On the lowermost conductive layer 23H, the second (intermediate) conductive layer 24H is provided. The conductive layer 24H extends through the openings OP formed through the lower conductive layer 23H and the insulator 22H to come in contact with the lower electrode layer 21H. The openings of the conductive layer 23H are formed simultaneously with the openings of the insulator 22H.

For example, a side wall insulating film (not shown) is provided on the side surface of the gate electrode of the high breakdown voltage transistor HT in the channel length direction of the transistor.

The lower electrode layers 21L and 21H of the high and low breakdown voltage transistors HT and LT are formed essentially simultaneously with the floating gate electrode 21. Therefore, in the high and low breakdown voltage transistors HT and LT, the lower electrode layers 21L and 21H are made of the same material (e.g., polysilicon) as the floating gate electrode 21, and have about the same film thickness as the floating gate electrode 21.

The insulators 22L and 22H of the high and low breakdown voltage transistors HT and LT are made of the same material as the inter-gate insulating film 22, and have about the same film thickness as the inter-gate insulating film 22. The openings OP of the insulators 22L and 22H are formed by the EI step.

In the high and low breakdown voltage transistors HT and LT, the respective conductive layers 23H, 24H, 25H, 23L, 24L and 25L of the upper electrode layers use the same material as the respective conductive layers 23, 24 and 25 of the control gate electrode CG. Moreover, the film thicknesses of the respective conductive layers 23H, 24H, 25H, 23L, 24L and 25L of the upper electrode layer are about the same as the film thicknesses of the respective conductive layers 23, 24 and 25 of the control gate electrode CG, respectively.

For example, among the three conductive layers 23H, 24H and 25H or 23L, 24L and 25L included in the upper electrode layer, the lowermost conductive layers 23H and 23L are formed of polysilicon layers. The intermediate conductive layers 24H and 24L are formed of, for example, silicon layers. The uppermost conductive layers 25H and 25L are formed of silicide layers. It is to be noted that in accordance with a material for use in the control gate electrode CG, the uppermost conductive layers 25H and 25L of the high and low breakdown voltage transistors HT and LT may be metal layers, and the intermediate conductive layers 24H and 24L thereof may be silicide layers. Moreover, the whole upper electrode layer may be the silicide layer.

As shown in (c) of FIG. 3 and (b) of FIG. 6, the upper electrode layers 23H, 24H and 25H of the high breakdown voltage transistor are drawn from the active area AAH into the isolation area STIH in the channel width direction of the transistor. A portion GF of the upper electrode layers 23H, 24H and 25H drawn to the isolation area STIH is disposed above the isolation insulating film 15H via the insulator 22H. Hereinafter, the portion GF of the upper electrode layers 23H, 24H and 25H above the isolation insulating film 15H is called the gate fringe portion GF.

The gate fringe portion GF is provided on the isolation insulating film 15H in the channel width direction of the transistor HT. The gate fringe portion GF and the transistor gate electrode HG are continued as one conductor, and the gate fringe portion GF is electrically connected to the gate electrode HG.

It is to be noted that also in the low breakdown voltage transistor LT, the lower electrode layer 21L comes in contact with the side surface of the isolation insulating film 15L in the channel width direction of the transistor, and the upper electrode layers 23L, 24L and 25L include the gate fringe portion GF, in the same manner as in the high breakdown voltage transistor HT.

Two diffusion layers 26H are provided as a source and a drain of the high breakdown voltage transistor HT in the semiconductor substrate 10 of the high breakdown voltage transistor forming area HA. The conductivity type of each of the diffusion layers 268 is suitably set depending on whether the high breakdown voltage transistor HT is of the p-channel type or the n-channel type.

The diffusion layer 26H is connected to a contact plug CPH1. The contact plug CPH1 is buried in the contact hole formed in the interlayer insulating film 80. On the contact plug CPH1 and the interlayer insulating film 80, an interconnect MH1 is provided. The interconnect MH1 is positioned at the same interconnect level as the intermediate interconnect M0 in the memory cell array 2. The interconnect MH1 is connected to an interconnect provided at the interconnect level of the upper layer via a via plug (not shown) to form a predetermined circuit. Moreover, the gate electrode HG of the high breakdown voltage transistor HT is connected to a contact plug CPH2. The contact plug CPH2 is connected to a interconnect MH2. The contact plug CPH2 is disposed, for example, above the isolation insulating film 15H.

The gate electrode HG includes the gate fringe portion GF, and the gate electrode HG is formed to bridge the isolation insulating films 15H which face each other in the channel width direction, whereby the diffusion layers 26H can be formed in a self-aligning manner by use of the gate electrode HG as a mask.

As shown in (c) of FIG. 3 and FIG. 6, the shield gate electrode SIG is provided in the isolation area STIR which surrounds the active area AAH in the high breakdown voltage transistor forming area HA in the flash memory of the present embodiment. The shield gate electrode SIG has a lattice-like plane layout in the high breakdown voltage transistor forming area HA, and is common to the high breakdown voltage transistors HT.

The shield gate electrode SIG is provided on the isolation insulating film 15H. The shield gate electrode SIG is adjacent to the gate fringe portion GF of the high breakdown voltage transistor HT on the isolation insulating film 15H. The shield gate electrode SIG is provided between the gate fringe portions GF of two high breakdown voltage transistors HT adjacent in the channel width direction.

The shield gate electrode SIG includes, for example, conductive layers 23S, 24S and 25S in the same manner as in the control gate electrode CG and the upper electrode layers of the respective transistors ST, HT and LT. For example, the shield gate electrode SIG includes the three conductive layers 23S, 24S and 25S. The shield gate electrode SIG includes the lowermost polysilicon layer 23S, the second polysilicon layer (or the silicide layer) 24S, and the uppermost silicide layer (or the metal layer) 25S. For example, a material and a film thickness of the respective conductive layers (also called the shield gate conductive layers) 23S, 24S and 25S included in the shield gate electrode SIG are the same as those of the control gate electrode CG and the upper electrode layers 23H, 24H and 25H of the respective transistors.

In the direction vertical to the semiconductor substrate surface, a position of an upper portion of the shield gate electrode SIG is set to be essentially the same as a position of the upper surface of the gate electrode HG. In consequence, the flatness of the upper surface of the interlayer insulating film 80 can be enhanced.

In the present embodiment, part of the shield gate electrode SIG is buried in a recess RC1 provided in the isolation insulating film 15H. Hereinafter, a portion BB buried in the recess RC1 of the shield gate electrode SIG will be called the buried portion BB. In the present embodiment, the recess RC1 provided with the buried portion BB of the shield gate electrode SIG is formed by the EI step. A forming area of the recess RC1 corresponds to the EI area.

In the direction vertical to the surface of the semiconductor substrate 10, a film thickness D1 of the isolation insulating film 15 between the buried portion BB of the shield gate electrode SIG and the semiconductor region 10 is smaller than a film thickness D2 of the isolation insulating film 15H between the gate fringe portion GF and the semiconductor region 10.

For example, in the present embodiment, an insulator (also called a shield gate insulating layer) 22S is provided between a bottom portion (the bottom surface) of the lowermost conductive layer 23S and an upper portion (the upper surface) of the isolation insulating film 15H. The insulator 22S is provided with an opening OP. The lowermost conductive layer 23S of the shield gate electrode SIG includes an opening OP. Moreover, the intermediate conductive layer 24S of the shield gate electrode SIG is provided as the buried portion BB in the recess RC1. The buried portion BB comes in contact directly with the isolation insulating film 15H.

The openings OP of the insulator 22S and the lowermost conductive layer 23S are formed by the EI step. It is to be noted that the insulator 22S is made of the same material as the inter-gate insulating film 22, and has the same film thickness as the inter-gate insulating film 22.

In the present embodiment, as shown in FIG. 3(c) and FIG. 6, an interconnect width W1 of the shield gate electrode SIG on the upper portion of the isolation insulating film 15H is larger than a width W2 of the recess RC1 in which part of the shield gate electrode SIG is buried. In this case, the interconnect width W1 of the upper portion of the shield gate electrode SIG is larger than the interconnect width W2 of the buried portion BB of the shield gate electrode SIG.

When the flash memory is driven, a predetermined potential is applied to the shield gate electrode SIG. The potential of the shield gate electrode SIG is controlled by, for example, the shield gate driver 35. When the high breakdown voltage transistor HT is driven, 0 V or a negative bias is applied to the shield gate electrode SIG.

In the flash memory of the present embodiment, the upper electrode layers 23H, 24H and 25H of the gate electrode HG of the high breakdown voltage transistor HT extend from the active area AAH into the isolation area STIH. The gate fringe portion GF of the upper electrode layer is disposed above the semiconductor region (the semiconductor substrate) 10 via the isolation insulating film 15H. When a high voltage is applied to the gate electrode HG of the high breakdown voltage transistor HT, a weak inversion layer (a channel) is formed sometimes in the semiconductor region 10 under the gate fringe portion GF owing to an MOS structure including the gate fringe portion GF, the isolation insulating film 15H and the semiconductor region 10.

In the present embodiment, the shield gate electrode SIG is provided between the gate fringe portions GF on the isolation insulating film 15H. When the high breakdown voltage transistor HT is driven, 0 V or a negative bias voltage is applied to the shield gate electrode SIG. Under the shield gate electrode SIG, the weak inversion layers generated along the bottom portion of the isolation insulating film 15H under the gate fringe portions GF to which the high voltage is applied can be prevented from being connected to each other between the high breakdown voltage transistors HT adjacent in the channel width direction, by the shield gate electrode SIG.

In consequence, it is possible to suppress the generation of a leak current between the high breakdown voltage transistors HT adjacent in the channel width direction due to the inversion layer formed under the isolation insulating film 15H.

It is to be noted that in the present embodiment, when the shield gate electrode SIG is provided on the isolation insulating film 15H to be adjacent to the gate fringe portion GE of the high breakdown voltage transistor HT, the shield gate electrode does not have to be provided on the isolation insulating film 15H adjacent to the active area AA in the channel length direction of the transistor HT. In this case, the shield gate electrode SIG has a linear plane structure extending in the channel length direction of the transistor HT.

In the flash memory as the semiconductor memory of the present embodiment, the shield gate electrode SIG is provided on the isolation insulating film 15H which surrounds the forming area HA of the high breakdown voltage transistor HT.

The bottom portion of the shield gate electrode SIG is positioned on the bottom side of the semiconductor substrate 10 as compared with the position of the highest portion of the upper surface of the isolation insulating film 15H in the direction vertical to the surface of the semiconductor substrate 10. For example, the bottom portion of the shield gate electrode SIG is positioned more closely to the bottom side of the semiconductor substrate 10 and the isolation insulating film 15H than the bottom portion of the gate electrode (the gate fringe portion) GF of the high breakdown voltage transistor HT drawn onto the isolation insulating film 15H, in the direction vertical to the surface of the semiconductor substrate 10. The bottom portion of the shield gate electrode SIG is positioned more closely to the bottom side of the semiconductor substrate 10 than the upper portion of the lower electrode layer 21H of the high breakdown voltage transistor HT.

It is to be noted that the bottom portion of the shield gate electrode SIG may be positioned more closely to the bottom side of the semiconductor substrate 10 than the bottom portion of the lower electrode layer 21H of the high breakdown voltage transistor HT (the upper portion of the gate insulating film 20H) or the bottom portion of the gate insulating film 20H of the high breakdown voltage transistor HT.

For example, the shield gate electrode SIG includes the buried portion BB buried in the recess RC1 formed in the isolation insulating film 15H.

When the shield gate electrode SIG includes the portion BB buried in the isolation insulating film 15H in this manner, the distance (the film thickness of the isolation insulating film) D1 between the shield gate electrode SIG and the semiconductor region under the isolation insulating film 15H becomes smaller than the distance (the film thickness of the isolation insulating film) D2 between the gate fringe portion GF of the high breakdown voltage transistor HT on the isolation insulating film 15H and the semiconductor region 10 under the isolation insulating film 15H.

In consequence, as compared with a structure where the bottom portion of the shield gate electrode SIG is positioned at the same height as the bottom portion of the gate fringe portion GF on the isolation insulating film 15H, the flash memory of the present embodiment has a larger effect of suppressing the formation of the inversion layer under the isolation insulating film 15H by the shield gate electrode SIG when the high breakdown voltage transistor HT is driven.

Furthermore, in the flash memory of the present embodiment, the recess RC1, in which part of the shield gate electrode SIG is buried, is formed simultaneously with the openings OP of the insulator (the inter-gate insulating film) 22H between the upper electrode layers 23H, 24H and 25H and the lower electrode layer 21H of the transistor HT. In consequence, a step of forming the recess RC1 in which the shield gate electrode SIG is buried (a step of decreasing the thickness of the isolation insulating film 15H of the forming area of the shield gate electrode SIG) can be common to a step of forming the openings OP through the insulator 22H. Therefore, there can be provided the flash memory which can suppress the formation of the inversion layer under the isolation insulating film 15H without increasing the number of the manufacturing steps.

As described above, according to the semiconductor memory of the first embodiment, it is possible to provide the semiconductor memory in which leak between the elements can be decreased and operation characteristics can be enhanced.

(b) Manufacturing Method

A manufacturing method of the semiconductor memory of the first embodiment (e.g., the flash memory) will be described with reference to FIG. 3 to FIG. 19.

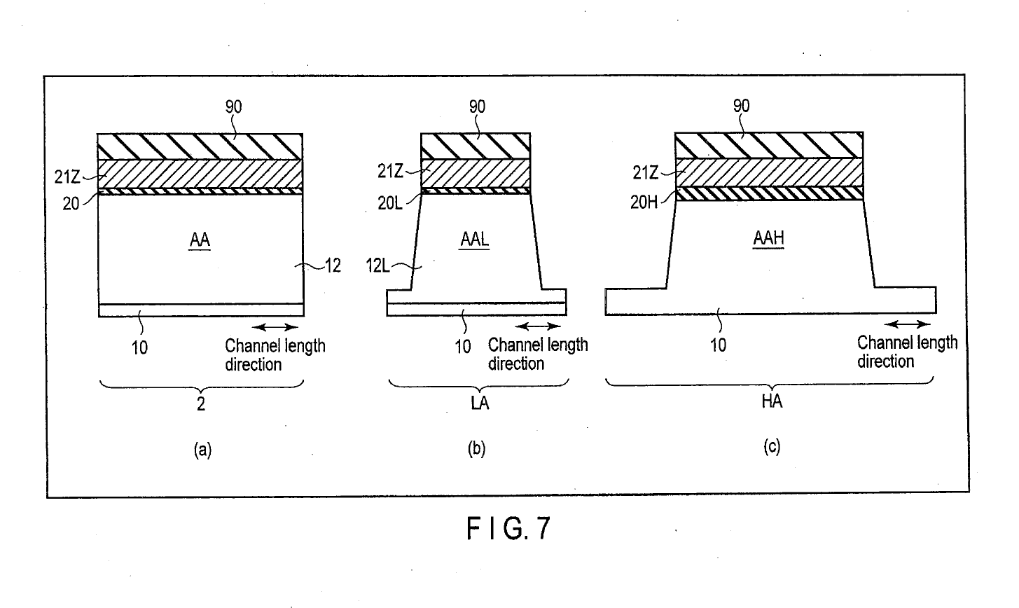

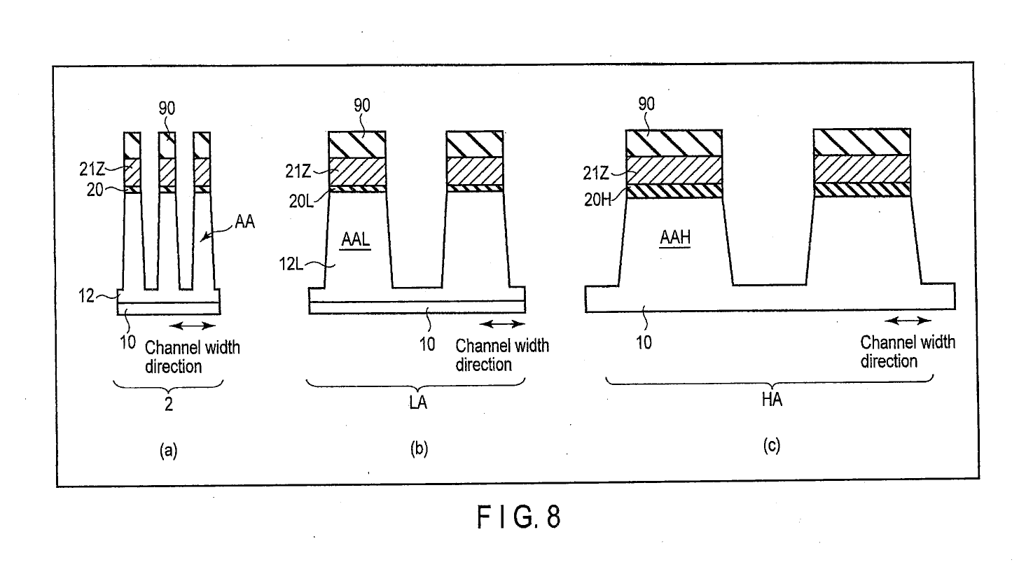

One process of the manufacturing method of the flash memory of the present embodiment will be described with reference to FIG. 7 and FIG. 8. FIG. 7 is a view showing the process for sections of the memory cell and the peripheral transistors along the channel length direction. FIG. 8 is a view showing the process for the sections of the memory cell and the peripheral transistors along the channel width direction. (a) of FIG. 7 and (a) of FIG. 8 show sectional step views of the memory cell. (b) of FIG. 7 and (b) of FIG. 8 show sectional step views of the low breakdown voltage transistor. (c) of FIG. 7 and (c) of FIG. 8 show sectional step views of the high breakdown voltage transistor. Hereinafter, when the forming area of the high breakdown voltage transistor is not distinguished from the forming area of the low breakdown voltage transistor, the forming areas will be called the peripheral transistor forming areas.

As shown in FIG. 7 and FIG. 8, in the memory cell array 2 and the peripheral transistor forming areas HA and LA, the well regions 12 and 12L having a predetermined impurity concentration are formed in the semiconductor substrate 10 (e.g., the silicon substrate), respectively, by, for example, an ion implantation step. For example, in the high breakdown voltage transistor forming area HA, no well region is formed, and the intrinsic area which hardly contains the impurities is provided in the high breakdown voltage transistor forming area HA. However, sometimes, the well region of the high breakdown voltage transistor forming area HA is formed, which makes the impurity concentration of the well region of the high breakdown voltage transistor forming area HA lower than the impurity concentration of the well region 12 in the memory cell array 2 or the impurity concentration of the well region 12L in the low breakdown voltage transistor forming area LA.

On the surface of the semiconductor substrate 10 of the high breakdown voltage transistor forming area HA, a silicon oxide film as the gate insulating film 20H of the high breakdown voltage transistor is formed by, for example, a thermal oxidation process. By this thermal oxidation step, the oxide film formed in the memory cell array 2 and the low breakdown voltage transistor forming area LA is removed by using a photolithography technology and a reactive ion etching (RIE) process.

On the surface of the semiconductor substrate 10 exposed in the memory cell array 2 and the low breakdown voltage transistor forming area, new oxide films 20 and 20L are formed by, for example, a thermal oxidation treatment. The oxide film formed in the memory cell array 2 is used as the gate insulating film (the tunnel insulating film) 20 of the memory cell and the gate insulating film 20 of the select transistor ST. The oxide film 20L formed in the low breakdown voltage transistor forming area is used as the gate insulating film 20L of the low breakdown voltage transistor.

It is to be noted that the oxide film 20H in the high breakdown voltage transistor forming area HA is subjected to a second thermal oxidation treatment by the thermal oxidation treatment for the memory cell array 2 and the low breakdown voltage transistor forming area LA. By the thermal oxidation treatments, the film thickness of the oxide film 20H in the high breakdown voltage transistor forming area HA further increases. Time and temperature of the first thermal treatment are preferably set in consideration of the gate insulating film 20H of the high breakdown voltage transistor which is subjected to at least two thermal treatments and in accordance with the characteristics desired of the transistor.

A polysilicon layer (a charge storage layer) 21Z is deposited on the oxide films 20, 20L and 20H in the memory cell array 2 and the peripheral transistor forming areas HA and LA by, for example, a chemical vapor deposition (CVD) process. The polysilicon layer 21Z is used as the floating gate electrode of the memory cell and as the lower electrode layers of the select transistor and the peripheral transistor.

A silicon nitride film 90 as a hard mask is deposited on the polysilicon layer 21Z by, for example, the CVD process. The silicon nitride film 90 is patterned into a predetermined active area shape by a lithography technology and the reactive ion etching (RIE) process.

In the memory cell array 2 and the peripheral transistor forming areas HA and LA, the polysilicon layer 21Z, the oxide films 20, 20L and 20H and the semiconductor substrate 10 are successively etched by, for example, the RIE process by use of the silicon nitride film 90 patterned into the predetermined shape as the mask. In consequence, a groove (an isolation trench) is formed in the semiconductor substrate 10.

In the memory cell array 2, the linear active area AA is formed. The active area and the isolation trench extend in the channel length direction (a column direction) of the transistor. The active area AA and the isolation trench form the line-and-space layout in the memory cell array 2.

Furthermore, in the high breakdown voltage transistor forming area HA and the low breakdown voltage transistor forming area LA, the isolation trenches are formed to surround the active areas AAH and AAL, respectively. Therefore, in the high and low breakdown voltage transistor forming areas HA and LA, the active areas AAH and AAL having a rectangular plane shape are formed, respectively.

On the surface of the semiconductor substrate (the active area) exposed via the trench (groove), a natural oxide film (not shown) or a protective film (not shown) is formed.

It is to be noted that the active area AA of the memory cell array 2 may be processed by a side wall transfer process.

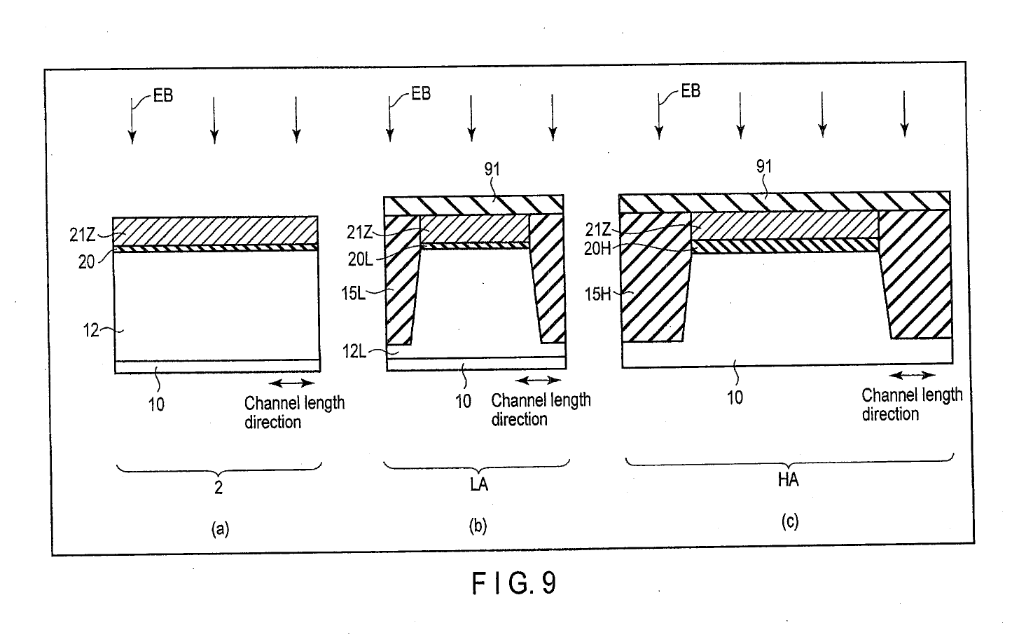

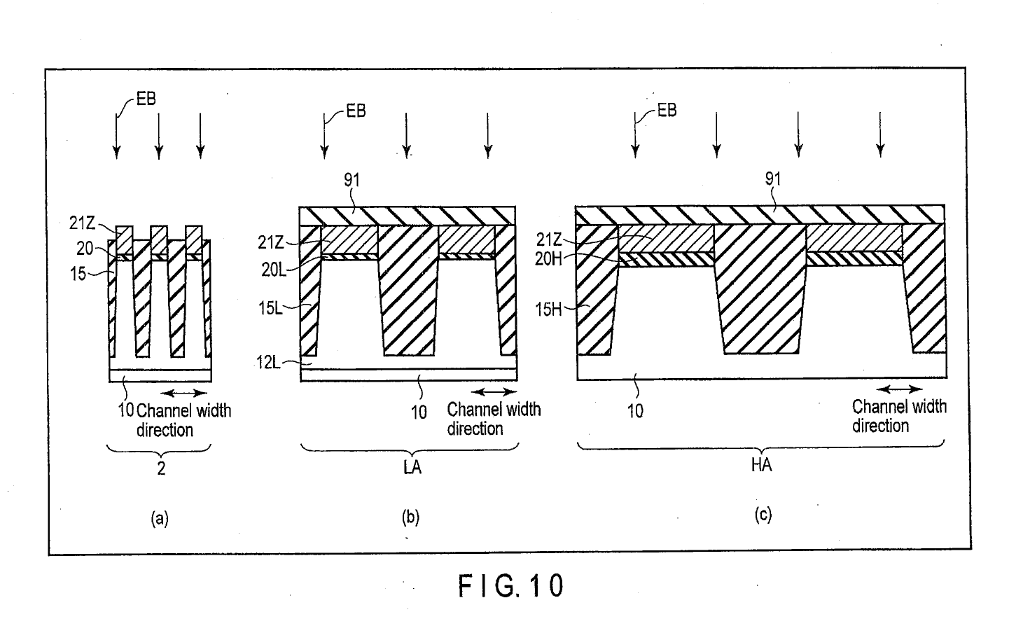

One process of the manufacturing method of the flash memory of the present embodiment will be described with reference to FIG. 9 and FIG. 10. FIG. 9 is a view showing the process for the sections of the memory cell and the peripheral transistors along the channel length direction. FIG. 10 is a view showing the process for the sections of the memory cell and the peripheral transistors along the channel width direction. (a) of FIG. 9 and (a) of FIG. 10 show sectional step views of the memory cell array. (b) of FIG. 9 and (b) of FIG. 10 show sectional step views of the low breakdown voltage transistor. (c) of FIG. 9 and (c) of FIG. 10 show sectional step views of the high breakdown voltage transistor.

As shown in FIG. 9 and FIG. 10, after removing the silicon nitride film (the hard mask) on the polysilicon layer 21Z, a silicon oxide film is formed in the isolation trench and on the polysilicon layer 21Z by, for example, the CVD process or a coating process. The upper surface of the silicon oxide film is subjected to a flattening treatment by etch back or a CMP process by use of, for example, the upper surface of the polysilicon layer 21Z as a stopper. In the isolation trench, the silicon oxide films 15, 15L and 15H as the isolation insulating films of an STI structure are formed. In consequence, the isolation area is formed in the semiconductor substrate 10.

At this time, the upper surface of the polysilicon layer 21Z is exposed. For example, the height of the upper surfaces of the isolation insulating films 15, 151, and 15H substantially matches the height of the upper surface of the polysilicon layer 21Z.

As shown in FIG. 9 and FIG. 10, the isolation insulating films 15, 15L and 15H are buried in the isolation trench, and then the upper surface of the isolation insulating film 15 in the memory cell array 2 is subjected to etch back EB. In the memory cell array 2, the upper surface of the isolation insulating film 15 retreats more closely to the bottom side of the semiconductor substrate 10 than the upper surface of the polysilicon layer 21Z. In the memory cell array 2, part of the side surface of the polysilicon layer 21Z in the channel width direction (the row direction or the x-direction) is exposed. In the following embodiments, an etch back step for retreating the upper surface of the isolation insulating film 15 in the memory cell array 2 will be called the EB step.

In the EB step, for example, the polysilicon layer 21Z and the isolation insulating films 15L and 15H of the peripheral transistor forming areas HA and LA are covered with a mask layer (e.g., a resist mask) 91. In this case, the upper surfaces of the isolation insulating films 15H and 15L of the peripheral transistor forming areas HA and LA do not retreat toward the bottom side of the semiconductor substrate 10.

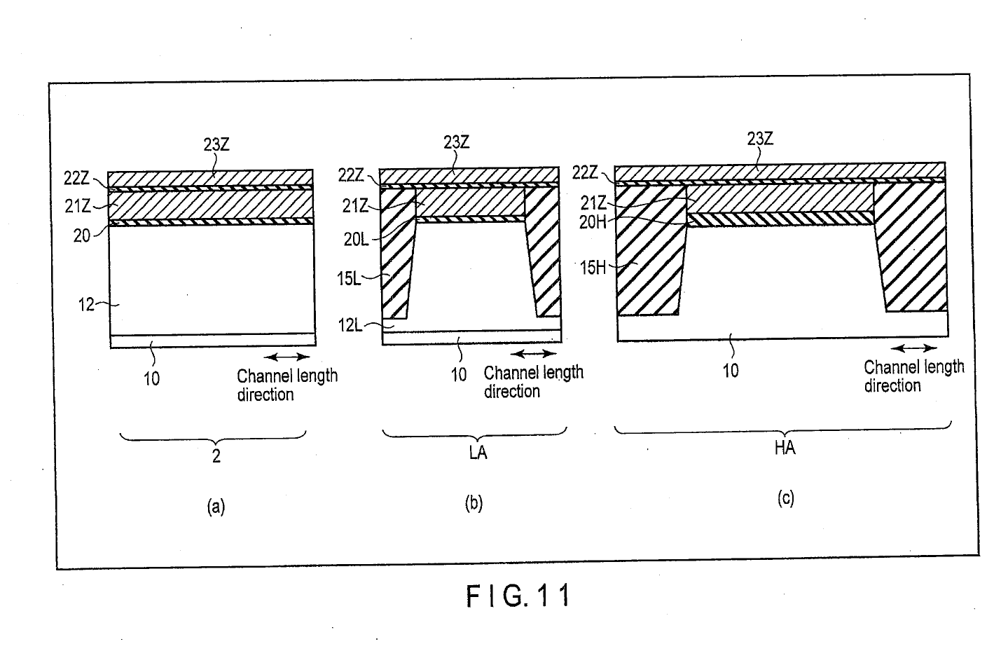

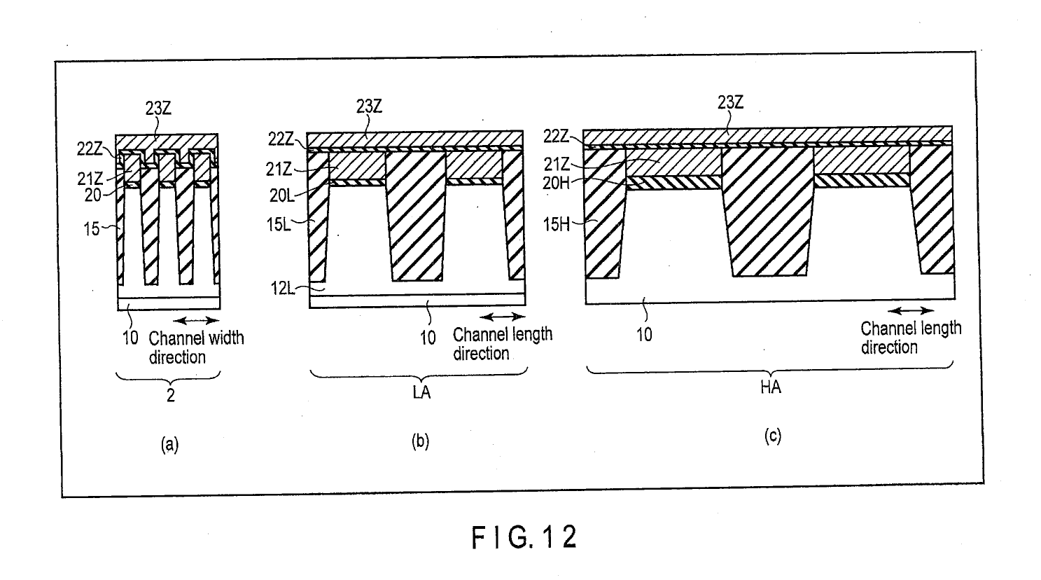

One process of the manufacturing method of the flash memory of the present embodiment will be described with reference to FIG. 11 and FIG. 12. FIG. 11 is a view showing the process for the sections of the memory cell, the high breakdown voltage transistor and the low breakdown voltage transistor along the channel length direction. FIG. 12 is a view showing the process for the sections of the memory cell, the high breakdown voltage transistor and the low breakdown voltage transistor along the channel width direction. (a) of FIG. 11 and (a) of FIG. 12 show sectional step views of the memory cell array. (b) of FIG. 11 and (b) of FIG. 12 show sectional step views of the low breakdown voltage transistor. (c) of FIG. 11 and (c) of FIG. 12 show sectional step views of the high breakdown voltage transistor.

In the memory cell array 2 and the peripheral transistor forming areas HA and LA, an insulator 22Z for forming the inter-gate insulating film of the memory cell is formed on the polysilicon layer 21Z and the isolation insulating films 15, 15L and 15H by, for example, the CVD process. The insulator 22Z is one of a silicon oxide film, a multilayer film including the silicon oxide film and a silicon nitride film, a single layer film of a high-dielectric constant film (a high-k film), and a multilayer film including the high-dielectric constant film. It is to be noted that as shown in (a) of FIG. 12, the insulator 22Z is formed not only on the upper surface of the polysilicon layer 21Z but also on the side surface of the polysilicon layer 21Z in the memory cell array 2.

In the memory cell array 2 and the peripheral transistor forming areas HA and LA, a conductive layer (e.g., a polysilicon layer) 23Z is deposited on the insulator 22Z by, for example, the CVD process. The conductive layer 23Z is used as part (the lowermost conductive layer) of the upper electrode layer included in the control gate electrode of the memory cell and in the gate electrodes of the select transistor and the peripheral transistor. As shown in (a) of FIG. 12, the side surface of the polysilicon layer 21Z is covered with the conductive layer 23Z via the insulator 22Z in the memory cell array 2.

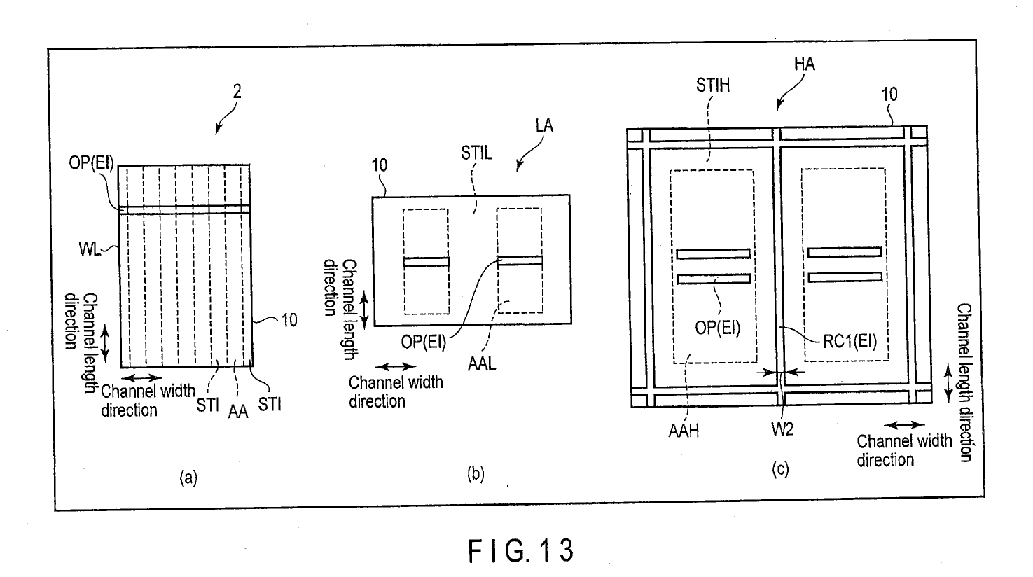

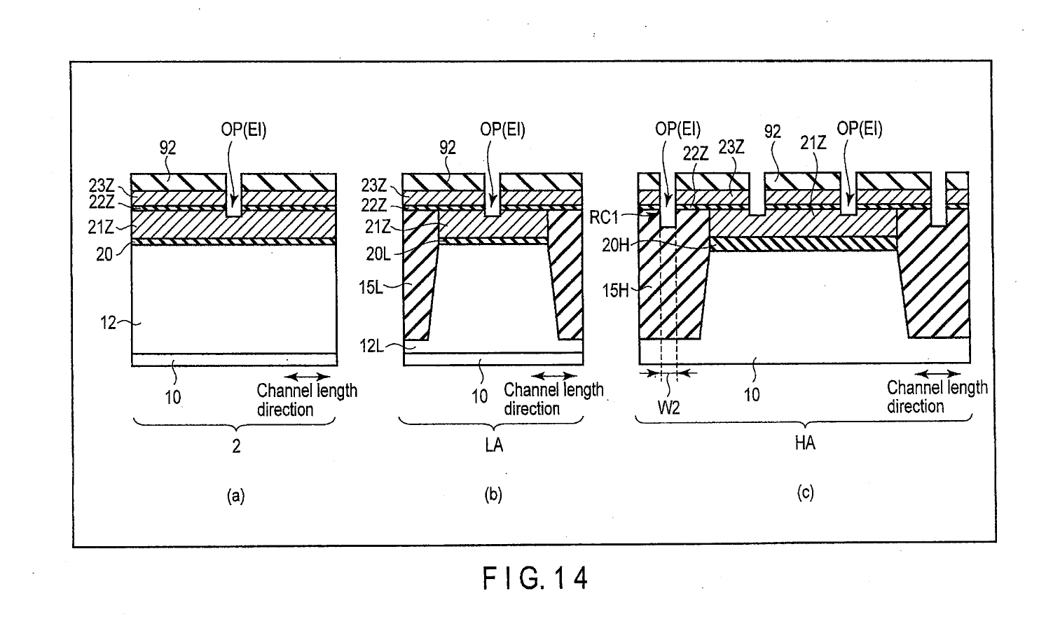

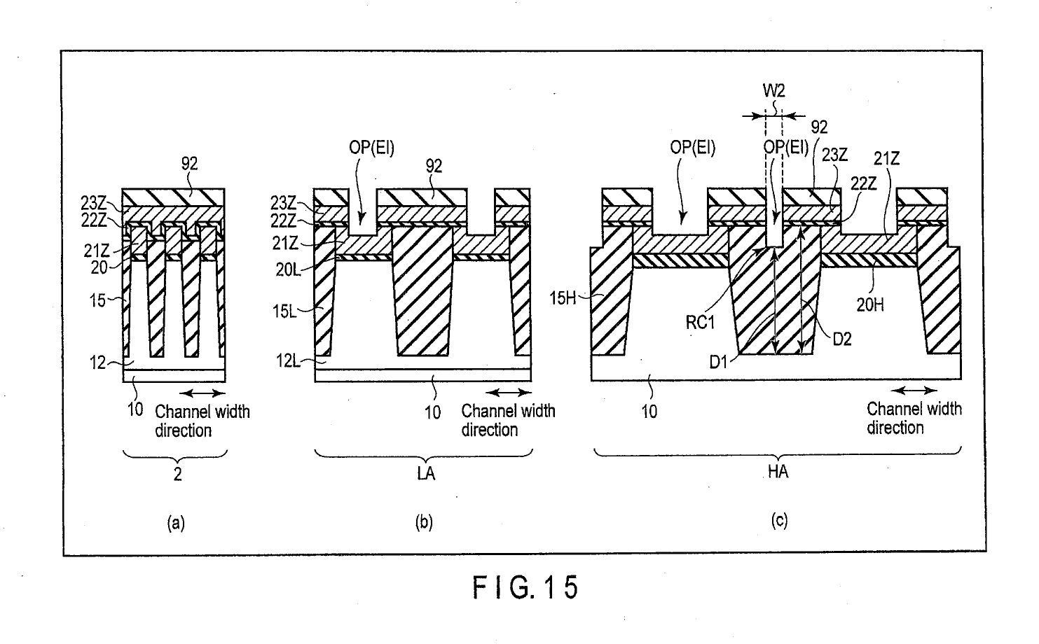

One process of the manufacturing method of the flash memory of the present embodiment will be described with reference to FIG. 13, FIG. 14 and FIG. 15. FIG. 13 is a view showing the process for planes of the memory cell array 2 and the peripheral transistor forming areas HA and LA. FIG. 14 is a view showing the process for the sections of the memory cell and the peripheral transistors along the channel length direction. FIG. 15 is a view showing the process for the sections of the memory cell and the peripheral transistors along the channel width direction. (a) of FIG. 13, (a) of FIG. 14 and (a) of FIG. 15 show planar and sectional step views of the memory cell array. (b) of FIG. 13, (b) of FIG. 14 and (b) of FIG. 15 show sectional step views of the low breakdown voltage transistor. (c) of FIG. 13, (c) of FIG. 14 and (c) of FIG. 15 show the sectional step views of the high breakdown voltage transistor.

As shown in FIG. 13 to FIG. 15, a resist mask 92 is formed on the conductive layer 23Z. In the forming areas of the select transistor and the peripheral transistor, for example, the resist mask 92 on the conductive layer 23Z is patterned to have an opening. Then, an etching step for forming the opening through the insulator 22Z is carried out. In consequence, the etching step for forming the opening through the insulator 22Z having the same constitution as the inter-gate insulating film will be called the EI step in the present embodiment. In opening forming areas (called the EI areas) of the select transistor and peripheral transistor forming areas HA and LA, openings OP are formed through the insulator 22Z. In the present embodiment, the openings OP are formed also through the conductive layer 23Z right under the insulator 22Z.

The upper surface of the polysilicon layer 21Z under the insulator 22Z is exposed via the formed openings OP.

In the manufacturing method of the flash memory of the present embodiment, the opening OP is formed through the insulator 22Z and the conductive layer 23Z in the shield gate forming area in the isolation area STIH which surrounds the high breakdown voltage transistor forming area HA, by the EI step. Additionally, in the shield gate forming area, the upper surface of the isolation insulating film 15H is etched via the opening OP, by the RIE process in the EI step. In consequence, the recess RC1 is formed in the upper surface of the isolation insulating film 15H, in the shield gate forming area.

A bottom portion of the recess RC1 in the isolation insulating film 15H is positioned more closely to the bottom side of the semiconductor substrate 10 than the bottom portion of the trench formed in the polysilicon layer 21Z, in the direction vertical to the surface of the semiconductor substrate 10. The isolation insulating film 15H is etched to acquire an etching selection ratio between the polysilicon layer 21Z and the isolation insulating film 15H, whereby the bottom portion of the recess RC1 may be positioned more closely to the bottom side of the semiconductor substrate 10 than the bottom portion of the polysilicon layer 21Z or the bottom portion of the insulating film 20H.

Here, the width W2 of the opening OP formed by the EI step is smaller than the interconnect width of the formed shield gate electrode in the shield gate forming area of the high breakdown voltage transistor forming area HA.

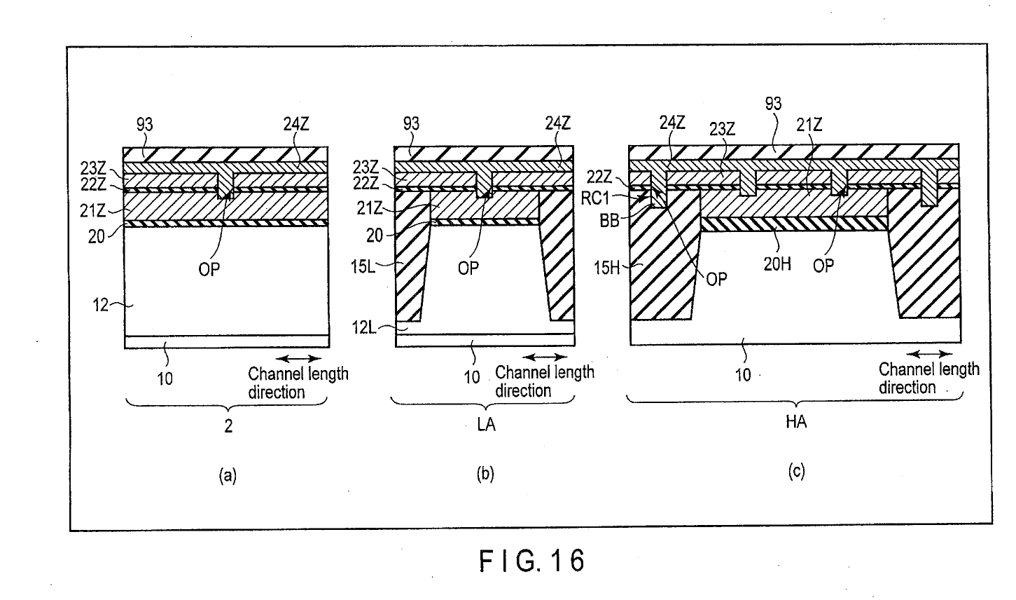

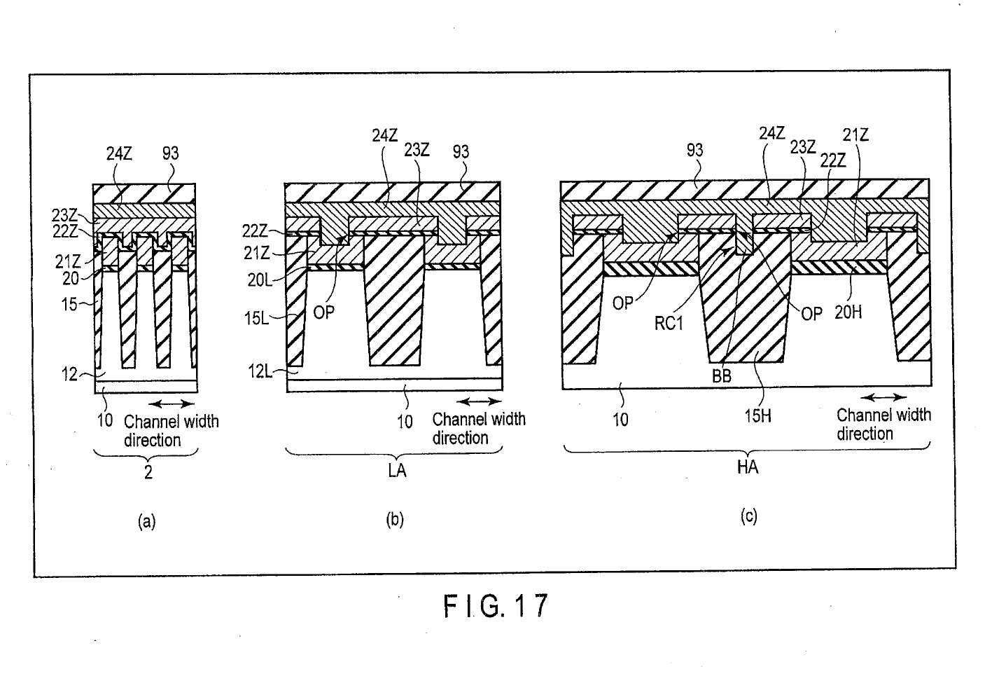

One process of the manufacturing method of the flash memory of the present embodiment will be described with reference to FIG. 16 and FIG. 17. FIG. 16 is a view showing the process for the sections of the memory cell, the high breakdown voltage transistor and the low breakdown voltage transistor along the channel length direction. FIG. 17 is a view showing the process for the sections of the memory cell, the high breakdown voltage transistor and the low breakdown voltage transistor along the channel width direction. (a) of FIG. 16 and (a) of FIG. 17 show sectional step views of the memory cell array. (b) of FIG. 16 and (b) of FIG. 17 show sectional step views of the low breakdown voltage transistor. (c) of FIG. 16 and (c) of FIG. 17 show sectional step views of the high breakdown voltage transistor.

In the EI area of each active area (the element forming area), the opening OP is formed through the insulator 22Z, and then a second conductive layer 24Z is deposited on the conductive layer 23Z. The second conductive layer 24Z is, for example, a polysilicon layer. However, the second conductive layer 24Z may be a metal layer.

Here, the conductive layer 24Z is deposited on the first conductive layer 23Z and the polysilicon layer 21Z so that the conductive layer 24Z comes in contact with the lower polysilicon layer 21Z via the opening OP in the select transistor forming area, the high breakdown voltage transistor forming area HA and the low breakdown voltage transistor forming area LA.

On the other hand, the opening OP made by the EI step is not formed through the insulator (the inter-gate insulating film) 22Z in the memory cell forming area, so that the second conductive layer 24Z is formed only on the first conductive layer 23Z.

When the recess RC1 is formed in the isolation insulating film 15H of the shield gate forming area by the EI step as in the present embodiment, the second conductive layer (e.g., the polysilicon layer) 24Z is buried in the recess RC1 of the isolation insulating film 15H. The buried portion BB of the shield gate electrode is formed in the recess RC1 of the isolation insulating film 15H. When the recess RC1 is formed in the isolation insulating film 15H, the bottom portion of the second conductive layer 24Z in the shield gate forming area, i.e., the bottom portion of the buried portion BB of the shield gate electrode is positioned more closely to the semiconductor substrate side than the bottom portion of the second conductive layer 24Z on the upper surface of the isolation insulating film 15H, in the direction vertical to the surface of the semiconductor substrate 10. Sometimes, the bottom portion of the buried portion BB of the shield gate electrode is positioned more closely to the bottom side of the semiconductor substrate 10 than the bottom portion of the polysilicon layer 21Z or the bottom portion of the gate insulating film 20H, in accordance with a depth of the recess RC1. The bottom portion of the buried portion BB of the shield gate electrode is positioned more closely to the semiconductor substrate 10 side than the highest portion of the upper surface of the isolation insulating film 15H, in the direction vertical to the surface of the semiconductor substrate 10.

For example, an SiN film 93 as a hard mask (the cap layer) is deposited on the second conductive layer 24 by the CVD process.

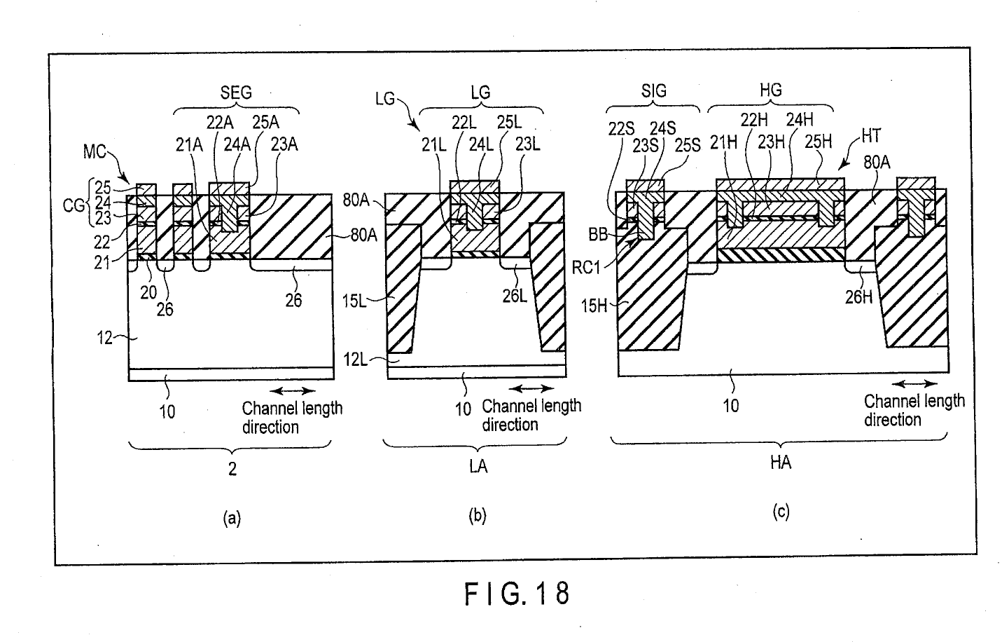

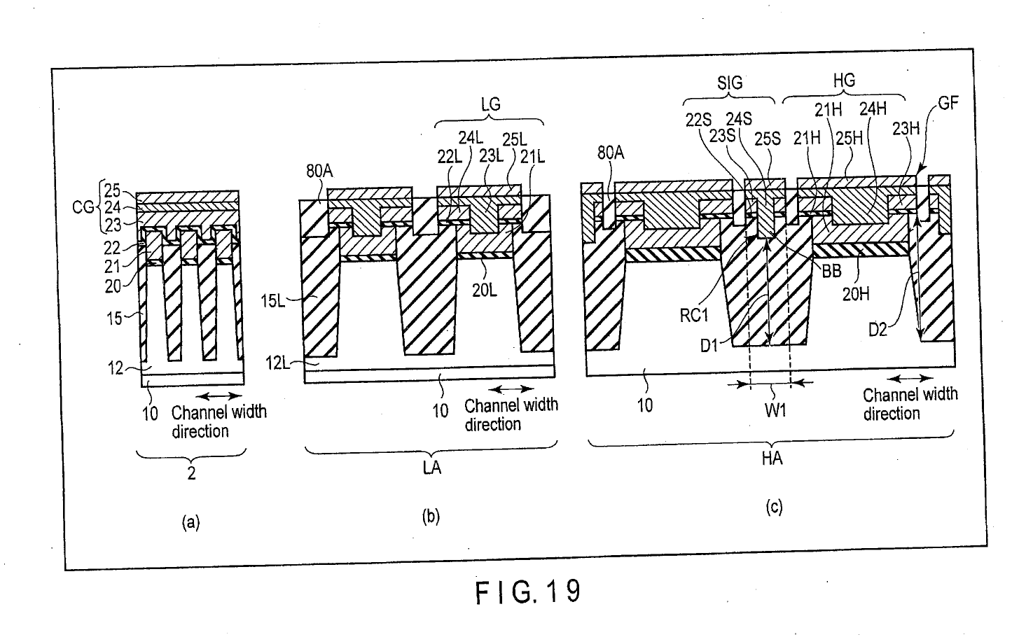

One process of the manufacturing method of the flash memory of the present embodiment will be described with reference to FIG. 18 and FIG. 19. FIG. 18 is a sectional process view of the memory cell and the peripheral transistors along the channel length direction. FIG. 19 is a sectional process view of the memory cell and the peripheral transistors along the channel width direction. (a) of FIG. 18 and (a) of FIG. 19 show sectional step views of the memory cell array. (b) of FIG. 18 and (b) of FIG. 19 show sectional step views of the low breakdown voltage transistor. (c) of FIG. 18 and (c) of FIG. 19 show sectional step views of the high breakdown voltage transistor.

The hard mask 93 of FIG. 16 and FIG. 17 is patterned to correspond to a predetermined gate pattern by the photolithography technology and the RIE process. A stack (the gate stack) for forming the gate electrode of each transistor is subjected to gate processing by use of the patterned cap layer 93 as the mask. That is, the second conductive layer 24Z, the first conductive layer 23Z, the insulator (the inter-gate insulating film) 22Z and the polysilicon layer 21Z are successively etched. It is to be noted that the gate stack in the memory cell array may be processed by the side wall transfer process.

In consequence, as shown in FIG. 18 and FIG. 19, the transistor gate electrodes CG, SEG, LG and HG each having the predetermined gate pattern are formed in the memory cell array 2 and the high and low breakdown voltage transistor areas HA and LA, respectively.

Part of the upper surface of each of the isolation insulating films 15H and 15L is etched by the gate processing. However, a depth of the isolation insulating film 15L or 15H etched by the gate processing may be smaller than that of the recess RC1 formed by the EI step or may be larger than that of the recess RC1.

In the memory cell array 2, the gate electrodes 21, CG and SEG of the memory cells MC and the select transistors ST are formed to obtain the line-and-space layout.

In the peripheral transistor forming areas HA and LA, the gate electrodes HG and LG of the transistors HT and LT are formed to bridge the isolation insulating films 15H and 15L which face each other in the transistor channel width direction. Therefore, one end and the other end of each of the gate electrodes HG and LG of the high and low breakdown voltage transistors HT and LT are provided on the upper surface of each of the isolation insulating films 15H and 15L. The portion on the upper surface of each of the isolation insulating films 15H and 15L in the high and low breakdown voltage transistors HT and LT will be called the gate fringe portion GF.

In the present embodiment, the shield gate electrode SIG is formed in the shield gate forming area of the high breakdown voltage transistor forming area HA simultaneously with the formation of the gate electrodes 21, CG, LG and HG of the transistors. The shield gate electrode SIG is formed adjacent to the gate fringe portion GF of the high breakdown voltage transistor HT on the isolation insulating film 15H.

The diffusion layers 26, 26A, 26L and 26H as the sources/drains are formed in the semiconductor substrate 10 in the self-aligning manner with the gate electrodes 21, CG, LG and HG by use of the formed gate electrodes 21, CG, LG and HG as the masks.

On the side surface of each of the gate electrode of each of the transistors MC, ST, HT and LT and the shield gate electrode SIG, a side wall insulating film (not shown) and a passivation film (not shown) are formed.

After removing the cap layers on the gate electrodes 21, CG, HG and LG and on the shield gate electrode SIG, an interlayer insulating film 80A is deposited on the semiconductor substrate 10 to cover the gate electrodes 21, CG, HG and LG and the shield gate electrode SIG.

For example, the upper surface of the interlayer insulating film 80A is removed by, for example, the CMP step or the etching, to expose the upper surfaces of the second conductive layers 24, 24A, 24H and 24L. A metal film for forming a silicide layer is deposited on the exposed upper surfaces of the second conductive layers 24, 24A, 24H and 24L and on the interlayer insulating film 80A by, for example, a sputtering process. Then, the semiconductor substrate 10 is subjected to a heating treatment, whereby the metal film and the polysilicon layers 24, 24A, 24H and 24L as the second conductive layers chemically react (silicide reaction).

By a treatment for forming the silicide layer (called the silicide treatment), the silicide layers 25, 25A, 25H and 25L as the third conductive layers are formed on the surfaces of the second conductive layers 24, 24A, 24H and 24L in the transistor gate electrodes CG, HG and LG and the shield gate electrode SIG. It is to be noted that the second conductive layers 24, 24A, 24H and 24L may entirely form the silicide layer. Additionally, the first conductive layers 23, 23A, 23H and 23L may include the silicide layer.

The metal film which does not react with polysilicon is removed. It is to be noted that when the metal film on the interlayer insulating film 80A is removed, the metal film on the polysilicon layer may be left.

Inconsequence, the memory cells MC each including the floating gate electrode 21 and the control gate electrode CG are formed in the memory cell array 2. The memory cells MC are formed, and simultaneously the select transistor ST, the high breakdown voltage transistor HT and the low breakdown voltage transistor LT are formed, respectively. Simultaneously with the formation of the respective transistors, the shield gate electrode SIG is formed on the isolation insulating film 15H in the high breakdown voltage transistor forming area HA. The shield gate electrode SIG includes three conductive layers, 23S, 24S and 25S, in the same manner as in the control gate electrode of the memory cell and the upper electrode layers of the other transistors.

The shield gate electrode SIG is formed to include the portion BB buried in the recess RC1 of the isolation insulating film 15H. In the present embodiment, part of the second conductive layer 24S is buried in the recess RC1 of the isolation insulating film 15H.

Then, as shown in FIG. 3 to FIG. 6, the interlayer insulating film is deposited to cover the gate electrodes of the respective transistors, and the contact plugs CP1, CPL1, CPH1, CPL2 and CPH2 connected to the diffusion layers 26, 26A, 26L and 26H and the gate electrodes CG, SEG, HG and LG are formed in the interlayer insulating film 80. Moreover, the interconnects (the intermediate interconnects) M0, ML1, ML2, MH1 and MH2, the source line, the via plug VP and the bit line BL are successively formed in the interlayer insulating film 81 by a multilayer interconnect technology.

The flash memory of the present embodiment is formed by the above manufacturing steps.

In the manufacturing method of the flash memory as the semiconductor memory of the present embodiment, the shield gate electrode SIG is formed on the isolation insulating film 15H which surrounds the forming area HA of the high breakdown voltage transistor HT. In the direction vertical to the surface of the semiconductor substrate 10, the bottom portion of the shield gate electrode SIG is positioned more closely to the bottom side of the semiconductor substrate 10 than the highest portion of the upper surface of the isolation insulating film 15H. Moreover, the bottom portion of the shield gate electrode SIG is positioned more closely to the bottom side of the semiconductor substrate 10 than the bottom portion of the gate fringe portion GF of the gate electrode of the high breakdown voltage transistor HT drawn onto the isolation insulating film 15H, in the direction vertical to the surface of the semiconductor substrate 10. For example, the bottom portion of the shield gate electrode SIG is positioned more closely to the bottom side of the semiconductor substrate 10 than the upper portion of the lower electrode layer 21H of the gate electrode HG of the high breakdown voltage transistor HT. In the present embodiment, the shield gate electrode SIG includes the buried portion BB buried in the recess RC1 formed in the isolation insulating film 15H.

In this manner, the shield gate electrode SIG includes the portion BB buried in the isolation insulating film 15H, whereby the distance D1 between the shield gate electrode SIG and the semiconductor region under the isolation insulating film 15H becomes smaller than the distance D2 between the gate fringe portion GF of the high breakdown voltage transistor HT on the isolation insulating film 15H and the semiconductor region 10 under the isolation insulating film 15H.

Consequently, in the flash memory of the present embodiment, an effect of suppressing the formation of the inversion layer during the driving of the high breakdown voltage transistor HT by the shield gate electrode SIG becomes larger, as compared with a structure where the bottom portion of the shield gate electrode SIG is positioned at the same height as the bottom portion of the gate fringe portion GF on the isolation insulating film 15H.

As described with reference to FIG. 3 to FIG. 19, in the manufacturing method of the flash memory of the present embodiment, the step for retreating the bottom portion of the shield gate electrode SIG more closely to the bottom side of the semiconductor substrate 10 than the bottom portion of the gate fringe portion GF, i.e., the step of forming the recess RC1 in which part of the shield gate electrode is buried is performed simultaneously with the formation of the opening OP through the insulator (the inter-gate insulating film) 22H between the upper electrode layers 23H, 24H and 25H and the lower electrode layer 21H.

In this manner, the step of retreating the bottom portion of the shield gate electrode SIG (the step of decreasing the film thickness of the isolation insulating film 15H of the forming area of the shield gate electrode SIG) can be common to the step of forming the opening OP through the insulator 22H. Therefore, also when the recess RC1 in which part of the shield gate electrode is buried is formed in the upper surface of the isolation insulating film 15H as in the present embodiment, the number of the openings to be formed in the mask is only increased, and it is not necessary to add a new manufacturing step.

As described above, according to the manufacturing method of the semiconductor memory of the present embodiment, there can be provided the flash memory which can suppress the formation of the inversion layer under the isolation insulating film 15H without increasing the number of the manufacturing steps.

Therefore, according to the semiconductor memory of the first embodiment, the leak between the elements can be decreased. Moreover, according to the manufacturing method of the semiconductor memory of the first embodiment, there can be provided the memory having the enhanced operation characteristics without the increase of the manufacturing steps.

### (2) Second Embodiment

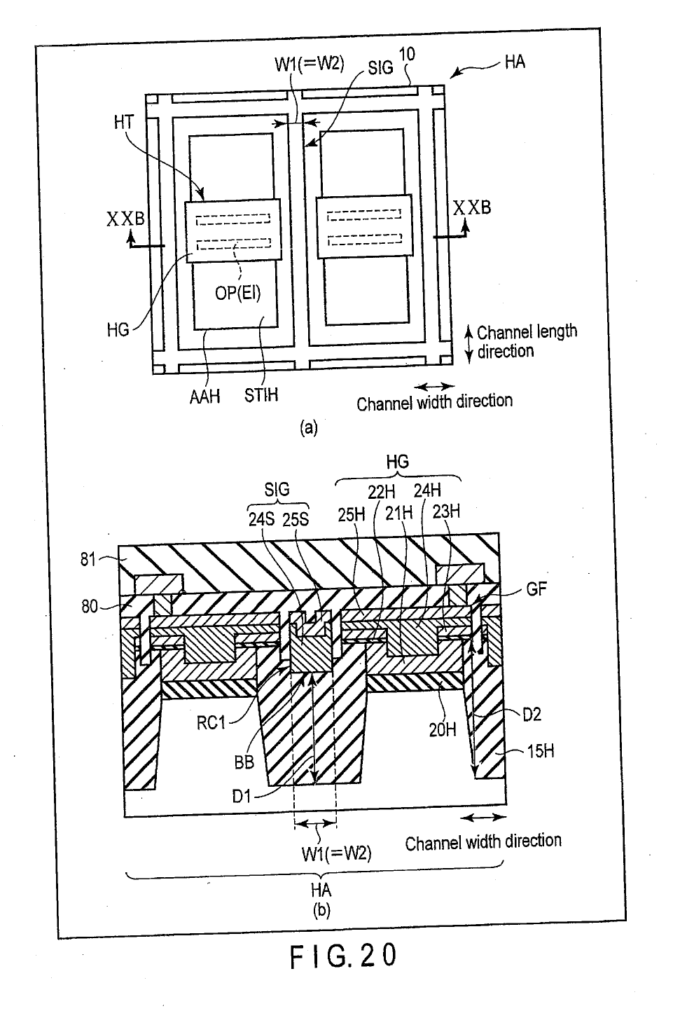

A semiconductor memory of a second embodiment will be described with reference to FIG. 20 to FIG. 23. Here, the descriptions of members, functions and manufacturing steps common to the first embodiment will be made if necessary.

(a) Structure

A structure of the flash memory of the second embodiment will be described with reference to FIG. 20. In the second embodiment, structures of a memory cell, a select transistor and a low breakdown voltage transistor are the same as the structures shown in FIG. 2 to FIG. 4, respectively, and hence the descriptions and illustrations of these structures are omitted. Moreover, the second embodiment is different from the first embodiment only in the structure of a shield gate electrode SIG, and the structure of a high breakdown voltage transistor HT is essentially the same as that of the first embodiment. Therefore, the description and illustration of a sectional structure of the high breakdown voltage transistor along a channel length direction thereof are omitted here.

FIG. 20 is a view for explaining the structure of the shield gate electrode SIG included in the flash memory of the present embodiment.

(a) of FIG. 20 shows a plan view of a peripheral area (the high breakdown voltage transistor forming area) where the shield gate electrode SIG is provided. (b) of FIG. 20 shows a sectional view of a peripheral circuit area (a high breakdown voltage transistor forming area HA) where the shield gate electrode SIG is provided. (b) of FIG. 20 is the sectional view of the transistor along a channel width direction thereof.

In the flash memory of the present embodiment, the structure of the shield gate electrode SIG and the structure of the forming area of the electrode are different from those of the first embodiment.

In the present embodiment, a width W2 of a recess RC1 in which the shield gate electrode SIG is buried has essentially the same size as an interconnect width W1 of the shield gate electrode SIG.

As shown in FIG. 20, the number of conductive layers 24S and 25S (the number of laminated layers) included in the shield gate electrode SIG is smaller than that of conductive layers 23H, 24H and 25H included in an upper electrode layer of a gate electrode HG of the high breakdown voltage transistor HT. For example, the shield gate electrode SIG does not include a film (here, a polysilicon layer) 23H of the lowermost layer of the upper electrode layers of the gate electrode HG of the transistor HT. A thickness of the shield gate electrode SIG is smaller than that of the upper electrode layers 23H, 24H and 25H of the high breakdown voltage transistor. Moreover, between the conductive layer 24S of the shield gate electrode SIG and an isolation insulating film 15H, an insulator of the same constitution (a film thickness and a material) as an inter-gate insulating film 22 is not provided.

Part of the side surface of the shield gate electrode SIG comes in contact with the side surface of the isolation insulating film 15H in the recess RC1. The shield gate electrode SIG has, for example, a hollow sectional shape. In the sectional shape of the isolation insulating film 15H in the channel width direction, the upper surface of the isolation insulating film 15H includes two or more stepped portions, and has a staircase-like shape.

It is to be noted that in the present embodiment, a position of the uppermost portion of the shield gate electrode SIG is set to essentially the same height as a position of the upper surface of the gate electrode HG in a direction vertical to the surface of a semiconductor substrate. However, in the direction vertical to the surface of the semiconductor substrate, sometimes, the position of the uppermost portion of the shield gate electrode SIG is lower than that of the upper surface of the gate electrode HG (is positioned on a semiconductor substrate side).

In the flash memory of the present embodiment, constitutional members included in the shield gate electrode SIG is different from constitutional members included in the upper electrode layer of the transistor HT, because in the manufacturing steps of the flash memory of the present embodiment described later, an insulator on the isolation insulating film 15H and the lowermost conductive layer of the upper electrode layers of the transistor are removed from a shield gate forming area by an EI step, when the recess RC1 is formed in the shield gate forming area.

In the flash memory of the second embodiment, the whole bottom portion of the shield gate electrode SIG is positioned more closely to the bottom side of a semiconductor substrate 10 than a bottom portion of a gate fringe portion GF. That is, in the whole bottom portion of the shield gate electrode SIG, a distance D1 between the shield gate electrode SIG and the semiconductor region 10 under the isolation insulating film 15H becomes smaller than a distance D2 between the gate fringe portion GF and the semiconductor region 10 under the isolation insulating film 15H.

Furthermore, the whole bottom portion of the shield gate electrode SIG retreats toward the semiconductor substrate 10 side, and hence an area (a facing area) of the bottom portion of the shield gate electrode SIG and the semiconductor substrate 10 facing each other via the isolation insulating film 15H becomes larger than that of the shield gate electrode described in the first embodiment.

Consequently, in the shield gate electrode SIG of the flash memory of the present embodiment, an effect of suppressing the formation of an inversion layer under the isolation insulating film 15H during the driving of the high breakdown voltage transistor becomes larger, as compared with the structure of the shield gate electrode of the first embodiment.

Also in a structure where the whole bottom portion of the shield gate electrode SIG retreats toward the bottom side of the semiconductor substrate 10, a step of etching the upper surface of the isolation insulating film 15H to form the recess RC1 can be carried out by the EI step. Therefore, manufacturing steps do not increase also in the flash memory of the present embodiment.

As described above, according to the semiconductor memory of the second embodiment, leak between elements can be decreased.

(b) Manufacturing Method

A manufacturing method of the semiconductor memory of the second embodiment will be described with reference to FIG. 20 to FIG. 23. It is to be noted that in the manufacturing method of the semiconductor memory of the present embodiment, the descriptions and illustrations of the same manufacturing steps as in the manufacturing method of the semiconductor memory of the first embodiment are omitted.

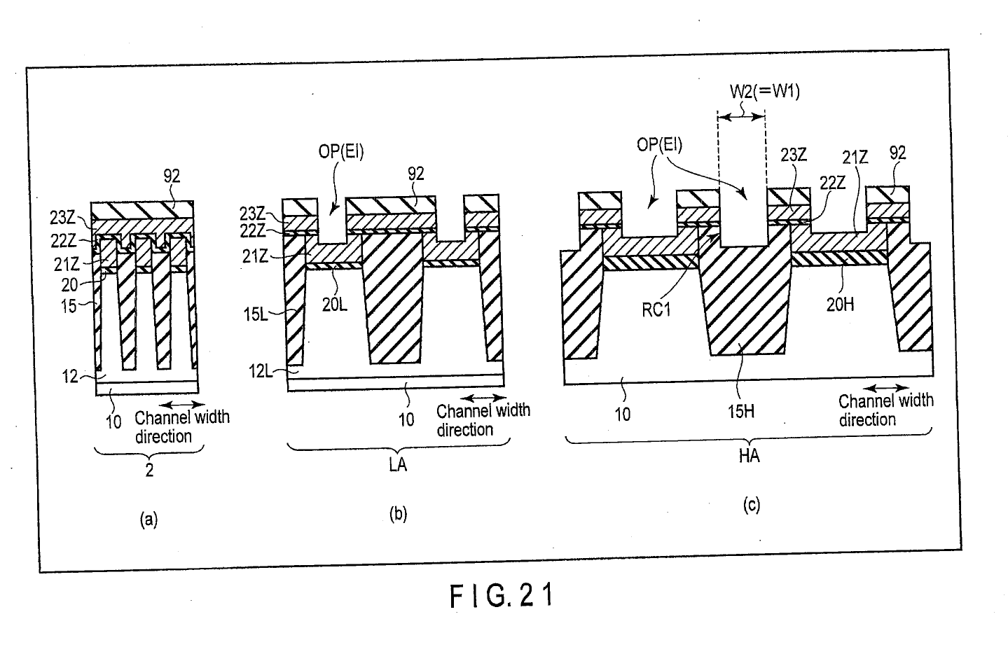

One process of the manufacturing method of the flash memory of the present embodiment will be described with reference to FIG. 21. FIG. 21 is a sectional process view of the memory cell and peripheral transistors along the channel width direction. (a) of FIG. 21 shows a sectional step view of a memory cell array. (b) of FIG. 21 shows a sectional step view of the low breakdown voltage transistor. (c) of FIG. 21 shows a sectional step view of the high breakdown voltage transistor.

As shown in FIG. 21, insulating films 20, 20L and 20H as gate insulating films, a polysilicon layer 21Z as a floating gate electrode and a lower electrode layer, and a mask (e.g., a silicon nitride film) are successively deposited on the semiconductor substrate 10 in the same manner as the process shown in FIG. 7 to FIG. 12. An isolation trench is formed in the semiconductor substrate 10 on the basis of the patterned mask. Isolation insulating films 15, 15L and 15H are buried in the formed isolation trench.

Then, by an EB step, the isolation insulating film 15 in a memory cell array 2 is selectively etched, and then an insulator 225 as an inter-gate insulating film is deposited on the polysilicon layer 21Z and on the element isolation insulating films 15, 15L and 15H. On the deposited insulator 22Z, a first conductive layer 23Z and a mask 92 are deposited.

Then, in a select transistor forming area, a low breakdown voltage transistor forming area LA and the high breakdown voltage transistor forming area HA, the mask 92 is subjected to patterning for forming openings through the insulator 22Z. Simultaneously, in the shield gate forming area of the high breakdown voltage transistor forming area HA, the mask 92 is subjected to patterning for forming the recess RC1 in the isolation insulating film 15H.

In this case, the mask 92 which covers the shield gate forming area is patterned so that the width W2 of the recess RC1 formed in the isolation insulating film 15H becomes essentially the same size as the interconnect width W1 of the shield gate electrode.

Then, the conductive layer 23Z, the insulator 22Z, the polysilicon layer 21Z and the isolation insulating film 15H are etched on the basis of the patterned mask 92. In consequence, openings OP are formed in the conductive layer 23Z and the insulator 22Z in an area where the gate electrode of each transistor is formed. In the shield gate forming area, by this EI step, the upper surface of the isolation insulating film 15H retreats toward a semiconductor substrate side, and the recess RC1 is formed in the upper surface of the isolation insulating film 15H. Then, in the present embodiment, the insulator 22Z and the first conductive layer 23Z are removed from the shield gate forming area.

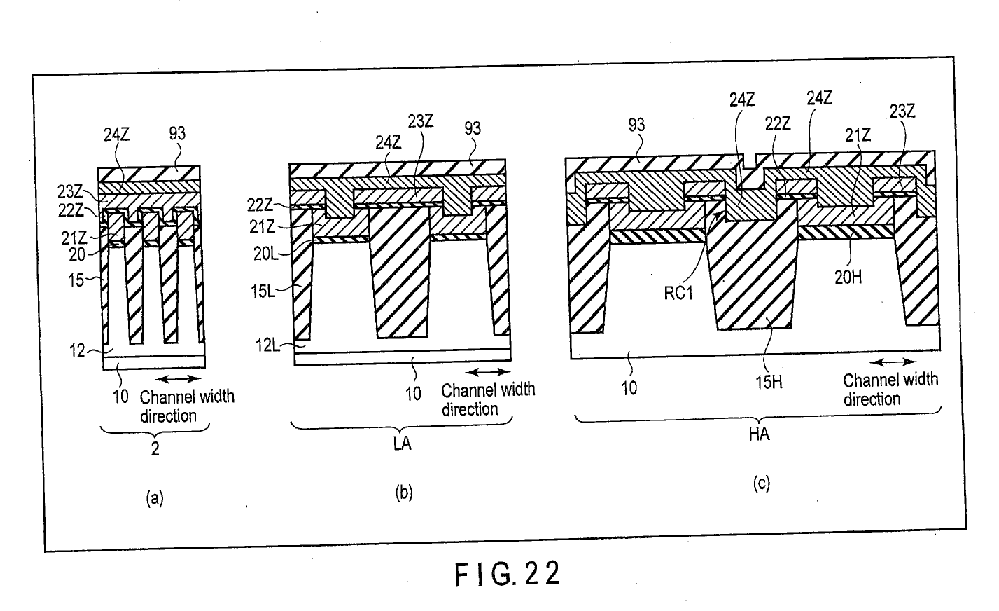

One process of the manufacturing method of the flash memory of the present embodiment will be described with reference to FIG. 22. FIG. 22 is a sectional process view of the memory cell and peripheral transistors along the channel width direction. (a) of FIG. 22 shows a sectional step view of the memory cell array. (b) of FIG. 22 shows a sectional step view of the low breakdown voltage transistor. (c) of FIG. 22 shows a sectional step view of the high breakdown voltage transistor.

As shown in FIG. 22, after removing the mask for the EI step, a second conductive layer (e.g., the polysilicon layer) 24Z is deposited on the polysilicon layer 21Z, the insulator 22Z, the first conductive layer 23Z and the isolation insulating film 15H by, for example, a CVD process in essentially the same manner as the process shown in FIG. 16 and FIG. 17. For example, a hard mask 93 is deposited on the second conductive layer 24Z.

In the present embodiment, the interior of the recess RC1 of the isolation insulating film 15H in the shield gate forming area is filled with the second conductive layer 24Z. The first conductive layer 23Z and the insulator 22Z are removed from the shield gate forming area by the EI step, and hence the second conductive layer 24Z does not come in contact with the first conductive layer 23Z and the insulator 22Z in the shield gate forming area.

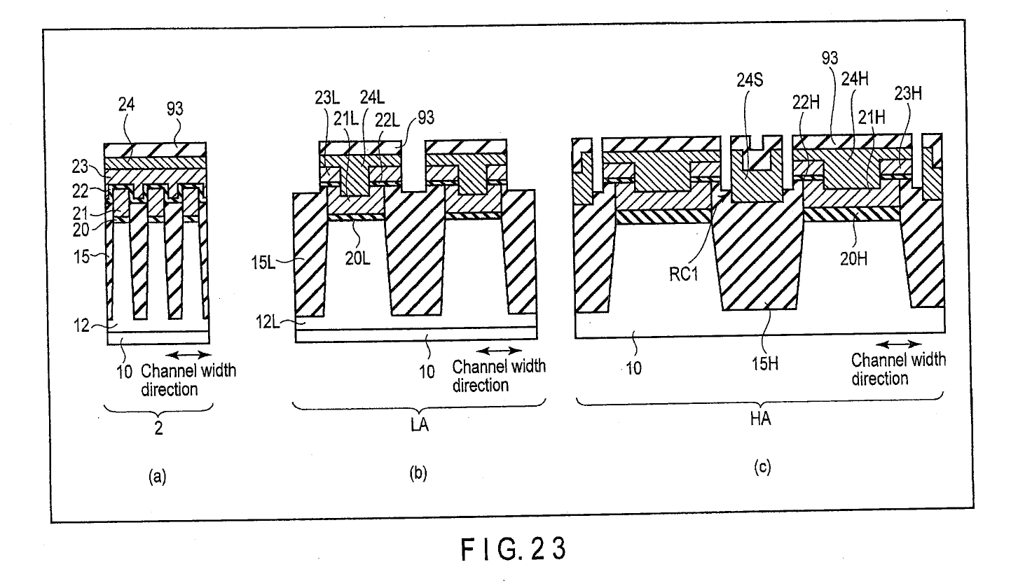

One process of the manufacturing method of the flash memory of the present embodiment will be described with reference to FIG. 23. FIG. 23 is a sectional process view of the memory cell and peripheral transistors along the channel width direction. (a) of FIG. 23(a) shows a sectional step view of the memory cell array. (b) of FIG. 23 shows a sectional step view of the low breakdown voltage transistor. (c) of FIG. 23 shows a sectional step view of the high breakdown voltage transistor.

As shown in FIG. 23, the hard mask 93 is patterned so that the respective constitutional members have predetermined dimensions in essentially the same manner as the process shown in FIG. 18 and FIG. 19. On the basis of the patterned hard mask 93, the respective transistor gate electrodes and the shield gate electrode 24Z are formed by an RIE process.

In this step, the constitutional member (the second conductive layer) 24Z for forming the shield gate electrode is processed to have essentially the same dimension as the width W2 of the recess RC1 in the isolation insulating film 15H of the shield gate forming area.

Afterward, as shown in FIG. 4, FIG. 5 and FIG. 20, a source/drain diffusion layer is formed in the semiconductor substrate 10, and then an interlayer insulating film 80A is deposited on the semiconductor substrate 10, in the same manner as the process shown in FIG. 18 and FIG. 19. A silicide treatment is carried out on the upper surfaces of second conductive layers 24, 24L, 24H and 24S, and silicide layers as third conductive layers 25, 25L, 25H and 25S are formed in surface layer portions of the second conductive layers 24, 24L, 24H and 24S.

Then, an interlayer insulating film, plugs and interconnects are successively formed in the same manner as in the first embodiment. By the above steps, the semiconductor memory (the flash memory) of the second embodiment is formed.

In the present embodiment, the shield gate electrode SIG is formed in the recess RC1 of the upper surface of the isolation insulating film 15H. Then, the shield gate electrode is formed by the SI step so that the interconnect width W1 of the shield gate electrode SIG has essentially the same size as the width W2 of the recess RC1 formed in the isolation insulating film 15H of the shield gate forming area.

In the same manner as in the first embodiment, in the direction vertical to the surface of the substrate, a bottom portion of the shield gate electrode SIG is positioned more closely to a bottom side of the semiconductor substrate 10 than the highest portion of the upper surface of the isolation insulating film 15H, and positioned more closely to the semiconductor substrate side than a bottom portion of the gate fringe portion of the high breakdown voltage transistor. In the flash memory formed by the manufacturing method of the present embodiment, the distance D1 between the bottom portion of the shield gate electrode SIG and the semiconductor region 10 in the direction vertical to the substrate surface is smaller than the distance D2 between the bottom portion of the gate fringe portion GF and the semiconductor region 10.

Furthermore, in the flash memory of the present embodiment, the facing area of the bottom portion of the shield gate electrode SIG and the semiconductor region 10 under the isolation insulating film 15H becomes larger than that of the shield gate electrode and the semiconductor region of the first embodiment.

Therefore, in the flash memory of the second embodiment, an effect of suppressing the formation of the inversion layer under the isolation insulating film 15H by the shield gate electrode SIG is further strengthened as compared with the flash memory formed by the manufacturing method of the first embodiment.

In addition, when the interconnect width of the shield gate electrode SIG is set to be essentially the same as the width of the recess RC1 of the isolation insulating film 15H as in the present embodiment, a dimension of the opening of the mask for forming the recess RC1 in the isolation insulating film 15H or a dimension of the opening of the mask for forming the shield gate electrode may be changed.

Therefore, to increase the facing area of the shield gate electrode SIG and the semiconductor region 10 in the manufacturing method of the flash memory of the present embodiment, the manufacturing steps for forming the flash memory do not increase.

In consequence, according to the manufacturing method of the semiconductor memory of the second embodiment, there can be provided the memory having enhanced operation characteristics without increasing the manufacturing steps.

### (3) Third Embodiment

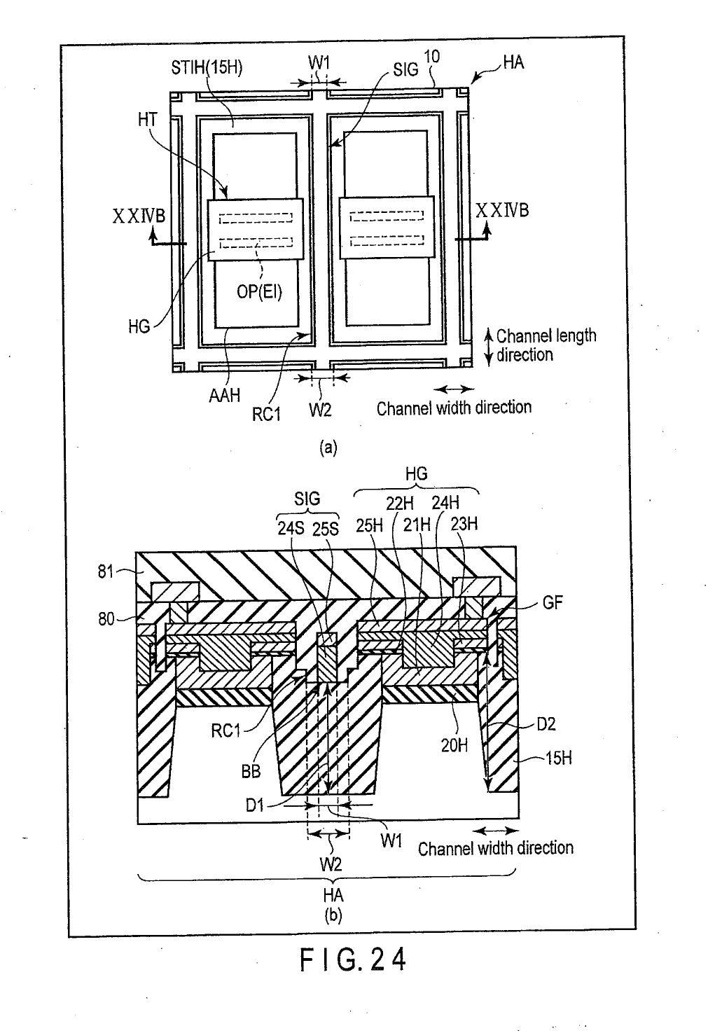

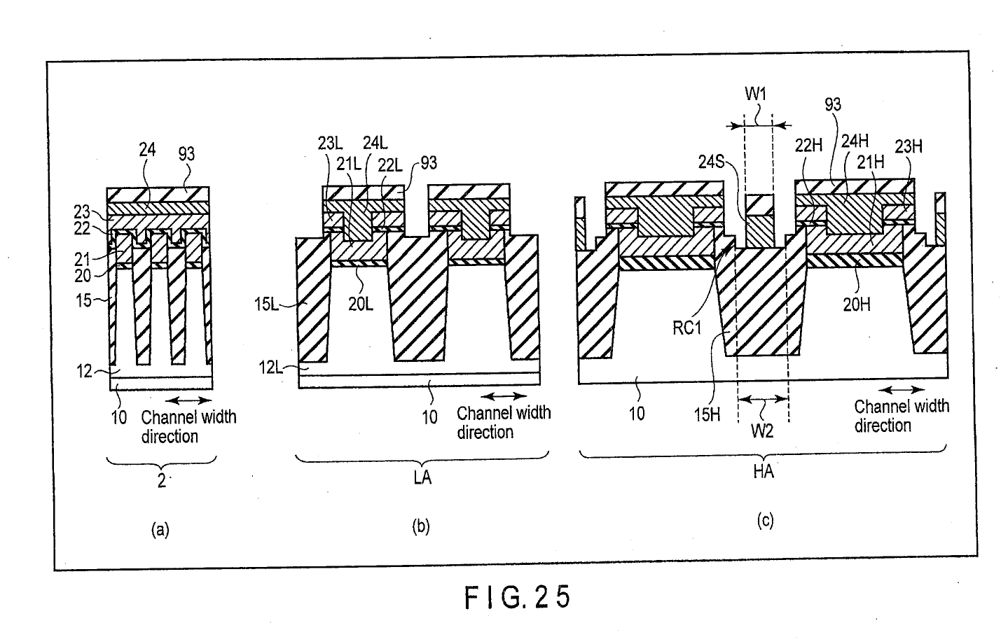

A semiconductor memory and a manufacturing method of the memory of a third embodiment will be described with reference to FIG. 24 and FIG. 25. Here, the descriptions of members, functions and manufacturing steps common to the first and second embodiments, will be made if necessary.

(a) Structure

A structure of a flash memory of the third embodiment will be described with reference to FIG. 24. In the third embodiment, structures of a memory cell, a select transistor and a low breakdown voltage transistor are the same as the structures shown in FIG. 2 to FIG. 4, respectively, and hence the descriptions and illustrations of these structures are omitted. Moreover, the third embodiment is different from the first and second embodiments only in the structure of the shield gate electrode SIG, and the structure of a high breakdown voltage transistor HT is essentially the same as in the first and second embodiments. Therefore, the description and illustration of a sectional structure of the high breakdown voltage transistor HT along a channel length direction are omitted here.

FIG. 24 is a view for explaining the structure of the shield gate electrode SIG included in the flash memory of the present embodiment.

(a) of FIG. 24 shows a plan view of a peripheral circuit area (a high breakdown voltage transistor forming area) where the shield gate electrode is provided. (b) of FIG. 24 shows a sectional view of the peripheral circuit area (the high breakdown voltage transistor forming area) where the shield gate electrode is provided. (b) of FIG. 24 is the sectional view of the transistor along a channel width direction thereof.

The flash memory of the present embodiment is different from the first and second embodiments in the structure of the shield gate electrode SIG and the structure of the forming area of the electrode.

As shown in FIG. 24, a width W2 of a recess RC1 formed in the upper surface of an isolation insulating film 15H is larger than a width W1 of the shield gate electrode SIG in the flash memory of the present embodiment.

In the present embodiment, the side surface of the shield gate electrode SIG does not come in contact with the inner side surface of the recess RC1 (the side surface of the isolation insulating film 15H). Between the side surface of the shield gate electrode SIG and the side surface of the isolation insulating film 15H, an interlayer insulating film 80 or a side wall insulating film (not shown) is buried.

The sectional structure of the upper surface of the isolation insulating film 15H in the high breakdown voltage transistor area has, for example, a staircase-like shape.

For example, in the direction vertical to the surface of the semiconductor substrate, a position of an upper portion of the shield gate electrode SIG becomes lower than that of an upper portion of a gate electrode HG, and retreats toward the bottom side of a semiconductor substrate 10.

For example, in the present embodiment, a distance between the shield gate electrode SIG and a gate fringe portion GF enlarges. Therefore, a parasitic capacitance between the shield gate electrode SIG and the gate fringe portion GF can be decreased.

Also in the flash memory of the present embodiment, a distance D1 between the bottom portion of the shield gate electrode SIG and the semiconductor region 10 can be set to be smaller than a distance D2 between the bottom portion of the gate fringe portion GE and the semiconductor region 10, in the same manner as in the first and second embodiments. In consequence, an effect of suppressing the formation of an inversion layer under the isolation insulating film 15H by the shield gate electrode SIG is strengthened.

Furthermore, even when the width W2 of the recess RC1 is larger than the interconnect width W1 of the shield gate electrode SIG as in the flash memory of the present embodiment, manufacturing steps of the flash memory do not increase.

Therefore, according to the semiconductor memory of the third embodiment, leak between elements can be decreased.

(b) Manufacturing Method

A manufacturing method of the semiconductor memory of the third embodiment will be described with reference to FIG. 24 and FIG. 25. It is to be noted that in the manufacturing method of the semiconductor memory of the present embodiment, the descriptions and illustrations of the same manufacturing steps as in the manufacturing method of the semiconductor memory of the first and second embodiments are omitted.

One process of the manufacturing method of the flash memory of the present embodiment will be described with reference to FIG. 25. FIG. 25 is a sectional process view of the memory cell and the peripheral transistors along the channel width direction. (a) of FIG. 25 shows a sectional step view of the memory cell array. (b) of FIG. 25 shows a sectional step view of the low breakdown voltage transistor. (c) of FIG. 25 shows a sectional step view of the high breakdown voltage transistor.

As shown in FIG. 25, an insulator 22Z as an inter-gate insulating film and a first conductive layer 23Z are successively deposited on a polysilicon layer 21Z and isolation insulating films 15, 15L and 15H by essentially the same process as the process shown in FIG. 7 to FIG. 15.

Then, an opening is formed through the insulator 22Z by an EI step. Simultaneously with this EI step, the recess RC1 is formed in the upper surface of the isolation insulating film 15H in a shield gate forming area.

In the manufacturing method of the flash memory of the present embodiment, the width W2 of the recess RC1 is set to be larger than the interconnect width W1 of the shield gate electrode formed in a subsequent step. In this case, the insulator 22Z and the first conductive layer 23Z are removed from the shield gate forming area.

Then, a mask for the EI step is removed, and then a second conductive layer 24Z and a mask 93 are deposited on the first conductive layer 23Z and the isolation insulating films 15, 15L and 15H. After the mask 93 is patterned, the conductive layers 21Z, 23Z and 24Z are subjected to gate processing on the basis of the pattern of the mask 93.

In consequence, a gate pattern (the gate electrode) of the transistor is formed in each transistor forming area, and simultaneously the pattern of the shield gate electrode is formed.

Since the interconnect width W1 of the shield gate electrode SIG is smaller than the width W2 of the recess RC1 formed in the isolation insulating film 15H in the shield gate forming area, the side surface of the conductive layer 24Z for forming the shield gate electrode does not come in contact with the isolation insulating film 15H.

Afterward, as shown in FIG. 24, a source/drain diffusion layer is formed, a side wall insulating film (not shown) is formed on the side surface of the processed conductive layer (the gate electrode), and then the interlayer insulating film 80 is deposited. The interlayer insulating film 80 is etched back to expose the upper surface of the conductive layer, and a silicide layer is formed on the upper surface of the conductive layer. Then, an interlayer insulating film, a contact plug and an interconnect are successively formed.

By the above steps, the flash memory of the third embodiment is completed.

In the manufacturing method of the flash memory of the present embodiment, the shield gate electrode SIG is formed in the recess RC1 in the upper surface of the isolation insulating film 15H in the shield gate forming area. The recess RC1 in the upper surface of the isolation insulating film 15H is formed by the EI step so that the width W2 of the recess RC1 formed in the isolation insulating film 15H becomes larger than the interconnect width W1 of the shield gate electrode SIG. The interconnect width W1 of the shield gate electrode SIG is smaller than the width W2 of the recess RC1.

In the manufacturing method of the flash memory of the present embodiment, the distance D1 between the bottom portion of the shield gate electrode SIG and the semiconductor region 10 is smaller than the distance D2 between the bottom portion of the gate fringe portion GF and the semiconductor region 10. In consequence, the effect of suppressing the formation of the inversion layer under the isolation insulating film 15H by the shield gate electrode SIG is strengthened.

Also in the manufacturing method of the flash memory of the present embodiment, it is possible to form the shield gate electrode SIG having the above structure without the increase of the manufacturing steps.

Therefore, according to the manufacturing method of the semiconductor memory of the third embodiment, there can be provided the memory having enhanced operation characteristics without the increase of the manufacturing steps.

### (4) Fourth Embodiment

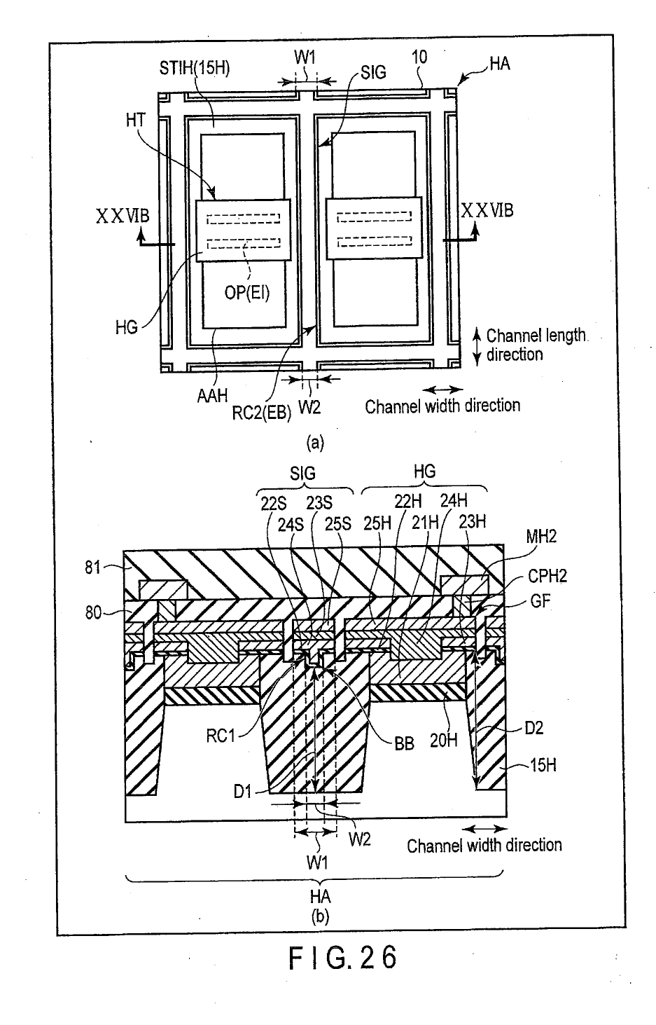

A semiconductor memory and a manufacturing method of the memory of a fourth embodiment will be described with reference to FIG. 26 to FIG. 29. It is to be noted that members and functions common to the first to third embodiments will be described in detail if necessary.

(a) Structure

A structure of the semiconductor memory (e.g., the flash memory) of the fourth embodiment will be described with reference to FIG. 26. In the fourth embodiment, structures of a memory cell, a select transistor and a low breakdown voltage transistor are the same as the structures shown in FIG. 2 to FIG. 4, respectively, and hence the descriptions and illustrations of the structures are omitted. Moreover, the fourth embodiment is different from the first to third embodiments only in a structure of a shield gate electrode SIG, and a structure of a high breakdown voltage transistor HT is essentially the same as in the first to third embodiments. Therefore, the description and illustration of a sectional structure of the high breakdown voltage transistor along a channel length direction thereof are omitted here.

FIG. 26 is a view for explaining the structure of the shield gate electrode SIG included in the flash memory of the present embodiment. (a) of FIG. 26 shows a plan view of a peripheral circuit area (a high breakdown voltage transistor forming area) where the shield gate electrode is provided. (b) of FIG. 26 shows a sectional view of the peripheral circuit area (the high breakdown voltage transistor forming area) where the shield gate electrode is provided. (b) of FIG. 26 is a sectional view of the transistor along a channel width direction thereof.

In the first to third embodiments, the step of retreating the forming position of the shield gate electrode SIG toward the bottom side of the semiconductor substrate 10 in a shield gate forming area, i.e., a step of forming a trench for providing the shield gate electrode SIG in the upper surface of an isolation insulating film can be common to the step of forming the opening through the insulator formed simultaneously with the inter-gate insulating film 22 (the EI step). However, a trench in which at least a part of the shield gate electrode SIG is provided may be formed by a step other than the EI step, as long as the step can be common to the step of forming a memory cell array or peripheral transistors.

In the flash memory of the present embodiment, as shown in FIG. 26, a step of forming a recess RC2 in an isolation insulating film 15H of the shield gate forming area can be common to a step of etching back an isolation insulating film 15 to expose the side surface of a floating gate electrode 21 in a memory cell array 2 (the EH step).

In this case, as shown in FIG. 26, the recess RC2, in which the shield gate electrode SIG is provided, is formed in the upper surface of the isolation insulating film 15H, before an insulator 22H as an inter-gate insulating film is formed. Therefore, in the recess RC2, an insulator 22S of the same constitution (the same material and film thickness) as in an inter-gate insulating film 22 is provided. Between a conductive layer 23S included in the shield gate electrode SIG and the isolation insulating film 15H, the insulator 22S is provided, and a conductor of the shield gate electrode SIG does not directly come in contact with the isolation insulating film 15H.

It is to be noted that in the present embodiment, a position of the upper portion of the shield gate electrode SIG is set to essentially the same height as a position of the upper surface of a gate electrode HG, in a direction vertical to the surface of a semiconductor substrate.

A width of the recess RC2, in which the shield gate electrode SIG is buried, is preferably suitably set so that the recess RC2 is not filled with the insulator 22H. For example, a width W2 of the recess RC2 in which the shield gate electrode SIG is provided has a dimension larger than twice film thickness of the insulator (the inter-gate insulating film) 22H. For example, a depth of the recess RC2 is essentially the same as a dimension (height) of the exposed side surface of the floating gate electrode 21, and is set to such a dimension that the whole side surface of a lower electrode layer 21H is not exposed.

In the flash memory of the present embodiment, the shield gate electrode SIG is adjacent to a gate fringe portion GF of the gate electrode HG of the high breakdown voltage transistor HT on the isolation insulating film 15H, in the same manner as in the first to third embodiments.

In the present embodiment, at least a part of the shield gate electrode SIG is buried in the recess RC2 formed by the EB step. Moreover, a bottom portion of a portion (the buried portion) of the shield gate electrode SIG buried in the recess RC2 is positioned more closely to a bottom side of a semiconductor substrate 10 than the highest portion of the upper surface of the isolation insulating film 15H and the bottom portion of the gate fringe portion GF, in the direction vertical to the surface of the semiconductor substrate 10. A distance D1 between the bottom portion of the shield gate electrode SIG and the semiconductor region 10 under the isolation insulating film 15H becomes smaller than a distance D2 between the gate fringe portion GF and the semiconductor region under the isolation insulating film 15H.

Therefore, also in the flash memory of the present embodiment, an effect of suppressing the formation of an inversion layer under the isolation insulating film 15H by the shield gate electrode SIG during the driving of the high breakdown voltage transistor becomes large, as compared with a case where the distance D1 between the bottom portion of the shield gate electrode SIG and the semiconductor region 10 is the same as the distance D2 between the gate fringe portion GF and the semiconductor region 10, in the same manner as in the first to third embodiments.

Furthermore, in the flash memory of the present embodiment, the recess RC2 for positioning the bottom portion of the shield gate electrode SIG more closely to the semiconductor substrate side than the gate fringe portion GF is formed by a step common to a step of etching back the upper surface of the isolation insulating film 15 in the memory cell array 2. Consequently, when the structure of FIG. 26 is formed, flash memory manufacturing steps do not increase also in the present embodiment.

Therefore, according to the semiconductor memory of the fourth embodiment, leak between elements can be decreased.

(b) Manufacturing Method

A manufacturing method of the semiconductor memory (the flash memory) of the fourth embodiment will be described with reference to FIG. 26 to FIG. 29. It is to be noted that in the manufacturing method of the semiconductor memory of the present embodiment, the descriptions and illustrations of the same manufacturing steps as in the manufacturing method of the semiconductor memory of the above-mentioned first to third embodiments are omitted.

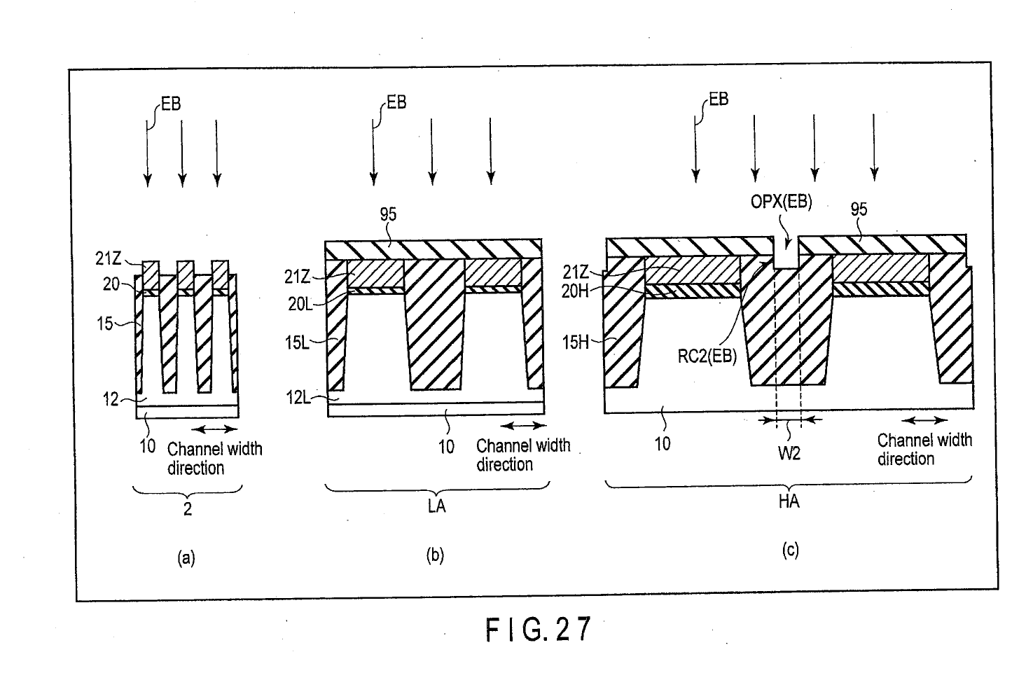

One process of the manufacturing method of the flash memory of the present embodiment will be described with reference to FIG. 27. FIG. 27 is a sectional process view of the memory cell and the peripheral transistors along the channel width direction. (a) of FIG. 27 shows a sectional step view of the memory cell array. (b) of FIG. 27 shows a sectional step view of the low breakdown voltage transistor. (c) of FIG. 27 shows a sectional step view of the high breakdown voltage transistor.

As shown in FIG. 27, in the same manner as in the first to third embodiments, isolation trenches (grooves) are formed in the semiconductor substrate 10 in the memory cell array 2 and peripheral transistor forming areas HA and LA, respectively, and then the isolation insulating films 15, 15L and 15H are buried in the trenches. The upper surfaces of the isolation insulating films 15, 15L and 15H are subjected to a flattening treatment so that the position (the height) of the upper surface of each of the isolation insulating films 15, 15L and 15H matches a position of the upper surface of a polysilicon layer 21Z.

Then, a resist mask 95 is formed in the peripheral transistor forming areas LA and HA so that a portion above the memory cell array 2 is open.

In the present embodiment, at a position where the trench is formed in the shield gate forming area, an opening OPX is formed in the mask (e.g., the resist mask) 95. This opening OPX is formed simultaneously with the patterning for opening the portion above the memory cell array 2.

By an etching step (the EB step) for the isolation insulating film 15 of the memory cell array 2, the upper surfaces of the isolation insulating films 15 and 15H are etched on the basis of a pattern of the mask 95. In consequence, the isolation insulating film 15 in the memory cell array 2 retreats toward the semiconductor substrate side. Simultaneously, in the shield gate forming area, the recess. RC2 for burying part of the shield gate electrode is formed in the upper surface of the isolation insulating film 15H.

In the manufacturing method of the present embodiment, the dimension of the pattern (the opening) of the mask 95 is determined so that the width W2 of the recess RC2 becomes larger than twice film thickness of the inter-gate insulating film formed in a subsequent step.

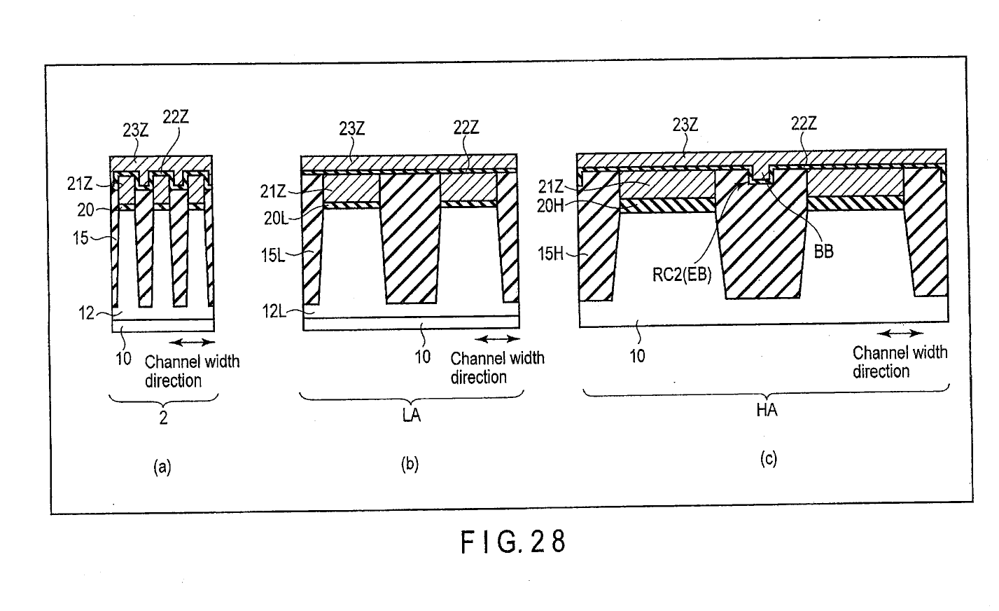

One process of the manufacturing method of the flash memory of the present embodiment will be described with reference to FIG. 28. FIG. 28 is a sectional process view of the memory cell and the peripheral transistors along the channel width direction. (a) of FIG. 28 shows a sectional step view of the memory cell array. (b) of FIG. 28 shows a sectional step view of the low breakdown voltage transistor. (c) of FIG. 28 shows a sectional step view of the high breakdown voltage transistor.

As shown in FIG. 28, the mask for the EB step is removed, and then an insulator 22Z as the inter-gate insulating film is deposited on the polysilicon layer 21Z and the isolation insulating films 15, 15L and 15H.

In the shield gate forming area, the insulator 22Z is deposited on the side surface of the recess RC2 and the bottom surface of the recess RC2. The size of the recess RC2 in the shield gate forming area is set to be larger than twice film thickness of the insulator 22Z. Therefore, the insulators 22Z on the facing side surfaces do not come in contact with each other in the recess RC2, and the interior of the recess RC2 is not filled with the insulator 22Z. It is to be noted that in the manufacturing method of the present embodiment, the width W2 of the recess RC2 is set to be smaller than an interconnect width of the shield gate electrode formed in a subsequent step.

After the insulator 22Z is deposited, a first conductive layer 23Z is deposited on the insulator 22Z. In the shield gate forming area, the first conductive layer 23Z is deposited on the insulator 22Z in the recess RC2, and the first conductive layer 23Z is buried in the recess RC2.

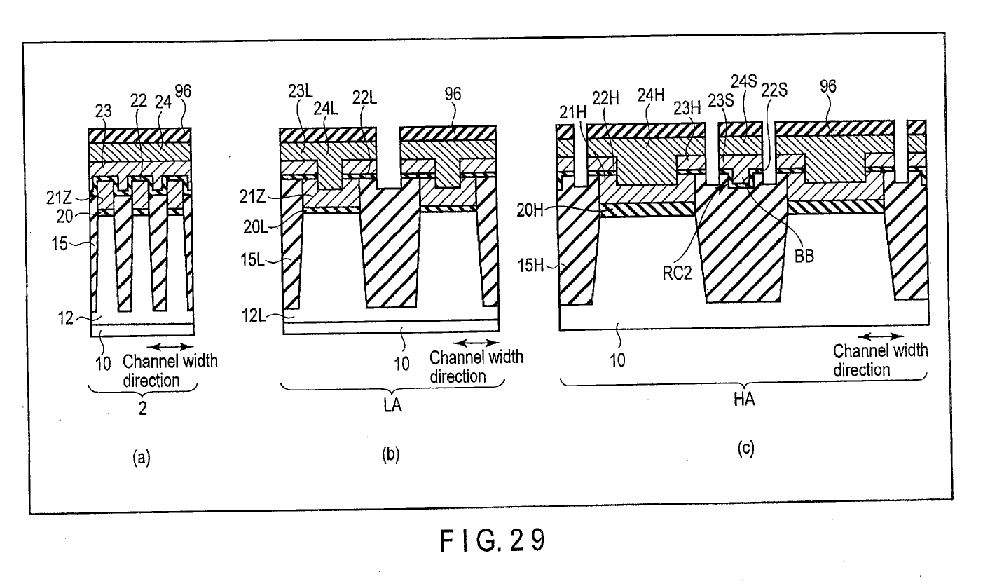

One process of the manufacturing method of the flash memory of the present embodiment will be described with reference to FIG. 29. FIG. 29 is a sectional process view of the memory cell and the peripheral transistors along the channel width direction. (a) of FIG. 29 shows a sectional step view of the memory cell array. (b) of FIG. 29 shows a sectional step view of the low breakdown voltage transistor. (c) of FIG. 29 shows a sectional step view of the high breakdown voltage transistor.

As shown in FIG. 29, openings OP are formed through first conductive layers 23L and 23H and insulators 22L and 22H in a select transistor forming area and the peripheral transistor forming areas HA and LA by the EI step, in the same manner as the process shown in FIG. 13 to FIG. 15.

In the present embodiment, when the EI step is carried out, the conductive layer 23S in the shield gate forming area is covered with the mask. The conductive layer 23S and the insulator 22S are not processed by the EI step.

Then, in the same manner as the process shown in FIG. 16 to FIG. 19, second conductive layers 24, 24L and 24H are deposited, and gate processing is carried out on the basis of a patterned mask 96. In the present embodiment, the conductive layers 24, 24L and 24H are connected to lower polysilicon layers 21, 21L and 21H via the openings OP, in gate electrodes of the transistors. On the other hand, in the shield gate electrode, a conductive layer 24S is provided on the conductive layer 23S, and does not come in contact with the insulator 22S under the conductive layer 23S or the isolation insulating film 15H.

After the gate processing, a source/drain diffusion layer, a side wall insulating film (not shown) and an interlayer insulating film are formed, and a silicide layer is formed on the upper surfaces of the conductive layers 24, 24L, 24L, 24H and 24S.

Then, as shown in FIG. 4, FIG. 5 and FIG. 26, an interlayer insulating film, an interconnect and a plug are successively formed by a multilayer interconnect technology in the same manner as in the first to third embodiments.

By the above steps, the flash memory of the present embodiment is formed.

In the manufacturing method of the flash memory of the present embodiment, the recess RC2 for retreating the forming position of the shield gate electrode toward the bottom side of the semiconductor substrate 10 is formed by etch back (the EB step) carried out for the isolation insulating film 15 in the memory cell array to expose the side surface of the floating gate electrode.

Also, when the recess RC2 is formed in the upper surface of the isolation insulating film 15H in the shield gate forming area by the EB step different from the EI step as in the manufacturing method of the present embodiment, the manufacturing steps of the flash memory of the present embodiment do not increase.

Furthermore, in the flash memory formed by the manufacturing method of the present embodiment, the distance D1 between the bottom portion of the shield gate electrode SIG and the semiconductor region 10 under the isolation insulating film 15H becomes smaller than the distance D2 between the bottom portion of the gate fringe portion and the semiconductor region 10 under the isolation insulating film 15H, in the same manner as in the first to third embodiments.

Therefore, the effect of suppressing the formation of the inversion layer under the isolation insulating film 15H by the shield gate electrode SIG during the driving of the high breakdown voltage transistor is further strengthened.

Thus, according to the manufacturing method of the semiconductor memory of the fourth embodiment, there can be provided the memory having enhanced operation characteristics without the increase of the manufacturing steps, in the same manner as in the first to third embodiments.

### (5) Fifth Embodiment

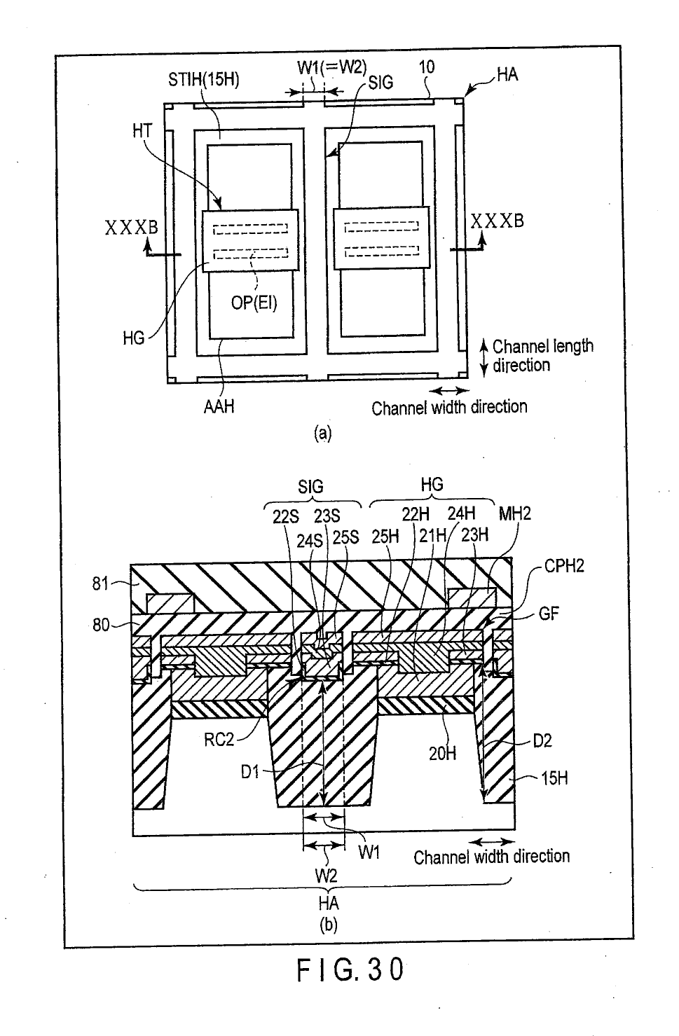

A semiconductor memory and a manufacturing method of the memory of a fifth embodiment will be described with reference to FIG. 30 and FIG. 31. It is to be noted that members and functions common to the first to fourth embodiments will be described in detail if necessary.

(a) Structure

A structure of the semiconductor memory (e.g., the flash memory) of the fifth embodiment will be described with reference to FIG. 30. In the fifth embodiment, structures of a memory cell, a select transistor and a low breakdown voltage transistor are the same as the structures shown in FIG. 2 to FIG. 4, respectively, and hence the descriptions and illustrations of the structures are omitted. Moreover, the fifth embodiment is different from the first to fourth embodiments only in a structure of a shield gate electrode SIG, and a structure of a high breakdown voltage transistor HT is essentially the same as in the first to third embodiments. Therefore, the description and illustration of the sectional structure of the high breakdown voltage transistor along a channel length direction thereof are omitted here.

FIG. 30 is a view for explaining the structure of the shield gate electrode SIG included in the flash memory of the present embodiment. (a) of FIG. 30 shows a plan view of a peripheral circuit area (a high breakdown voltage transistor forming area) where the shield gate electrode is provided. (b) of FIG. 30 shows a sectional view of the peripheral circuit area (the high breakdown voltage transistor forming area) where the shield gate electrode is provided. (b) of FIG. 30 is a sectional view of the transistor along a channel width direction thereof.

The fifth embodiment shows an example where an interconnect width of the shield gate electrode SIG is larger than that of a recess RC2 formed in the upper surface of an isolation insulating film 15H. However, even when the recess RC2 is formed in the isolation insulating film 15H by an EB step, an interconnect width W1 of the shield gate electrode SIG may be the same as a width W2 of the recess RC2 in the same manner as in the structure described in the second embodiment.

In this case, for example, the side surface of the bottom portion side of the shield gate electrode SIG is covered with an insulator 22S. Moreover, a sectional shape of the shield gate electrode SIG is, for example, a hollow type sectional shape.

In the flash memory of the present embodiment, the whole bottom portion of the shield gate electrode can be retreated toward a semiconductor substrate side, and hence a facing area of the bottom portion of the shield gate electrode SIG and a semiconductor region 10 can be enlarged in the same manner as in the second embodiment. Therefore, in the flash memory of the present embodiment, an effect of suppressing the formation of an inversion layer under the isolation insulating film 15H by the shield gate electrode SIG can be strengthened as compared with the fourth embodiment.

Therefore, according to the semiconductor memory of the fifth embodiment, leak between elements can be decreased.

(b) Manufacturing Method

A manufacturing method of the semiconductor memory (the flash memory) of the fifth embodiment will be described with reference to FIG. 30 and FIG. 31. It is to be noted that in the manufacturing method of the semiconductor memory of the present embodiment, the descriptions and illustrations of the same manufacturing steps as in the manufacturing method of the semiconductor memory of the above-mentioned first to fourth embodiments are omitted.

FIG. 31 shows one process of the manufacturing method of the flash memory of the present embodiment.

FIG. 31 shows a sectional process view of a memory cell and peripheral transistors along the channel width direction. (a) of FIG. 31 shows a sectional step view of the memory cell array. (b) of FIG. 31 shows a sectional step view of the low breakdown voltage transistor. (c) of FIG. 31 shows a sectional step view of the high breakdown voltage transistor.

As shown in FIG. 31, in the same manner as the process shown in FIG. 27, an opening to expose a memory cell array 2 for the EB step in the memory cell array 2 is formed in a mask 95 which covers the semiconductor substrate 10. Simultaneously, in a shield gate forming area, an opening for forming the recess RC2 in the isolation insulating film 15H is formed in the mask 95.

A dimension of the opening of this mask is set so that the width W2 of the recess RC2 formed on the basis of the mask has essentially the same size as the interconnect width W1 of the shield gate electrode formed in a subsequent step.

The isolation insulating films 15, 15H in the memory cell array 2 and the shield gate forming area are etched on the basis of the mask. In consequence, the upper surface of the isolation insulating film 15 in the memory cell array 2 is etched, and, simultaneously, the recess RC2 provided with the shield gate electrode SIG is formed in the isolation insulating film 15H.

Moreover, in the same manner as in the example described in the fifth embodiment, an insulator 22Z and conductive layers 23Z and 24Z are formed, and the gate electrodes and shield gate electrodes of the respective transistors are formed by gate processing.

Thus, in the shield gate forming area, the opening of essentially the same width as the interconnect width W1 of the shield gate electrode SIG is formed in the mask 95 for use in the EB step, whereby the interconnect width W1 of the shield gate electrode can be essentially the same size as the width W2 of the recess RC2.

After the gate processing, a source/drain diffusion layer, a side wall insulating film (not shown) and an interlayer insulating film are formed, and a silicide layer is formed on the upper surfaces of conductive layers 24, 24L, 24L, 24H and 24S. Then, an interlayer insulating film, interconnects and plugs are successively formed by a multilayer interconnect technology.

As described above, also when the recess RC2 of essentially the same width W1 as the interconnect width W1 of the shield gate electrode SIG is formed in the isolation insulating film 15H by use of the EB step in the manufacturing method of the flash memory of the present embodiment, there can be provided the flash memory of the present embodiment without any noticeable change or increase of the manufacturing steps.

Therefore, according to the semiconductor memory of the fifth embodiment, the leak between the elements can be decreased. Moreover, according to the manufacturing method of the semiconductor memory of the fifth embodiment, there can be provided the memory having enhanced operation characteristics without the increase of the manufacturing steps.

### (6) Sixth Embodiment

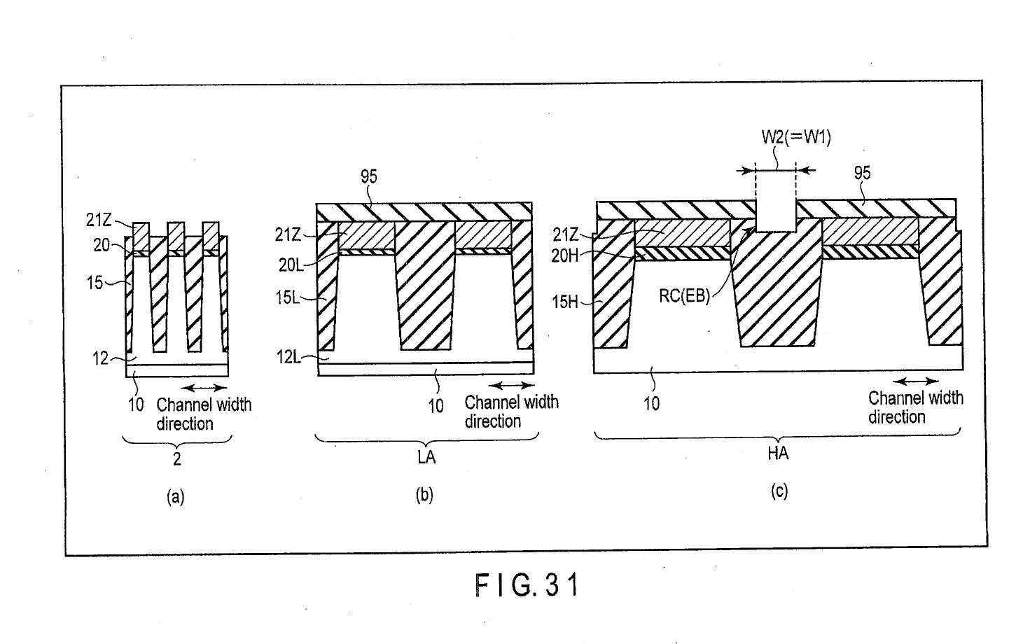

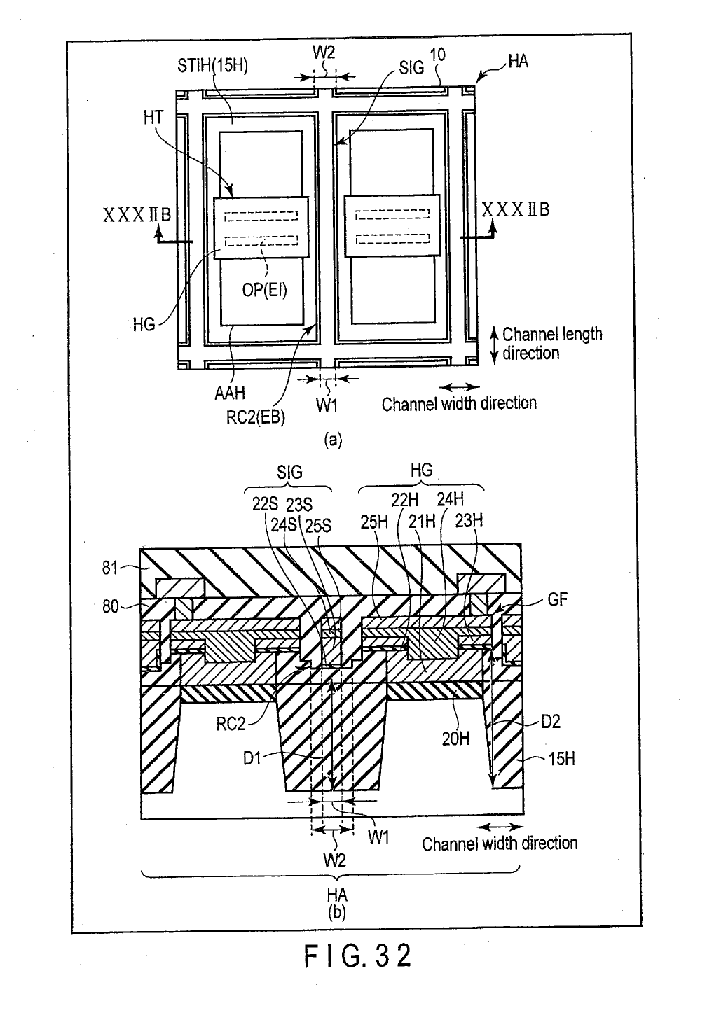

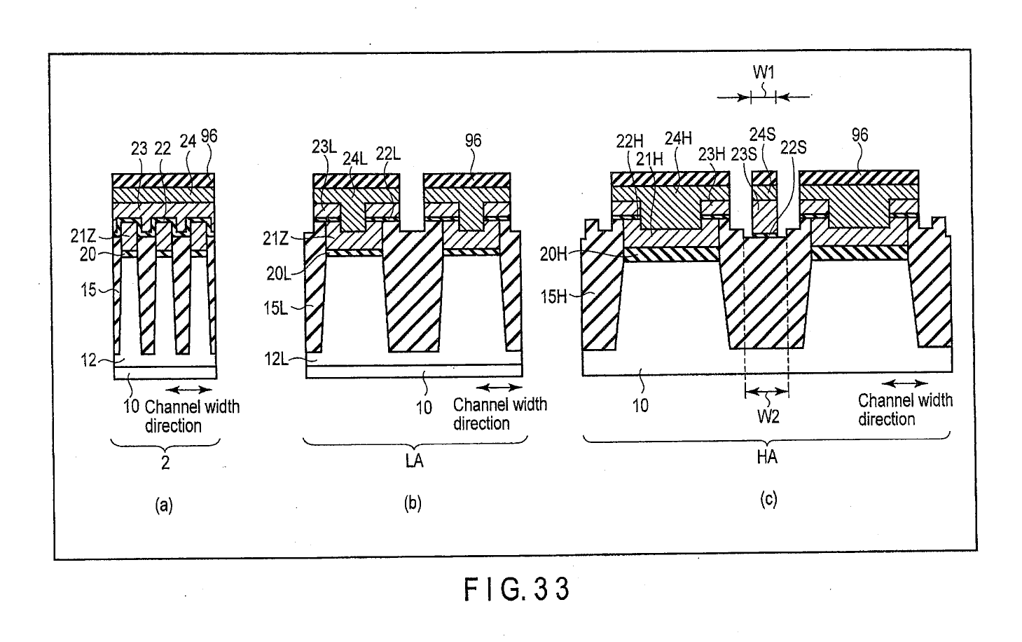

A semiconductor memory and a manufacturing method of the memory of a sixth embodiment will be described with reference to FIG. 32 and FIG. 33.

A structure of the semiconductor memory (e.g., the flash memory) of the sixth embodiment will be described with reference to FIG. 32. In the sixth embodiment, structures of a memory cell, a select transistor and a low breakdown voltage transistor are the same as the structures shown in FIG. 2 to FIG. 4, respectively, and hence the descriptions and illustrations of the structures are omitted. Moreover, the sixth embodiment is different from the first to fifth embodiments only in a structure of a shield gate electrode SIG, and a structure of a high breakdown voltage transistor HT is essentially the same as that of the first to fifth embodiments. Therefore, the description and illustration of the sectional structure of the high breakdown voltage transistor HT along a channel length direction thereof are omitted here. It is to be noted that members and functions common to the first to fifth embodiments will be described in detail if necessary.

FIG. 32 is a view for explaining the structure of the shield gate electrode SIG included in the flash memory of the present embodiment. (a) of FIG. 32 shows a plan view of a peripheral circuit area (a high breakdown voltage transistor forming area) where the shield gate electrode is provided. (b) of FIG. 32 shows a sectional view of the peripheral circuit area (the high breakdown voltage transistor forming area) where the shield gate electrode is provided. (b) of FIG. 32 is a sectional view of the transistor along a channel width direction thereof.

As shown in FIG. 32, in the flash memory of the present embodiment, a width W2 of a recess RC2 of an isolation insulating film 15H in a shield gate forming area is a dimension larger than an interconnect width W1 of the shield gate electrode SIG.

In this case, in the shield gate forming area, an insulator 22S of the same constitution (material and film thickness) as a inter-gate insulating film is provided between a bottom portion of the shield gate electrode SIG and an upper portion of the isolation insulating film 15H.

For example, in a direction vertical to the surface of a semiconductor substrate, a position of an upper portion of the shield gate electrode SIG is set to essentially the same height as a position of the upper surface of a gate electrode HG sometimes, or becomes lower than that of the upper surface of the gate electrode HG sometimes.

The shield gate electrode SIG has a structure provided on the insulator 22S in the recess RC2 of the isolation insulating film 15H. The side surface of the shield gate electrode SIG does not come in contact with the inner side surface of the recess RC2 (the isolation insulating film 15H). Between the side surface of the shield gate electrode SIG and the inner side surface of the recess RC2, an interlayer insulating film (or a side wall insulating film) is buried.

Here, a manufacturing method of the flash memory of the present embodiment will be described with reference to FIG. 33. It is to be noted that in the manufacturing method of the semiconductor memory of the present embodiment, the descriptions and illustrations of the same manufacturing steps as in the manufacturing method of the semiconductor memory of the above-mentioned first to fourth embodiments are omitted.

FIG. 33 shows one process of the manufacturing method of the flash memory of the present embodiment.

FIG. 33 shows a sectional process view of a memory cell and peripheral transistors along the channel width direction. (a) of FIG. 33 shows a sectional step view of the memory cell array. (b) of FIG. 33 shows a sectional step view of the low breakdown voltage transistor. (c) of FIG. 33 shows a sectional step view of the high breakdown voltage transistor.

In the same manner as the process shown in FIG. 27 and FIG. 31, an opening to expose a memory cell array 2 for an ES step in the memory cell array is formed in a mask 95 which covers a semiconductor substrate 10 in the memory cell array 2. In the shield gate forming area, an opening for forming the recess RC2 in the isolation insulating film 15H is formed in the mask 95.

A dimension of the opening of this mask is set so that the width W2 of the recess RC2 formed on the basis of the mask becomes larger than the interconnect width W1 of the shield gate electrode formed in a subsequent step.

An isolation insulating film 15, 15H in the memory cell array 2 and the shield gate forming area are etched on the basis of the mask. In consequence, the upper surface of the isolation insulating film 15 in the memory cell array 2 is etched, and, simultaneously, the recess RC2 provided with the shield gate electrode SIG is formed in the isolation insulating film 15H.

Afterward, as shown in FIG. 33, an insulator 22Z and conductive layers 23Z and 24Z are formed, and deposited on the isolation insulating films 15 and 15H and on a conductive layer 21Z in the same manner as in the examples described in the fourth and fifth embodiments. Then, on the basis of the patterned mask 96, a gate laminate is processed, to form the gate electrodes of the respective transistors and shield gate electrodes.

Thus, in the shield gate forming area, the opening of a dimension larger than the interconnect line width W1 of the shield gate electrode SIG is formed in the mask 95 for use in the ER step, whereby the width W2 of the recess RC2 can be larger than the interconnect line width W1 of the shield gate electrode.

It is to be noted that when the shield gate electrode SIG and the recess RC2 having the above relation between the width W1 and the width W2 are formed, the recess RC2 of the isolation insulating film 15H is not enlarged during processing, but the processing may be carried out so that a processing width of the shield gate electrode SIG becomes smaller than the width W2 of the recess RC2.

As described above, the flash memory of the present embodiment is formed.

In the flash memory of the present embodiment, the trench RC2 for retreating the forming position of the shield gate electrode toward the bottom side of the semiconductor substrate 10 is formed by etch back (the EB step) carried out for the isolation insulating film 15 in the memory cell array to expose the side surface of a floating gate electrode. Consequently, in a direction vertical to the surface of the semiconductor substrate, a distance D1 between the shield gate electrode SIG and the semiconductor region 10 becomes smaller than a distance between a gate fringe portion GF and the semiconductor region 10. In consequence, the formation of an inversion layer under the isolation insulating film 15H by the shield gate electrode SIG can be suppressed to a greater extent.

In the manufacturing method of the present embodiment, even when the recess RC2 having the width W2 larger than the interconnect width W1 of the shield gate electrode SIG is formed in the isolation insulating film 15H by use of the EB step, it is possible to form the flash memory of the present embodiment without any noticeable change or increase of the manufacturing steps.

Therefore, according to the semiconductor memory of the sixth embodiment, leak between elements can be decreased. Moreover, according to the manufacturing method of the semiconductor memory of the sixth embodiment, there can be provided the memory having enhanced operation characteristics without any increase of the manufacturing steps.

### (7) Seventh Embodiment

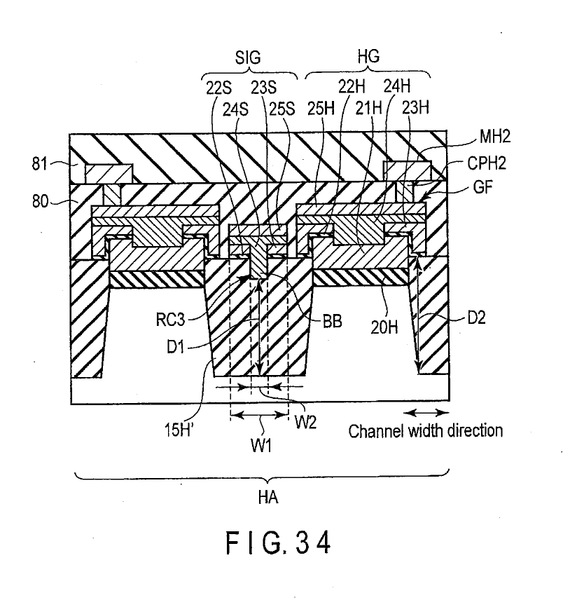

A semiconductor memory and a manufacturing method of the memory of a seventh embodiment will be described with reference to FIG. 34 to FIG. 36. It is to be noted that members and functions common to the first to sixth embodiments will be described in detail if necessary.

(a) Structure

A structure of the flash memory of the seventh embodiment will be described with reference to FIG. 34. In the seventh embodiment, structures of a memory cell, a select transistor and a low breakdown voltage transistor are the same as the structures shown in FIG. 2 to FIG. 4, respectively, and hence the descriptions and illustrations of the structures are omitted. Moreover, the seventh embodiment is different from the first to sixth embodiments only in a structure of a shield gate electrode SIG, and a structure of a high breakdown voltage transistor HT is essentially the same as in the first to sixth embodiments. Therefore, the description and illustration of the sectional structure of the high breakdown voltage transistor along a channel length direction thereof are omitted here. It is to be noted that members and functions common to the first to sixth embodiments will be described in detail if necessary.

FIG. 34 is a view for explaining the structure of the shield gate electrode SIG included in the flash memory of the present embodiment. FIG. 34 shows a sectional view of a peripheral circuit area (the high breakdown voltage transistor forming area) provided with the shield gate electrode. FIG. 34 is a sectional view of the transistor along a channel width direction thereof. It is to be noted that a planar structure of the peripheral circuit area (the high breakdown voltage transistor forming area) provided with the shield gate electrode is the same as the structure shown in (c) of FIG. 3, and hence the illustration thereof is omitted here.

As shown in FIG. 34, in an EB step for a memory cell array 2 in the flash memory of the present embodiment, no mask is formed in peripheral transistor forming areas HA and LA, and isolation insulating films 15L and 15H′ of the peripheral transistor forming areas LA and HA are also exposed to EB conditions. In this case, the upper surface of the isolation insulating film 15H′ in the high breakdown voltage transistor forming area HA is retreated toward a bottom side of a semiconductor substrate 10.

A recess RC3 is formed in the isolation insulating film 15H′ retreated toward the bottom side of the semiconductor substrate by the above EB step. The recess RC3 is formed by an EI step. At least a part of the shield gate electrode SIG is buried in the recess RC3.

In the present embodiment, in a direction vertical to the surface of the semiconductor substrate, a position of the upper surface of the shield gate electrode SIG becomes lower than that of the upper surface of a gate electrode HG, and retreats toward the bottom side of the semiconductor substrate 10. However, in accordance with a width of the isolation insulating film 15H′ and a distance between the gate electrodes HG, the position of an upper portion of the shield gate electrode SIG is sometimes set to essentially the same height as the position of the upper surface of the gate electrode HG in the direction vertical to the surface of the semiconductor substrate.

In this case, a gate fringe portion GF is also provided on the isolation insulating film 15H′ to retreat toward the semiconductor substrate. In the flash memory of the present embodiment, a distance D1 between the bottom portion of the shield gate electrode SIG and the semiconductor region 10 under the isolation insulating film 15H′ is smaller than a distance D2 between the bottom portion of the gate fringe portion GF and the semiconductor region 10 under the isolation insulating film 15H′, in the same manner as in the first to sixth embodiments.

Also, in a structure where the recess RC3 in which at least a part of the bottom portion of the shield gate electrode SIG is buried is formed in the isolation insulating film 15H′ having the upper surface retreated toward the semiconductor substrate side by the EB step, an effect substantially similar to that of the flash memories of the first to sixth embodiments can be obtained.

That is, when the high breakdown voltage transistor is driven in the flash memory of the present embodiment, an effect of suppressing the formation of an inversion layer under the isolation insulating film 15H′ by the shield gate electrode SIG is strengthened.

Therefore, according to the semiconductor memory of the seventh embodiment, leak between elements can be decreased.

(b) Manufacturing Method

A manufacturing method of the semiconductor memory (e.g., the flash memory) of the seventh embodiment will be described with reference to FIG. 34 to FIG. 36. It is to be noted that in the manufacturing method of the semiconductor memory of the present embodiment, the descriptions and illustrations of the same manufacturing steps as in the manufacturing method of the semiconductor memory of the first to sixth embodiments are omitted.

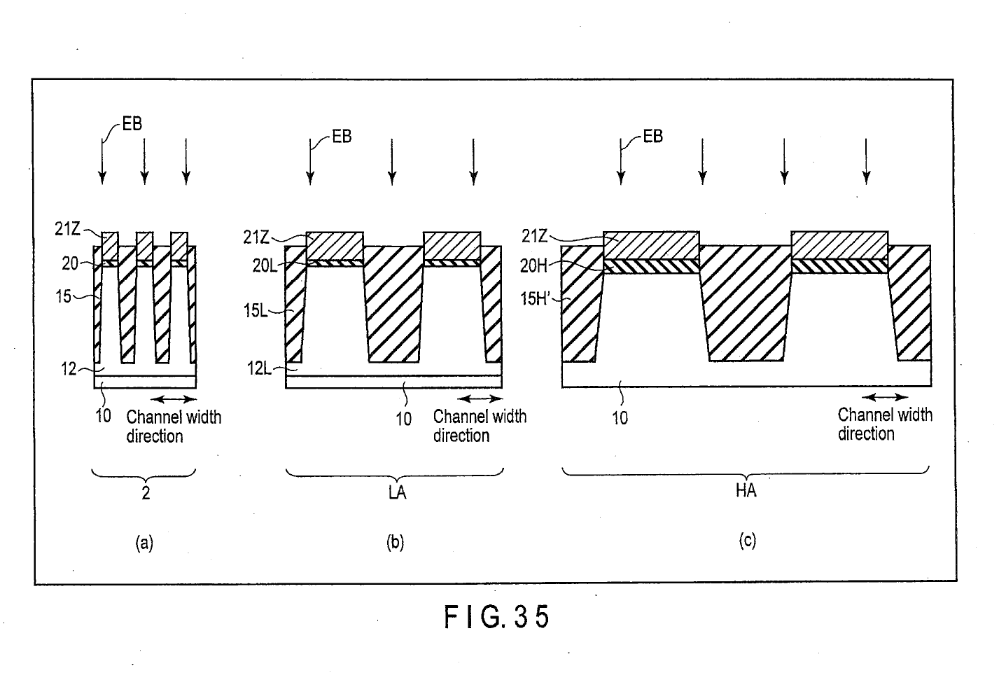

One process of the manufacturing method of the flash memory of the present embodiment will be described with reference to FIG. 35. FIG. 35 is a sectional process view of the memory cell and the peripheral transistors along the channel width direction. (a) of FIG. 35 shows a sectional step view of the memory cell. (b) of FIG. 35 shows a sectional step view of the low breakdown voltage transistor. (c) of FIG. 35 shows a sectional step view of the high breakdown voltage transistor.

As shown in FIG. 35, in the EB step, a mask which covers the peripheral transistor forming areas HA and LA is not formed, and in the whole surface of the semiconductor substrate 10, the etch back of an isolation insulating film 15 in the memory cell array 2 is carried out. In consequence, the upper surface of the isolation insulating film 15 in the memory cell array 2 is etched back, and, simultaneously, the upper surfaces of the isolation insulating films 15L and 15H′ in the peripheral transistor forming areas are also etched. In the high breakdown voltage transistor forming area HA and the low breakdown voltage transistor forming area LA, the upper surfaces of the isolation insulating films 15L and 15H′ retreat more closely to the bottom side of the semiconductor substrate 10 than the upper surface of a polysilicon layer 21Z on gate insulating films 20L and 20H by the EB step.

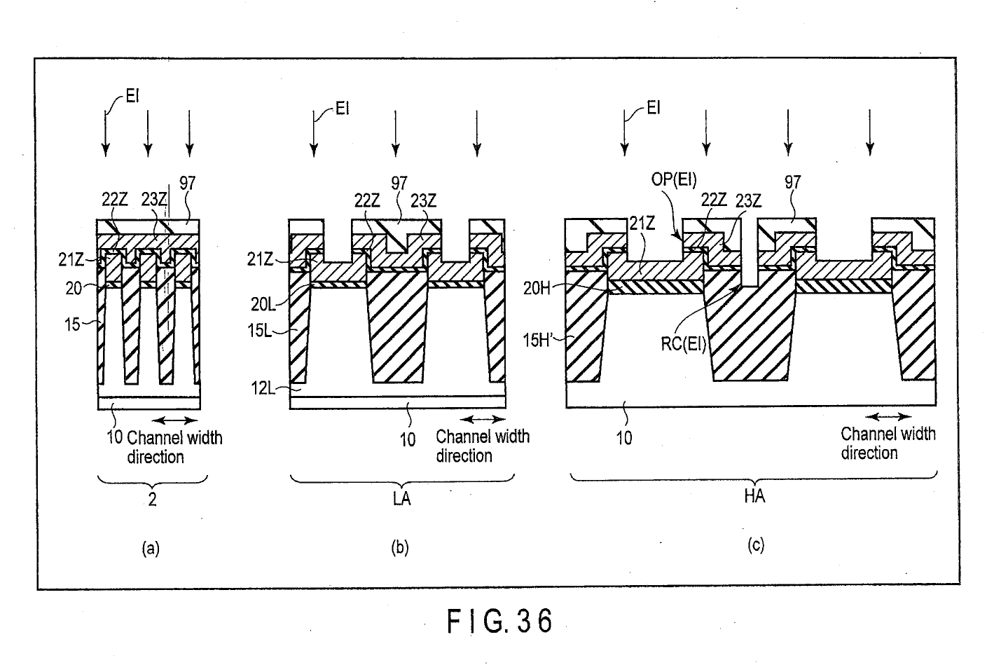

One process of the manufacturing method of the flash memory of the present embodiment will be described with reference to FIG. 36. FIG. 36 is a sectional process view of the memory cell and the peripheral transistors along the channel width direction. (a) of FIG. 36 shows a sectional step view of the memory cell array. (b) of FIG. 36 shows a sectional step view of the low breakdown voltage transistor. (c) of FIG. 36 shows a sectional step view of the high breakdown voltage transistor.

By the EB step, the upper surfaces of the isolation insulating films 15, 15L and 15H′ in the memory cell array 2 and the peripheral transistor forming areas HA and LA are etched back, and then an insulator 22Z as an inter-gate insulating film, a first conductive layer 23Z and a mask 97 are successively deposited on the polysilicon layer 21Z and the isolation insulating films 15, 15L and 15H′.

Then, in the same manner as the process described with reference to FIG. 13 to FIG. 15, the recess RC3 is formed in the isolation insulating film 15H′ etched back by the EB step on the basis of the patterned mask 97 simultaneously with the formation of an opening through the conductive layer 23Z and the insulator 22Z. For example, a width W2 of the recess RC3 is smaller than an interconnect width of the shield gate electrode formed in a subsequent step.

Afterward, the gate electrode, a source/drain diffusion layer, plugs and interconnects are successively formed in the same manner as the steps described in the first to sixth embodiments.

By the above steps, the flash memory of the present embodiment is formed.

Also, in the manufacturing method of the flash memory of the present embodiment, it is possible to form the flash memory in which the distance D1 between the shield gate electrode SIG and the semiconductor region is smaller than a distance D2 between the gate fringe portion GF and the semiconductor region in the direction vertical to the surface of the semiconductor substrate without the increase of the manufacturing steps. In consequence, the effect of suppressing the formation of an inversion layer under the isolation insulating film 15H′ by the shield gate electrode SIG is strengthened.

In the manufacturing method of the flash memory of the present embodiment, a step of forming a mask layer which covers a peripheral area can be omitted in the EB step for the memory cell array 2. Therefore, according to the manufacturing method of the flash memory of the present embodiment, the manufacturing steps of the semiconductor memory can be simplified in addition to the effects of the first to sixth embodiments.

As described above, the leak between the elements can be decreased according to the semiconductor memory of the seventh embodiment. Moreover, according to the manufacturing method of the semiconductor memory of the seventh embodiment, there can be provided the memory having enhanced operation characteristics without the increase of the manufacturing steps.

### (8) Eighth Embodiment

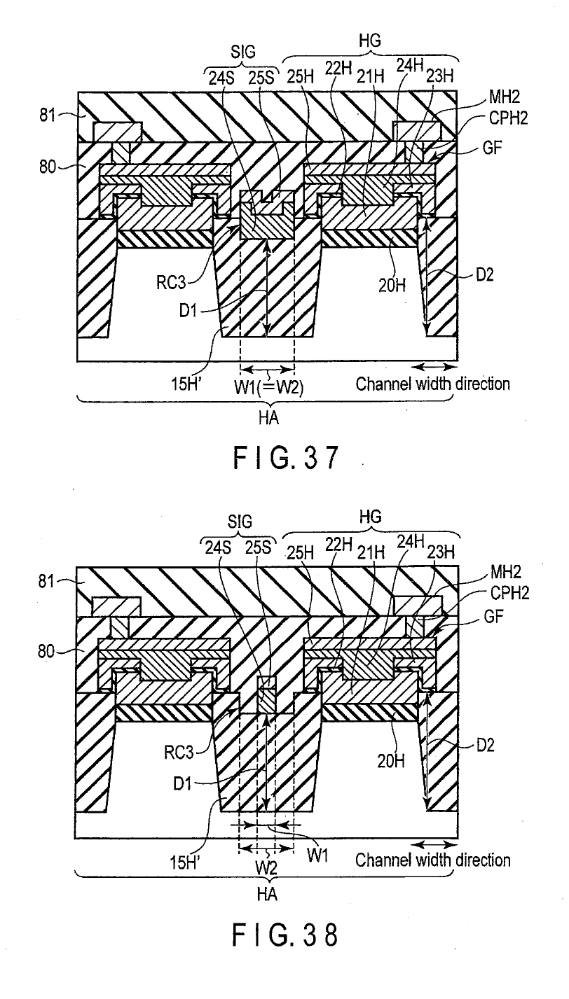

A semiconductor memory and a manufacturing method of the memory of an eighth embodiment will be described with reference to FIG. 37. In the eighth embodiment, structures of a memory cell, a select transistor and a low breakdown voltage transistor are the same as the structures shown in FIG. 2 to FIG. 4, respectively, and hence the descriptions and illustrations of these structures are omitted. Moreover, the eighth embodiment is different from the first to seventh embodiments only in a structure of a shield gate electrode SIG, and a structure of a high breakdown voltage transistor HT is essentially the same as in the first to seventh embodiments. Therefore, the description and illustration of the sectional structure of the high breakdown voltage transistor along a channel length direction are omitted. It is to be noted that members and functions common to the first to seventh embodiments will be described in detail if necessary.

FIG. 37 is a view for explaining the structure of the semiconductor memory (the flash memory) of the eighth embodiment. FIG. 37 shows a sectional view of a peripheral circuit area (the high breakdown voltage transistor forming area) provided with the shield gate electrode. FIG. 37 is a sectional view of the transistor along a channel width direction thereof. It is to be noted that a planar structure of the peripheral circuit area (the high breakdown voltage transistor forming area) provided with the shield gate electrode is essentially the same as the structure shown in FIG. 20, and hence the illustration thereof is omitted here.

As shown in FIG. 37, in the high breakdown voltage transistor HT of the flash memory of the present embodiment, the shield gate electrode SIG and a gate fringe portion GF are provided on an isolation insulating film 15H′ having an upper surface retreated toward a bottom side of a semiconductor substrate 10 by an EB step.

In the upper surface of the isolation insulating film 15H′, a recess RC3 in which the shield gate electrode SIG is buried is provided. In the same manner as in the second and fifth embodiments, an interconnect width W1 of the shield gate electrode SIG has essentially the same size as a width W2 of the recess RC3.

Here, a manufacturing method of the flash memory of the present embodiment will be, described.

In the manufacturing method of the flash memory of the present embodiment, as described with reference to FIG. 35, the upper surface of an isolation insulating film 15 in a memory cell array 2 is etched back, and, simultaneously, the upper surface of the isolation insulating film 15H′ in a high breakdown voltage transistor forming area HA is etched back, in the EB step. An insulator 22Z, a conductive layer 23Z and a mask 97 are deposited on a polysilicon layer 21Z and the isolation insulating film 15H′. The mask 97 is patterned to include an opening.

Continuously with the formation of the opening through the conductive layer 23Z and the insulator 22Z on the basis of the mask 97 by an EI step as described above, the recess RC3 is formed in the upper surface of the isolation insulating film 15H′. A dimension of the recess RC3 is set to the same size as the interconnect width of the shield gate electrode SIG formed in a subsequent step.

Afterward, gate processing, the formation of a source/drain diffusion layer, the formation of a silicide layer and the formation of plugs/interconnects are successively carried out. The interconnect width W1 of the formed shield gate electrode is essentially the same as the width W2 of the recess RC3 formed in the upper surface of the isolation insulating film 15H′.

Thus, the dimension of the opening of the mask above an isolation insulating film 15H in a shield gate forming area is regulated during EI processing in the same manner as in the second embodiment, whereby as shown in FIG. 37, it is possible to form the flash memory of a structure where the interconnect width W1 of the shield gate electrode SIG is essentially the same as the width W2 of the recess RC3 provided with the shield gate electrode SIG.

Also, in the flash memory and the manufacturing method of the memory of the present embodiment, it is possible to form the flash memory where a distance D1 between the shield gate electrode SIG and the semiconductor region 10 is smaller than a distance D2 between the gate fringe portion GF and the semiconductor region 10 in a direction vertical to the surface of the semiconductor substrate without adding any manufacturing step. In consequence, the formation of an inversion layer under the isolation insulating film 15H by the shield gate electrode SIG can be suppressed to a greater extent.

As described above, leak between elements can be decreased according to the semiconductor memory of the eighth embodiment. Moreover, according to the manufacturing method of the semiconductor memory of the eighth embodiment, there can be provided the memory having enhanced operation characteristics without adding any manufacturing step.

### (9) Ninth Embodiment

A semiconductor memory and a manufacturing method of the memory of a ninth embodiment will be described with reference to FIG. 38. In the ninth embodiment, structures of a memory cell, a select transistor and a low breakdown voltage transistor are the same as the structures shown in FIG. 2 to FIG. 4, respectively, and hence the descriptions and illustrations of the structures are omitted. Moreover, the ninth embodiment is different from the first to eighth embodiments only in a structure of a shield gate electrode SIG, and a structure of a high breakdown voltage transistor HT is essentially the same as in the first to eighth embodiments. Therefore, the description and illustration of the sectional structure of the high breakdown voltage transistor along a channel length direction thereof are omitted here. It is to be noted that members and functions common to the first to eighth embodiments will be described in detail if necessary.

FIG. 38 is a view for explaining a structure of the semiconductor memory (e.g., the flash memory) of the ninth embodiment. FIG. 38 shows a sectional view of a peripheral circuit area (the high breakdown voltage transistor forming area) provided with the shield gate electrode. FIG. 38 is a sectional view of the transistor along a channel width direction thereof. It is to be noted that a planar structure of the peripheral circuit area (the high breakdown voltage transistor forming area) provided with the shield gate electrode is essentially the same as the structure shown in FIG. 26, and hence the illustration thereof is omitted here.

As shown in FIG. 38, in the high breakdown voltage transistor HT of the flash memory of the present embodiment, the shield gate electrode SIG and a gate fringe portion GF are provided on an isolation insulating film 15H′ having an upper surface retreated toward a bottom side of a semiconductor substrate 10 by an EB step, in the same manner as in the structures shown in FIG. 35 and FIG. 37. Moreover, in a recess RC3 of the upper surface of an isolation insulating film 15H′, a width w2 of the recess RC3 is larger than an interconnect width W1 of the shield gate electrode SIG.

Thus, in the flash memory of the present embodiment, the interconnect width W1 of the shield gate electrode SIG is smaller than the width W2 of the recess RC3 formed in the upper surface of the isolation insulating film 15H′, in the same manner as in the third and sixth embodiments.

In the manufacturing method of the flash memory of the present embodiment, as described with reference to FIG. 36, an opening is formed through a conductive layer 23Z and an insulator 22Z by an EI step, and simultaneously the recess RC3 is formed in the upper surface of the isolation insulating film 15H′ etched back in an EB step. A mask 97 is patterned so that the width W2 of the recess RC3 becomes larger than the interconnect width W1 of the shield gate electrode SIG formed in a subsequent step. The upper surface of the isolation insulating film 15H′ is etched on the basis of the mask 97.

Afterward, gate processing, the formation of a source/drain diffusion layer, the formation of a silicide layer and the formation of plugs/interconnects are successively carried out. The interconnect width of the formed shield gate electrode is smaller than the width W2 of the recess RC3 formed in the upper surface of the isolation insulating film 15H′.

Thus, the dimension of the opening of the mask above an isolation insulating film 15H in a shield gate forming area is regulated during SI processing, whereby as shown in FIG. 38, it is possible to form the flash memory of a structure where the interconnect width W1 of the shield gate electrode SIG is smaller than the width W2 of the recess RC3 in which the shield gate electrode SIG is buried.

Also in the flash memory and the manufacturing method of the memory of the present embodiment, it is possible to form the flash memory where a distance D1 between the shield gate electrode SIG and the semiconductor region 10 is smaller than a distance D2 between the gate fringe portion GF and the semiconductor region 10 in a direction vertical to the surface of the semiconductor substrate without adding any manufacturing step. In consequence, the formation of an inversion layer under the isolation insulating film 15H by the shield gate electrode SIG can be suppressed to a greater extent.

Therefore, leak between elements can be decreased according to the semiconductor memory of the ninth embodiment. Moreover, according to the manufacturing method of the semiconductor memory of the ninth embodiment, there can be provided the memory having enhanced operation characteristics without adding any manufacturing step.

### (10) Modifications

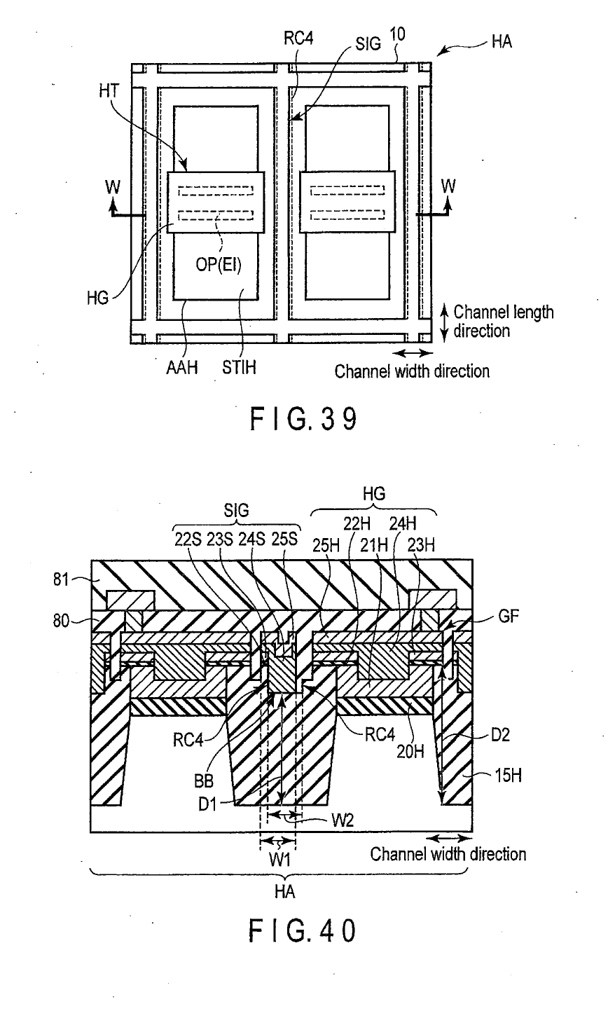

Modifications of the semiconductor memory (the flash memory) of the embodiment will be described with reference to FIG. 39 to FIG. 42. In the present modifications, structures of a memory cell, a select transistor and a low breakdown voltage transistor are essentially the same as the structures described in the first to ninth embodiments, respectively, and hence the descriptions and illustrations of the structures are omitted. Moreover, the present modifications are different from the first to ninth embodiments only in a structure of a shield gate electrode SIG, and a structure of a high breakdown voltage transistor HT is essentially the same as in the first to ninth embodiments. Therefore, the description and illustration of the sectional structure of the high breakdown voltage transistor along a channel length direction thereof are omitted here.

For example, as shown in FIG. 39, a deviation sometimes occurs between a position of the shield gate electrode SIG and a position of a recess RC4 formed in the upper surface of an isolation insulating film 15H, owing to misalignment of a mask.

Thus, when the misalignment occurs between the shield gate electrode SIG and the recess RC4, a sectional shape of the shield gate electrode SIG in the above-mentioned embodiments is a sectional shape shown in FIG. 40 to FIG. 42.

FIG. 40 shows a modification of the flash memory of the second embodiment. The recess RC4 is formed by an ET step, and an interconnect width W1 of a shield gate electrode SIG is set to be essentially the same as a width W2 of the recess RC4.

As shown in FIG. 40, at one end of the shield gate electrode in an interconnect width direction, a first conductive layer 23S and an insulator 22S are left between the upper surface of an isolation insulating film 15H and a second conductive layer 24S of the shield gate electrode SIG. For example, at the other end of the shield gate electrode in the width direction (on a side where the insulator 22S is not left), the side surface of the shield gate electrode SIG does not come in contact with the inner side surface of the recess RC4 (the side surface of the isolation insulating film 15H).

The insulator 22S and the conductive layer 23S remain in a direction opposite to a direction in which a forming position of the recess RC4 deviates from a forming position of the shield gate electrode SIG.

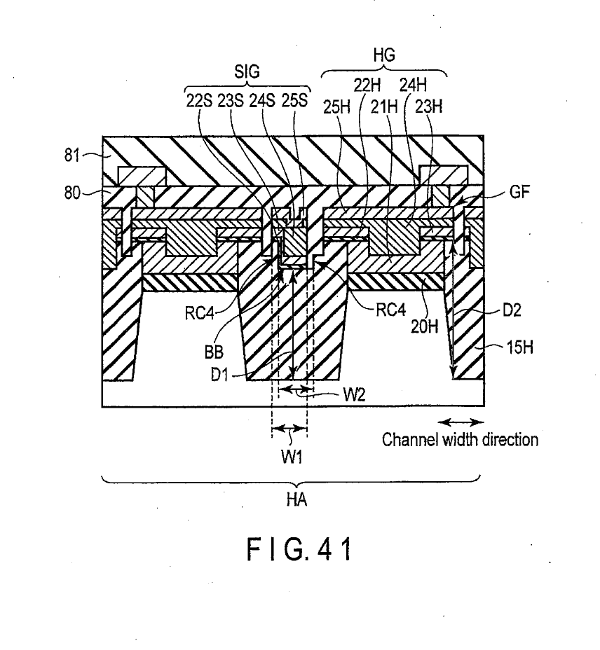

FIG. 41 shows a modification of the flash memory of the fifth embodiment. A trench RC4 is formed by an EB step, and an interconnect width W1 of a shield gate electrode SIG is set to be essentially the same as a width W2 of the trench RC4.

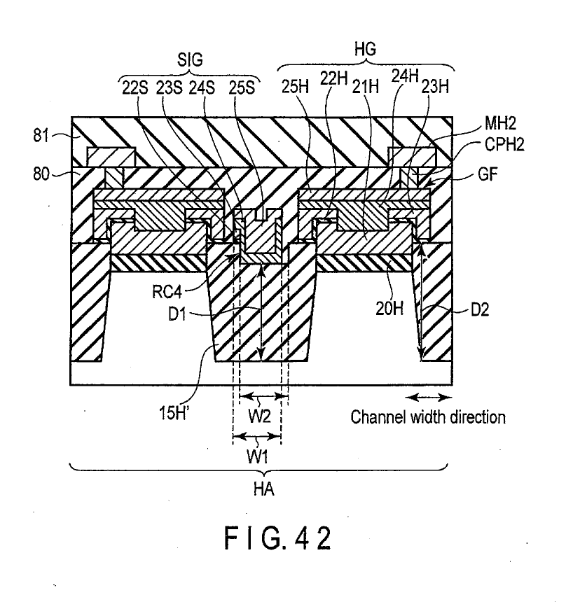

Furthermore, FIG. 42 shows a modification of the flash memory of the eighth embodiment. A trench RC4 is formed, by an EI step, in the upper surface of an isolation insulating film 15H′ etched by an EB step. Moreover, an interconnect width W1 of a shield gate electrode SIG is set to be essentially the same as a width W2 of the trench.

Also, in FIG. 41 and FIG. 42, at one end of the shield gate electrode in a width direction, a first conductive layer 23S and an insulator 225 are left between the upper surface of an isolation insulating film 15H and a second conductive layer 24S of the shield gate electrode SIG. For example, at the other end of the shield gate electrode in the width direction, the side surface of the shield gate electrode SIG does not come in contact with the inner side surface of the recess (the side surface of the isolation insulating film 15H).

Also, in the modifications shown in FIG. 39 to FIG. 42, it is possible to obtain essentially the same effects as in the effects described in the first to ninth embodiments.

Therefore, according to the modifications of the semiconductor memory of the present embodiment, there can be provided the semiconductor memory in which leak between elements can be decreased. According to the modification of the manufacturing method of the semiconductor memory of the present embodiment, there can be provided the memory having enhanced operation characteristics without the increase of manufacturing steps.

[Other]

In the first to ninth embodiments and the modifications, the semiconductor memory according to the embodiment has been described with respect to the illustration of an NAND-type flash memory. However, the semiconductor memory of the embodiment is not limited to the NAND-type flash memory, and may be applied to another semiconductor memory as long as the semiconductor memory includes memory cells of a stack gate structure including a charge storage layer, a high breakdown voltage transistor and a shield gate electrode.

In the first to ninth embodiments and the modifications, there has been described the manufacturing method in which the memory cells and the peripheral transistors are formed by a common step, but the memory cells and the peripheral transistors do not have to be formed by the common step, as long as the peripheral transistor (the high breakdown voltage transistor) and the shield gate electrode are formed by a common step.

When the peripheral transistor (the high breakdown voltage transistor) and the shield gate electrode are formed by the common step, the gate electrode of the peripheral transistor may be formed of a structure where the upper electrode layer is not isolated from the lower electrode layer via the insulator, i.e., a structure of one continuous conductor. Moreover, in the gate electrode of the peripheral transistor, the insulator between the upper electrode layer and the lower electrode layer may not include an opening for connecting the upper electrode layer to the lower electrode layer.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit Of the inventions.

What is claimed is:

1. A semiconductor memory comprising:
a memory cell array provided in a semiconductor substrate and including a first active area surrounded with a first isolation insulating film;
a first transistor area provided in the semiconductor substrate and including a second active area surrounded with a second isolation insulating film;
a memory cell provided in the memory cell array, the memory cell comprising a first gate insulating film provided on the first active area, a charge storage layer provided on the first gate insulating film, a first insulator provided on the charge storage layer, and a control gate electrode provided on the charge storage layer via the first insulator;
a first transistor provided in the first transistor area, the first transistor comprising a second gate insulating film having a second film thickness larger than, a first film thickness of the first gate insulating film and provided on the second active area, and a first electrode layer provided on the second gate insulating film; and
a shield gate electrode provided on the second isolation insulating film,
wherein the bottom surface of the shield gate electrode is positioned more closely to the semiconductor substrate side as compared with the highest upper surface of the second isolation insulating film.

2. The semiconductor memory according to claim 1, wherein a trench is provided in an upper portion of the second isolation insulating film,
a width of an upper portion of the shield gate electrode is larger than that of the trench, and
a part of the shield gate electrode is buried in the trench.

3. The semiconductor memory according to claim 2, wherein a sectional shape of the shield gate electrode is a downwardly projecting shape.

4. The semiconductor memory according to claim 1, wherein a trench is provided in an upper portion of the second isolation insulating film,
a width of the shield gate electrode is equal to or smaller than a width of the trench, and
the shield gate electrode is provided in the trench.

5. The semiconductor memory according to claim 1, wherein the first transistor further comprises a second insulator provided on the first electrode layer and having a first opening, and a second electrode layer provided on the first electrode layer via the second insulator and extending from the second active area onto the second isolation insulating film in a channel width direction of the first transistor,
the second electrode layer includes a first conductive layer on the second insulator, and a second conductive layer on the first conductive layer,
the shield gate electrode includes a first layer of the same material as that of the second conductive layer, and
the first layer comes in contact with the second isolation insulating film.

6. The semiconductor memory according to claim 5, wherein the shield gate electrode further includes a third insulator of the same material as that of the second insulator between the first layer and the second isolation insulating film, and an intermediate layer of the same material as that of the first conductive layer between the third insulator and the first layer,
a trench is provided in an upper portion of the second isolation insulating film,
wherein the first layer is buried in the trench via a second opening formed through the intermediate layer and the third insulator.

7. The semiconductor memory according to claim 1, wherein a third insulator formed of the same material as that of the second insulator is provided between the shield gate electrode and the second isolation insulating film.

8. The semiconductor memory according to claim 5, wherein, in the direction vertical to the surface of the semiconductor substrate, a first distance between a lower surface of the shield gate electrode and a lower surface of the second isolation insulating film is smaller than a second distance between a lower surface of the second electrode layer extending from the second active area onto the second isolation insulating film and the lower surface of the second isolation insulating film.

9. The semiconductor memory according to claim 1, wherein the first transistor further comprises a second insulator provided on the first electrode layer and having a first opening, and second electrode layer provided on the first electrode layer via the second insulator,
a lower surface of the shield gate electrode is positioned more closely to the semiconductor substrate side than an upper surface of the first electrode layer.

10. The semiconductor memory according to claim 1, wherein the first transistor further comprises a second insulator provided on the first electrode layer and having a first opening, and a second electrode layer provided on the first electrode layer via the second insulator,
a position of an upper surface of the shield gate electrode is substantially the same as a position of an upper surface of the second electrode layer in the direction vertical to the surface of the semiconductor substrate.

11. The semiconductor memory according to claim 1, wherein the first transistor further comprises a second insulator provided on the first electrode layer and having a first opening, and a second electrode layer provided on the first electrode layer via the second insulator,
an upper surface of the shield gate electrode is positioned more closely to the semiconductor substrate side than an upper surface of the second electrode layer in the direction vertical to the surface of the semiconductor substrate.

12. The semiconductor memory according to claim 4, wherein the trench has a depth of two steps.

13. The semiconductor memory according to claim 4, wherein an interlayer insulating film is provided between the side surface of the trench and the side surface of the shield gate electrode.

14. The semiconductor memory according to claim 1, wherein the shield gate electrode is formed to surround the first transistor.

15. A manufacturing method of a semiconductor memory comprising:
forming a first layer on a semiconductor substrate;
processing the first layer and forming first and second grooves in the semiconductor substrate surrounding first and second active area, respectively;
burying the first and second grooves to form first and second isolation insulating film;
forming a second layer on an insulator on the first layer in the first and second active areas to bury the second layer in a trench of an upper portion of the second isolation insulating film; and
processing the second layer and the insulator in the first and second active areas to form, in the first active area, a memory cell including a charge storage layer and a control gate electrode and to form, in the second active area, a transistor including a first electrode layer and a second electrode layer on the first electrode layer, and simultaneously processing the second layer on the second isolation insulating film to form a shield gate electrode on the second isolation insulating film so that a lower surface of the shield gate electrode is positioned more closely to the semiconductor substrate side as compared with the highest upper surface of the second isolation insulating film.

16. The manufacturing method of the semiconductor memory according to claim 15, wherein the second electrode layer is formed to extend from the second active area onto the second isolation insulating film, and
the shield gate electrode is formed so that the lower surface of the shield gate electrode is positioned more closely to the semiconductor substrate side than a lower surface of the second electrode layer above the second isolation insulating film, in the direction vertical to the surface of the semiconductor substrate.

17. The manufacturing method of the semiconductor memory according to claim 15, further comprising:
forming an opening in the insulator in the second active area, to expose an upper portion of the first layer simultaneously with the formation of the trench, prior to forming the second layer.

18. The manufacturing method of the semiconductor memory according to claim 15, further comprising:
etching back an upper portion of the first isolation insulating film toward the semiconductor substrate side simultaneously with the formation of the trench, prior to forming the insulator.

19. The manufacturing method of the semiconductor memory according to claim 15, wherein a width of an upper portion of the shield gate electrode is larger than a width of the trench.

20. The manufacturing method of the semiconductor memory according to claim 15, wherein a width of an upper portion of the shield gate electrode is smaller than a width of the trench.
